(19) United States
(12) Patent Application Publication
(10) Pub. No.: US 2025/0275349 A1
(43) Pub. Date: Aug. 28, 2025

(54) MATERIALS FOR ORGANIC ELECTROLUMINESCENT DEVICES

(71) Applicant: Merck Patent GmbH, Darmstadt (DE)

(72) Inventors: Amir Hossain PARHAM, Darmstadt (DE); Stefan SCHRAMM, Darmstadt (DE); Philipp SCHUETZ, Darmstadt (DE)

(21) Appl. No.: 18/857,846

(22) PCT Filed: Apr. 25, 2023
(86) PCT No.: PCT/EP2023/060757

§ 371 Date: Oct. 18, 2024

(30) Foreign Application Priority Data
Apr. 28, 2022 (EP) 22170576.7

(51) Int. Cl. H10K 50/12; C09K 11/06; H10K 85/60; H10K 101/10; H10K 101/30

(52) U.S. Cl. CPC H10K 50/121; C09K 11/06; H10K 85/654; H10K 85/6572; H10K 85/6574; C09K 2211/1018; H10K 2101/10; H10K 2101/30

(57) ABSTRACT

The present invention relates to a composition comprising a electron-transporting host material, a phosphorescent emitter as a sensitizer and a fluorescent emitter, as well as devices comprising these compositions, especially organic electroluminescent devices including an emission layer comprising these compositions.

The present invention describes a composition comprising a electron-transporting host material, a phosphorescent emitter as a sensitizer and a fluorescent emitter, as well as devices comprising these compositions, especially organic electroluminescent devices including an emission layer comprising these compositions.

The structure of organic electroluminescent devices (OLEDs) in which organic semiconductors are used as functional materials is described, for example, in U.S. Pat. No. 4,539,507. Common emitting materials used in OLEDs are organometallic iridium and platinum complexes which exhibit phosphorescence rather than fluorescence (M. A. Baldo et al., Appl. Phys. Lett. 1999, 75, 4-6). For quantum-mechanical reasons, up to four times the energy efficiency and power efficiency is possible using organometallic compounds as phosphorescent emitters.

In spite of the good results which are achieved with organometallic iridium and platinum complexes as phosphorescent emitters, there is still a need for improvement of OLEDs performances, especially in terms of efficiency, color purity, achieving deep blue colors.

As an alternative to phosphorescent OLEDs, the prior art describes organic electroluminescent devices comprising, in the emitting layer, a phosphorescent organometallic complex as a sensitizer, which shows mixing of S1 and T1 states due to the large spin-orbit coupling, and a fluorescent compound as an emitter, so that the emission decay time can significantly be shortened. Such systems have been described in the prior art, for example in US 2021/104682 A1 and US 2021/0098714 A1. This is a very promising technique to improve OLEDs properties, more particularly with regard to blue emission.

However, further improvements are still necessary with respect to the performance data of OLEDs, in particular with a view to broad commercial use, for example in display devices or as light sources. Of particular importance in this connection are the lifetime, the efficiency and the operating voltage of the OLEDs and as well as the colour values achieved. In particular, in case of blue-emitting OLEDs, there is potential for improvement with respect to the lifetime and the efficiency of the devices.

An important starting point for achieving the said improvements is the choice of the host materials, sensitizer and emitter in the emitting layer.

An emitter compound here is taken to mean a compound which emits light during operation of the electronic device.

A sensitizer compound here is taken to mean a compound that does not emit light by itself but transfers its energy to the fluorescent emitter, to facilitate light emission.

A host compound here is taken to mean a compound which is present in the mixture in a greater proportion than the emitter and/or the sensitizer compound. The term matrix compound and the term host compound can be used synonymously in accordance to the present invention. The host compound preferably does not emit light.

Even if a plurality of different host compounds are present in the mixture of the emitting layer, their individual proportions are typically greater than the proportion of the emitter compounds, or the proportions of the individual emitter compounds if a plurality of emitter compounds are present in the mixture of the emitting layer.

If a mixture of a plurality of compounds is present in the emitting layer, the emitter compound is typically the component present in smaller amount, i.e. in a smaller proportion than the other compounds present in the mixture of the emitting layer. In this case, the emitter compound is also referred to as dopant. If a mixture of a plurality of compounds is present in the emitting layer, the emitter compound is typically the component present in smaller amount, i.e. in a smaller proportion than the other compounds present in the mixture of the emitting layer. In this case, the emitter compound is also referred to as dopant.

Also, even if a plurality of different host compounds are present in the mixture of the emitting layer, their individual proportions are typically greater than the proportion of the sensitizer compounds, or the proportions of the individual sensitizer compounds if a plurality of sensitizer compounds are present in the mixture of the emitting layer. Since the sensitizer is preferably present in a smaller amount than the host compounds(s), the sensitizer compound might also referred to as dopant.

Host materials, metal complexes and fluorescent emitters for use in organic electronic devices are well known to the person skilled in the art. A multitude of host materials, complexes and fluorescent emitters has been developed both for fluorescent and for phosphorescent electronic devices. However, it is still a challenge to find new combinations of OLED materials for the emitting layer leading to devices having an efficient emission with the appropriate colour emission and an excellent lifetime. However, there is still need for improvement in the case of use of a combination of host materials, sensitizer and emitter in the emitting layer, more particularly blue emitting layer, especially in relation to efficiency, operating voltage and/or lifetime of the organic electronic device.

Host compounds comprising carbazole and triazine groups as disclosed in, for example, EP 2497811 A2 are known as suitable hosts for OLEDs. Metal complexes as sensitizer are also known from the prior art, like in US 2021/104682 A1. Of course, there is a multitude of fluorescent emitters, which are known from the prior art.

The problem addressed by the present invention is that of providing compositions, which are especially suitable as compositions for emitting layers, preferably for blue or green emitting layers in OLEDs.

Surprisingly, it has been found that compositions comprising the compounds described in more detail below solve this problem and are particularly suitable for use in OLEDs. In particular, the OLEDs have a long lifetime, a high efficiency, and a low operating voltage. These compositions as well as electronic devices, in particular organic electroluminescent devices, containing these compositions are therefore the object of the present invention.

The invention therefore provides a composition comprising:
at least one electron-transporting host material;
at least one blue phosphorescent metal complex;
at least one fluorescent emitter;
characterized in that at least one electron-transporting host material is selected from the compounds of formulae (1), (2) or (3);

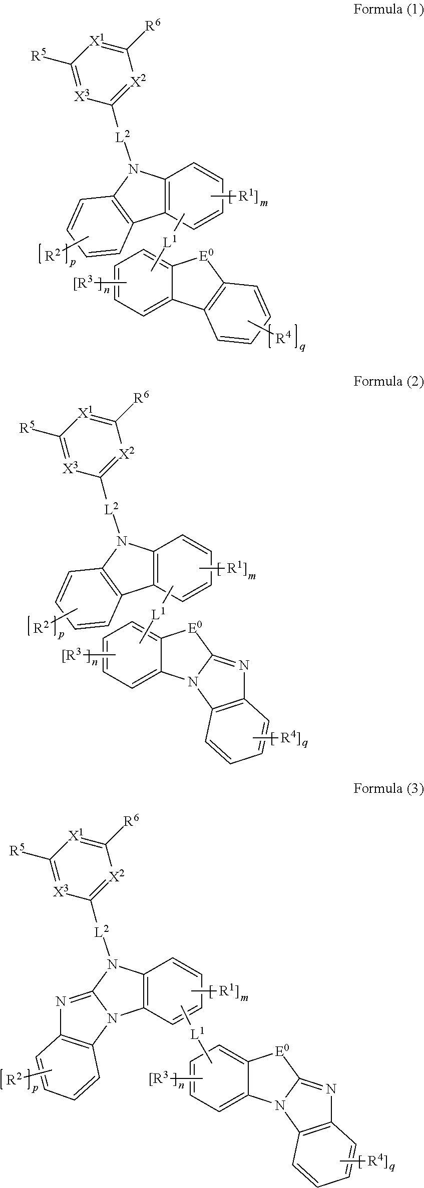

where the symbols and indices used are as follows:
X¹, X², X³ stand, on each occurrence identically or differently, for a group CR^{X} or N; with the proviso that at least one group selected from X¹, X² and X³ stands for N;
E⁰ stands for on each occurrence, identically or differently, for C(R^{C})₂, NR^{N}, O or S;
L¹, L² stand on each occurrence, identically or differently, for a single bond, —C(R)₂—, —Si(R)₂— or for an aromatic or heteroaromatic ring system having 5 to 30 aromatic ring atoms, which may be substituted by one or more radicals R;
R^{X}, R¹, R², R³, R⁴, R⁵, R⁶ stand on each occurrence, identically or differently, for a radical selected from H, D, F, Cl, Br, I, CHO, CN, C(═O)Ar, P(═O)(Ar)₂, S(═O)Ar, S(═O)₂Ar, N(R)₂, N(Ar)₂, NO₂, Si(R)₃, B(OR)₂, OSO₂R, a straight-chain alkyl, alkoxy or thioalkyl group having 1 to 40 C atoms or branched or a cyclic alkyl, alkoxy or thioalkyl group having 3 to 40 C atoms, each of which may be substituted by one or more radicals R, where in each case one or more non-adjacent CH₂ groups may be replaced by RC═CR, C≡C, Si(R)₂, Ge(R)₂, Sn(R)₂, C═O, C═S, C═Se, P(═O)(R), SO, SO₂, O, S or CONR and where one or more H atoms may be replaced by D, F, Cl, Br, I, CN or NO₂, an aromatic or heteroaromatic ring system having 5 to 60 aromatic ring atoms, which may in each case be substituted by one or more radicals R, and an aryloxy group having 5 to 60 aromatic ring atoms, which may be substituted by one or more radicals R; where two radicals R¹, two radicals R², two radicals R³, two radicals R⁴ may form an aliphatic, aromatic or heteroaromatic ring system together, which may be substituted by one or more radicals R;
R^{C} stand on each occurrence, identically or differently, for a radical selected from H, D, a straight-chain alkyl group having 1 to 40 C atoms, which may be substituted by one or more radicals R, an aryl or heteroaryl group having 6 to 18 aromatic ring atoms, which may in each case be substituted by one or more radicals R; where two radicals R^{C} may form an aliphatic, aromatic or heteroaromatic ring system together, which may be substituted by one or more radicals R;
R^{N} stand on each occurrence, identically or differently, for a radical selected from H, D, F, a straight-chain alkyl group having 1 to 40 C atoms or branched or a cyclic alkyl group having 3 to 40 C atoms, each of which may be substituted by one or more radicals R, and where one or more H atoms may be replaced by D, F or CN, an aromatic or heteroaromatic ring system having 5 to 60 aromatic ring atoms, which may in each case be substituted by one or more radicals R;
R stands on each occurrence, identically or differently, for H, D, F, Cl, Br, I, CHO, CN, C(═O)Ar, P(═O)(Ar)₂, S(═O)Ar, S(═O)₂Ar, N(R′)₂, N(Ar)₂, NO₂, Si(R′)₃, B(OR′)₂, OSO₂R′, a straight-chain alkyl, alkoxy or thioalkyl group having 1 to 40 C atoms or branched or a cyclic alkyl, alkoxy or thioalkyl group having 3 to 40 C atoms, each of which may be substituted by one or more radicals R′, where in each case one or more non-adjacent CH₂ groups may be replaced by R′C═CR′, C≡C, Si(R)₂, Ge(R′)₂, Sn(R)₂, C═O, C═S, C═Se, P(═O)(R′), SO, SO₂, O, S or CONR′ and where one or more H atoms may be replaced by D, F, Cl, Br, I, CN or NO₂, an aromatic or heteroaromatic ring system having 5 to 60 aromatic ring atoms, which may in each case be substituted by one or more radicals R′, or an aryloxy group having 5 to 60 aromatic ring atoms, which may be substituted by one or more radicals R′; where two radicals R may form an aliphatic or aromatic ring system together, which may be substituted by one or more radicals R′;
Ar is, on each occurrence, identically or differently, an aromatic or heteroaromatic ring system having 5 to 60 aromatic ring atoms, which may in each case also be substituted by one or more radicals R′;
R′ stands on each occurrence, identically or differently, for H, D, F, C, Br, I, CN, a straight-chain alkyl, alkoxy or thioalkyl group having 1 to 20 C atoms or branched or cyclic alkyl, alkoxy or thioalkyl group having 3 to 20 C atoms, where in each case one or more non-adjacent CH₂ groups may be replaced by SO, SO₂, O, S and where one or more H atoms may be replaced by D, F, C, Br or I, or an aromatic or heteroaromatic ring system having 5 to 24 aromatic ring atoms;
m, n are the same or different at each instance and are selected from 0, 1, 2 or 3;
p, q are the same or different at each instance and are 0, 1, 2, 3 or 4.

Furthermore, the following definitions of chemical groups apply for the purposes of the present application:

An aryl group in the sense of this invention contains 6 to 60 aromatic ring atoms, preferably 6 to 40 aromatic ring atoms, more preferably 6 to 20 aromatic ring atoms; a heteroaryl group in the sense of this invention contains 5 to 60 aromatic ring atoms, preferably 5 to 40 aromatic ring atoms, more preferably 5 to 20 aromatic ring atoms, at least one of which is a heteroatom. The heteroatoms are preferably selected from N, O and S. This represents the basic definition. If other preferences are indicated in the description of the present invention, for example with respect to the number of aromatic ring atoms or the heteroatoms present, these apply.

An aryl group or heteroaryl group here is taken to mean either a simple aromatic ring, i.e. benzene, or a simple heteroaromatic ring, for example pyridine, pyrimidine or thiophene, or a condensed (annellated) aromatic or heteroaromatic polycycle, for example naphthalene, phenanthrene, quinoline or carbazole. A condensed (annellated) aromatic or heteroaromatic polycycle in the sense of the present application consists of two or more simple aromatic or heteroaromatic rings condensed with one another.

An aryl or heteroaryl group, which may in each case be substituted by the above-mentioned radicals and which may be linked to the aromatic or heteroaromatic ring system via any desired positions, is taken to mean, in particular, groups derived from benzene, naphthalene, anthracene, phenanthrene, pyrene, dihydropyrene, chrysene, perylene, fluoranthene, benzanthracene, benzophenanthrene, tetracene, pentacene, benzopyrene, furan, benzofuran, isobenzofuran, dibenzofuran, thiophene, benzothiophene, isobenzothiophene, dibenzothiophene, pyrrole, indole, isoindole, carbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthimidazole, phenanthrimidazole, pyridimidazole, pyrazinimidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, benzopyridazine, pyrimidine, benzopyrimidine, quinoxaline, pyrazine, phenazine, naphthyridine, azacarbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine and benzothiadiazole.

An aryloxy group in accordance with the definition of the present invention is taken to mean an aryl group, as defined above, which is bonded via an oxygen atom. An analogous definition applies to heteroaryloxy groups.

An aromatic ring system in the sense of this invention contains 6 to 60 C atoms in the ring system, preferably 6 to 40 C atoms, more preferably 6 to 20 C atoms. A heteroaromatic ring system in the sense of this invention contains 5 to 60 aromatic ring atoms, preferably 5 to 40 aromatic ring atoms, more preferably 5 to 20 aromatic ring atoms, at least one of which is a heteroatom. The heteroatoms are preferably selected from N, O and/or S. An aromatic or heteroaromatic ring system in the sense of this invention is intended to be taken to mean a system which does not necessarily contain only aryl or heteroaryl groups, but instead in which, in addition, a plurality of aryl or heteroaryl groups may be connected by a non-aromatic unit (preferably less than 10% of the atoms other than H), such as, for example, an sp³-hybridised C, Si, N or O atom, an sp²-hybridised C or N atom or an sp-hybridised C atom. Thus, for example, systems such as 9,9′-spirobifluorene, 9,9′-diarylfluorene, triarylamine, diaryl ether, stilbene, etc., are also intended to be taken to be aromatic ring systems in the sense of this invention, as are systems in which two or more aryl groups are connected, for example, by a linear or cyclic alkyl, alkenyl or alkynyl group or by a silyl group. Furthermore, systems in which two or more aryl or heteroaryl groups are linked to one another via single bonds are also taken to be aromatic or heteroaromatic ring systems in the sense of this invention, such as, for example, systems such as biphenyl, terphenyl or diphenyltriazine.

An aromatic or heteroaromatic ring system having 5-60 aromatic ring atoms, which may in each case also be substituted by radicals as defined above and which may be linked to the aromatic or heteroaromatic group via any desired positions, is taken to mean, in particular, groups derived from benzene, naphthalene, anthracene, benzanthracene, phenanthrene, benzophenanthrene, pyrene, chrysene, perylene, fluoranthene, naphthacene, pentacene, benzopyrene, biphenyl, biphenylene, terphenyl, terphenylene, quaterphenyl, fluorene, spirobifluorene, dihydrophenanthrene, dihydropyrene, tetrahydropyrene, cis- or trans-indenofluorene, truxene, isotruxene, spirotruxene, spiroisotruxene, furan, benzofuran, isobenzofuran, dibenzofuran, thiophene, benzothiophene, isobenzothiophene, dibenzothiophene, pyrrole, indole, isoindole, carbazole, indolocarbazole, indenocarbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthimidazole, phenanthrimidazole, pyridimidazole, pyrazinimidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, benzopyridazine, pyrimidine, benzopyrimidine, quinoxaline, 1,5-diazaanthracene, 2,7-diazapyrene, 2,3-diazapyrene, 1,6-diazapyrene, 1,8-diazapyrene, 4,5-diazapyrene, 4,5,9,10-tetraazaperylene, pyrazine, phenazine, phenoxazine, phenothiazine, fluorubin, naphthyridine, azacarbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine and benzothiadiazole, or combinations of these groups.

For the purposes of the present invention, a straight-chain alkyl group having 1 to 40 C atoms or a branched or cyclic alkyl group having 3 to 40 C atoms or an alkenyl or alkynyl group having 2 to 40 C atoms, in which, in addition, individual H atoms or CH₂ groups may be substituted by the groups mentioned above under the definition of the radicals, is preferably taken to mean the radicals methyl, ethyl, n-propyl, i-propyl, n-butyl, i-butyl, s-butyl, t-butyl, 2-methylbutyl, n-pentyl, s-pentyl, cyclopentyl, neopentyl, n-hexyl, cyclohexyl, neohexyl, n-heptyl, cycloheptyl, n-octyl, cyclooctyl, 2-ethylhexyl, trifluoromethyl, pentafluoroethyl, 2,2,2-trifluoroethyl, ethenyl, propenyl, butenyl, pentenyl, cyclopentenyl, hexenyl, cyclohexenyl, heptenyl, cycloheptenyl, octenyl, cyclooctenyl, ethynyl, propynyl, butynyl, pentynyl, hexynyl or octynyl. An alkoxy or thioalkyl group having 1 to 40 C atoms is preferably taken to mean methoxy, trifluoromethoxy, ethoxy, n-propoxy, i-propoxy, n-butoxy, i-butoxy, s-butoxy, t-butoxy, n-pentoxy, s-pentoxy, 2-methylbutoxy, n-hexoxy, cyclohexyloxy, n-heptoxy, cyclo-heptyloxy, n-octyloxy, cyclooctyloxy, 2-ethylhexyloxy, pentafluoroethoxy, 2,2,2-tri-fluoroethoxy, methylthio, ethylthio, n-propylthio, i-propylthio, n-butylthio, i-butylthio, s-butylthio, t-butylthio, n-pentylthio, s-pentylthio, n-hexylthio, cyclohexylthio, n-heptylthio, cycloheptylthio, n-octylthio, cyclooctylthio, 2-ethylhexylthio, trifluoromethylthio, pentafluoro-ethylthio, 2,2,2-trifluoroethylthio, ethenylthio, propenylthio, butenylthio, pentenylthio, cyclo-pentenylthio, hexenylthio, cyclohexenylthio, heptenylthio, cycloheptenylthio, octenylthio, cyclooctenylthio, ethynylthio, propynylthio, butynylthio, pentynylthio, hexynylthio, heptynyl-thio or octynylthio.

The formulation that two radicals may form a ring with one another is, for the purposes of the present application, intended to be taken to mean, inter alia, that the two radicals are linked to one another by a chemical bond. This is illustrated by the following schemes:

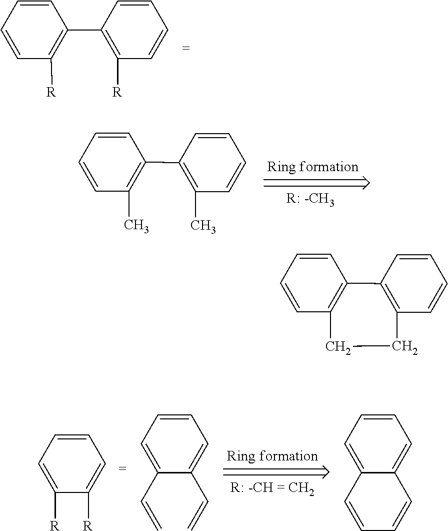

Furthermore, however, the above-mentioned formulation is also intended to be taken to mean that, in the case where one of the two radicals represents hydrogen, the second radical is bonded at the position to which the hydrogen atom was bonded, with formation of a ring. This is illustrated by the following scheme:

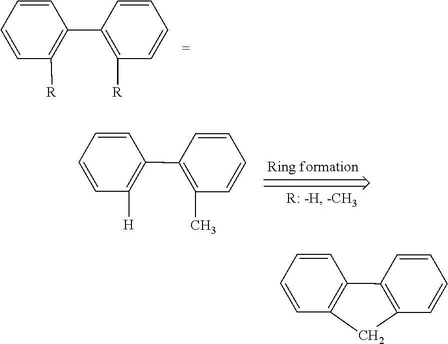

When two radicals form a ring with one another, then it is preferred that the two radicals are adjacent radicals. Adjacent radicals in the sense of the present invention are radicals which are bonded to atoms which are linked directly to one another or which are bonded to the same atom.

Preferably, E⁰ stands for on each occurrence, identically or differently, for NR^{N} or O.

Preferably, the three groups X¹, X², X³ stand for N.

Preferably, L¹, L² stand on each occurrence, identically or differently, for a single bond or for an aromatic or heteroaromatic ring system having 6 to 18 aromatic ring atoms, which may be substituted by one or more radicals R. Examples of suitable aromatic or heteroaromatic ring systems having 6 to 18 aromatic ring atoms for L¹ and L² are benzene, naphthalene, biphenyl, fluorene, spirobifluorene, dibenzofuran, dibenzothiophene, carbazole, carboline and xanthene, which may be substituted by one or more radicals R.

Preferably, the at least one electron-transporting host material in the composition is selected from the compounds of formulae (1A), (2A) or (3A);

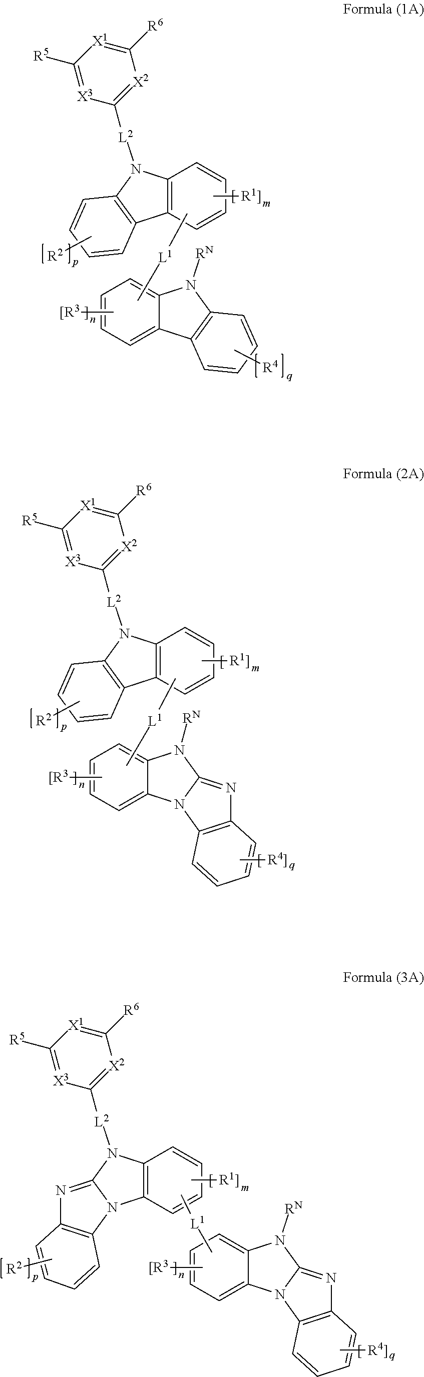

where the symbols and indices have the same meaning as above.

More preferably, the at least one electron-transporting host material is selected from the compounds of formulae (1B), (2B) or (3B);

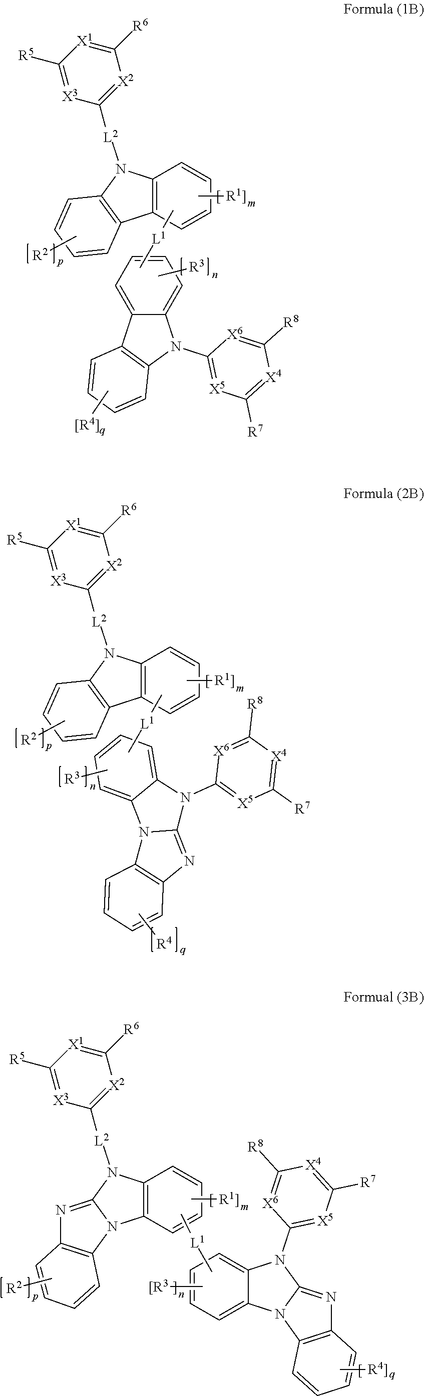

where
X⁴, X⁵, X⁶ stand, on each occurrence identically or differently, for a group CR^{X} or N; where R^{X} has the same meaning as above, and with the proviso that at least one group selected from X⁴, X⁵ and X⁶ stands for N;
R⁷, R⁸ stand on each occurrence, identically or differently, for a radical selected from H, D, F, Cl, Br, I, CHO, CN, C(═O)Ar, P(═O)(Ar)₂, S(═O)Ar, S(═O)₂Ar, N(R)₂, N(Ar)₂, NO₂, Si(R)₃, B(OR)₂, OSO₂R, a straight-chain alkyl, alkoxy or thioalkyl group having 1 to 40 C atoms or branched or a cyclic alkyl, alkoxy or thioalkyl group having 3 to 40 C atoms, each of which may be substituted by one or more radicals R, where in each case one or more non-adjacent CH₂ groups may be replaced by RC═CR, C≡C, Si(R)₂, Ge(R)₂, Sn(R)₂, C═O, C═S, C═Se, P(═O)(R), SO, SO₂, O, S or CONR and where one or more H atoms may be replaced by D, F, Cl, Br, I, CN or NO₂, an aromatic or heteroaromatic ring system having 5 to 60 aromatic ring atoms, which may in each case be substituted by one or more radicals R, and an aryloxy group having 5 to 60 aromatic ring atoms, which may be substituted by one or more radicals R;
and where the other symbols and indices have the same meaning as above.

Even more preferably, the at least one electron-transporting host material is selected from the compounds of formulae (1C), (2C) or (3C);

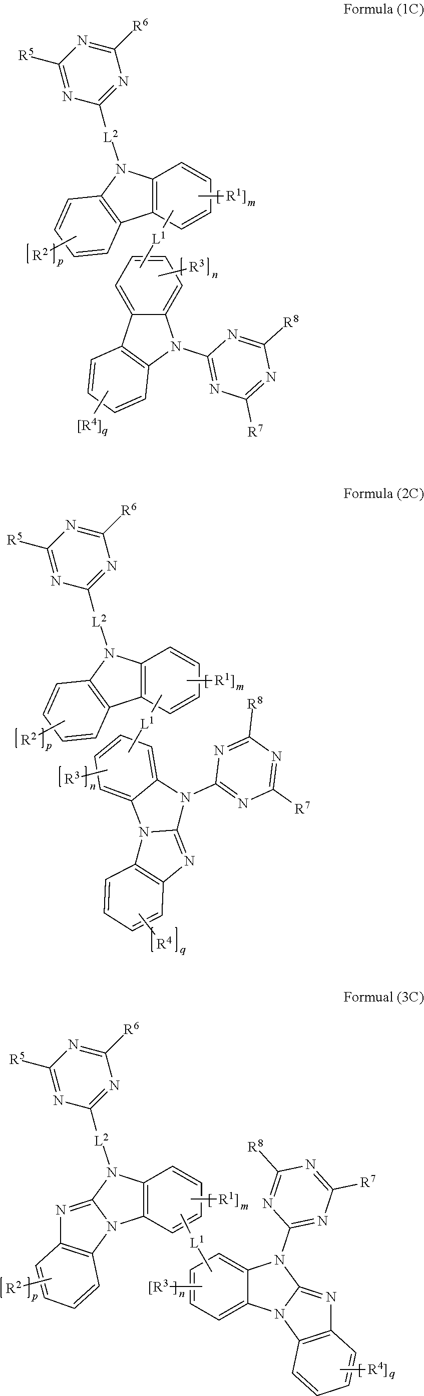

where the other symbols and indices have the same meaning as in above.

Particularly preferably, the at least one electron-transporting host material is selected from the compounds of formulae (1D), (2D) or (3D);

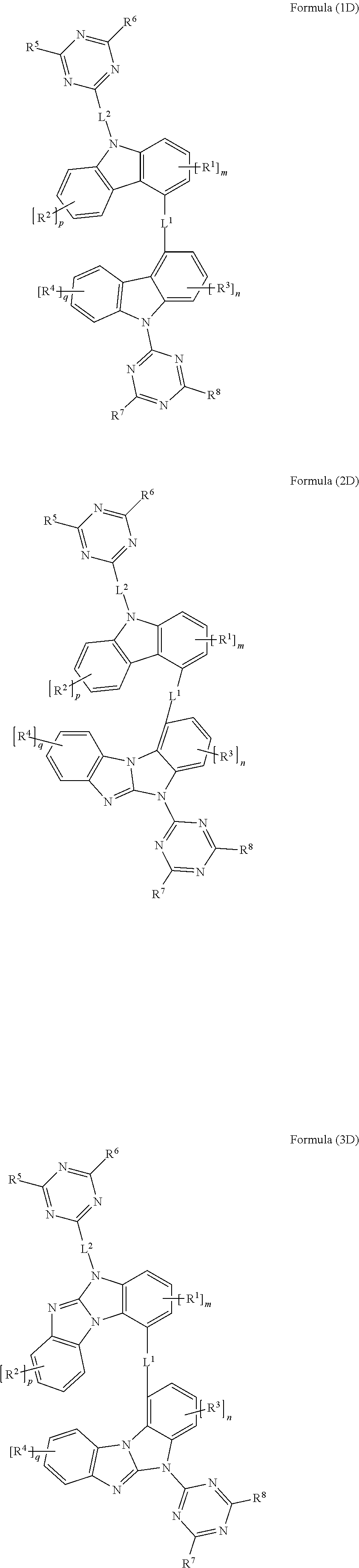

where the symbols and indices have the same meaning as above.

Preferably R^{X}, R¹, R², R³, R⁴, R⁵, R⁶ stand on each occurrence, identically or differently, for H, D, F, a straight-chain alkyl, alkoxy or thioalkyl group having 1 to 40, preferably 1 to 20, more preferably 1 to 10 C atoms or branched or a cyclic alkyl, alkoxy or thioalkyl group having 3 to 40, preferably 3 to 20, more preferably 3 to 10 C atoms, each of which may be substituted by one or more radicals R, where in each case one or more non-adjacent CH₂ groups may be replaced by RC═CR, C≡C, O or S and where one or more H atoms may be replaced by D or F, an aromatic or heteroaromatic ring system having 5 to 60, preferably 5 to 40, more preferably 5 to 30, particularly preferably 5 to 18 aromatic ring atoms, which may in each case be substituted by one or more radicals R.

More preferably, R^{X}, R¹, R², R³, R⁴ stand on each occurrence, identically or differently, for H, D, F, a straight-chain alkyl group having 1 to 20, preferably 1 to 10, more preferably 1 to 6 C atoms or branched or a cyclic alkyl group having 3 to 20, preferably 3 to 10, more preferably 3 to 6 C atoms, each of which may be substituted by one or more radicals R, an aromatic or heteroaromatic ring system having 5 to 40, preferably 5 to 30, more preferably 5 to 18 aromatic ring atoms, which may in each case be substituted by one or more radicals R.

More preferably R⁵, R⁶ stand on each occurrence, identically or differently, for an aromatic or heteroaromatic ring system having 5 to 60, preferably 5 to 40, more preferably 5 to 30, particularly preferably 5 to 18 aromatic ring atoms, which may in each case be substituted by one or more radicals R.

Particularly preferably, R^{X}, R¹, R², R³, R⁴ stand on each occurrence, identically or differently, for H, D, a straight-chain alkyl group having 1 to 10, preferably 1 to 6 C atoms or branched or a cyclic alkyl group having 3 to 10, preferably 3 to 6 C atoms, each of which may be substituted by one or more radicals R, or an aromatic or heteroaromatic ring system having 5 to 18 aromatic ring atoms, preferably 6 to 12 aromatic ring atoms, which may in each case be substituted by one or more radicals R.

Particularly preferably R⁵, R⁶ stand on each occurrence, identically or differently, for an aryl or heteroaryl group having 6 to 18 aromatic ring atoms, which may in each case be substituted by one or more radicals R.

Very particularly preferably, R^{X}, R¹, R², R³, R⁴ stand for H or D.

Preferably, R^{C} stand on each occurrence, identically or differently, for a radical selected from H, D, a straight-chain alkyl group having 1 to 10, preferably 1 to 6, more preferably 1 to 3 C atoms, which may be substituted by one or more radicals R, an aryl or heteroaryl group having 6 to 18, preferably 6 to 12 aromatic ring atoms, which may in each case be substituted by one or more radicals R; where two radicals R^{C} may form an aliphatic, aromatic or heteroaromatic ring system together, which may be substituted by one or more radicals R.

Preferably, R^{N} stand on each occurrence, identically or differently, for a radical selected from an aromatic or heteroaromatic ring system having 5 to 60, preferably 5 to 40, more preferably 5 to 30, particularly preferably 5 to 18 aromatic ring atoms aromatic ring atoms, which may in each case be substituted by one or more radicals R.

More preferably, R^{N} stand on each occurrence, identically or differently, for a radical selected from an aryl or heteroaryl group having 6 to 18 aromatic ring atoms, and which may in each case be substituted by one or more radicals R. Examples of particularly suitable groups R^{N} are are benzene, fluorene, spirobifluorene, dibenzofuran, dibenzothiophene, carbazole, carboline, xanthene, pyridine, pyrimidine, pyrazine and triazine, which may be substituted by one or more radicals R. Very particularly suitable groups R^{N} are are pyridine, pyrimidine, and triazine, which may be substituted by one or more radicals R, where R is an aryl or heteroaryl group having 6 to 18 aromatic ring atoms.

Preferably, R stands on each occurrence, identically or differently, for H, D, F, CN, N(Ar)₂, a straight-chain alkyl, alkoxy or thioalkyl group having 1 to 40, preferably 1 to 20, more preferably 1 to 10 C atoms or a branched or a cyclic alkyl, alkoxy or thioalkyl group having 3 to 40, preferably 3 to 20, more preferably 3 to 10 C atoms, each of which may be substituted by one or more radicals R′, and where one or more H atoms may be replaced by D, F, CN, or an aromatic or heteroaromatic ring system having 5 to 60, preferably 5 to 40, more preferably 5 to 30, even more preferably 6 to 18 aromatic ring atoms, which may in each case be substituted by one or more radicals R′.

Preferably, Ar is, on each occurrence, identically or differently, an aromatic or heteroaromatic ring system having 5 to 60, preferably 5 to 40, more preferably 5 to 30, even more preferably 6 to 18 aromatic ring atoms, which may in each case also be substituted by one or more radicals R′;

Preferably, R′ stands on each occurrence, identically or differently, for H, D, F, CN, a straight-chain alkyl, alkoxy or thioalkyl group having 1 to 10 C atoms or branched or cyclic alkyl, alkoxy or thioalkyl group having 3 to 10 C atoms, or an aromatic or heteroaromatic ring system having 6 to 18 aromatic ring atoms.

Suitable examples of electron-transporting host materials of formulae (1), (2) or (3) are depicted in the following table:

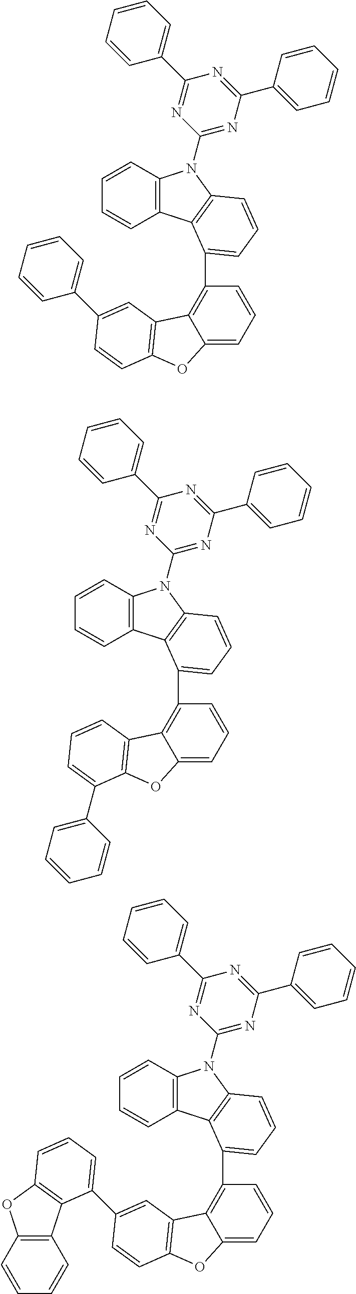

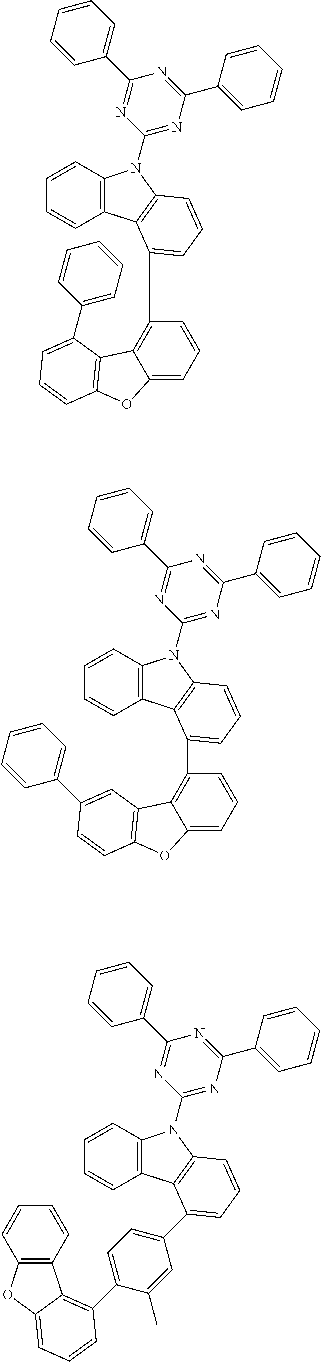 [SMILES: c1ccc(-c2nc(-c3ccccc3)nc(-n3c4ccccc4c4c(-c5cccc6oc7cccc(-c8ccccc8)c7c56)cccc43)n2)cc1 ; c1ccc(-c2ccc3oc4cccc(-c5cccc6c5c5ccccc5n6-c5nc(-c6ccccc6)nc(-c6ccccc6)n5)c4c3c2)cc1 ; Cc1cc(-c2cccc3c2c2ccccc2n3-c2nc(-c3ccccc3)nc(-c3ccccc3)n2)ccc1-c1cccc2oc3ccccc3c12]

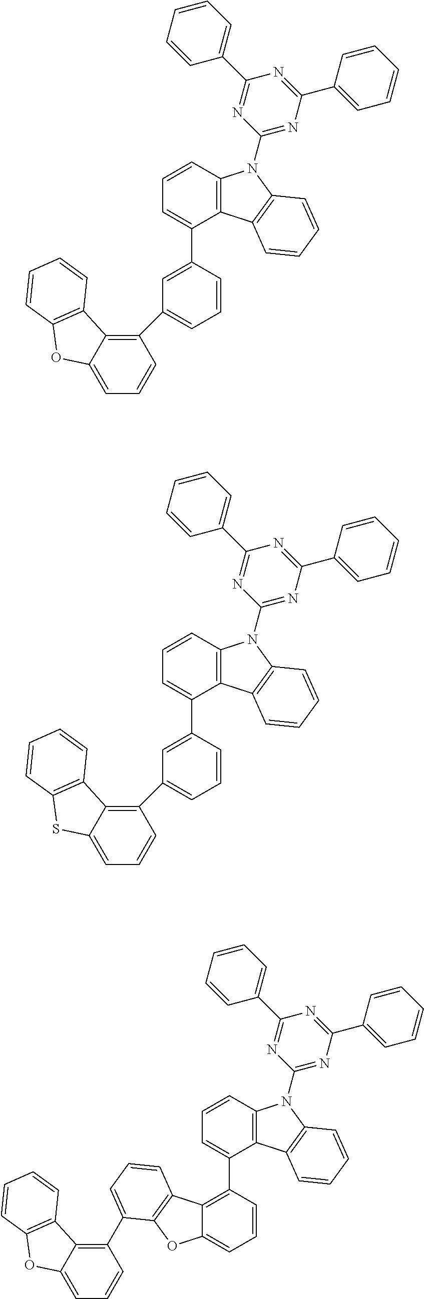 [SMILES: c1ccc(-c2nc(-c3ccccc3)nc(-n3c4ccccc4c4c(-c5cccc(-c6cccc7oc8ccccc8c67)c5)cccc43)n2)cc1 ; c1ccc(-c2nc(-c3ccccc3)nc(-n3c4ccccc4c4c(-c5cccc(-c6cccc7sc8ccccc8c67)c5)cccc43)n2)cc1 ; c1ccc(-c2nc(-c3ccccc3)nc(-n3c4ccccc4c4c(-c5cccc6oc7c(-c8cccc9oc%10ccccc%10c89)cccc7c56)cccc43)n2)cc1]

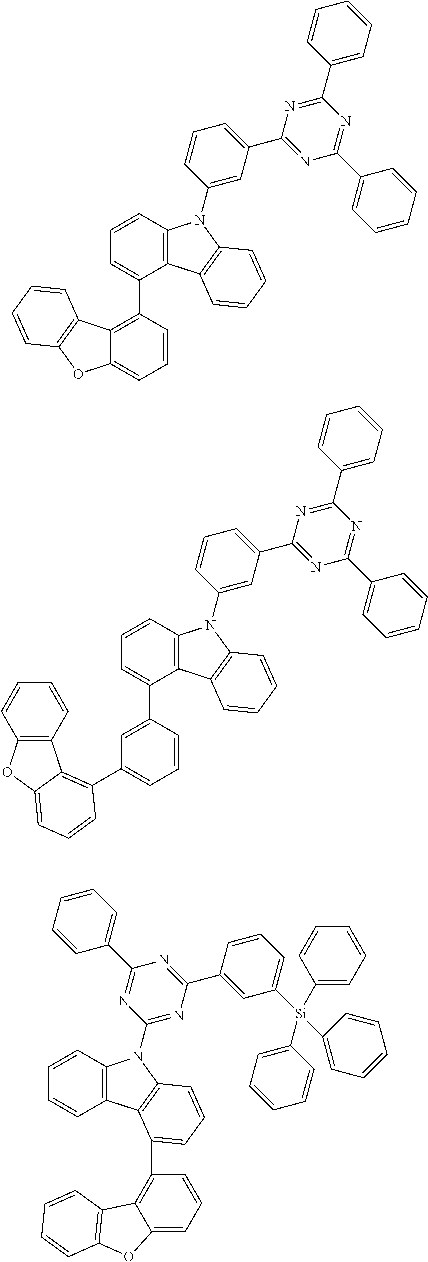 [SMILES: c1ccc(-c2nc(-c3ccccc3)nc(-c3cccc(-n4c5ccccc5c5c(-c6cccc7oc8ccccc8c67)cccc54)c3)n2)cc1 ; c1ccc(-c2nc(-c3ccccc3)nc(-c3cccc(-n4c5ccccc5c5c(-c6cccc(-c7cccc8oc9ccccc9c78)c6)cccc54)c3)n2)cc1 ; c1ccc(-c2nc(-c3cccc([Si](c4ccccc4)(c4ccccc4)c4ccccc4)c3)nc(-n3c4ccccc4c4c(-c5cccc6oc7ccccc7c56)cccc43)n2)cc1]

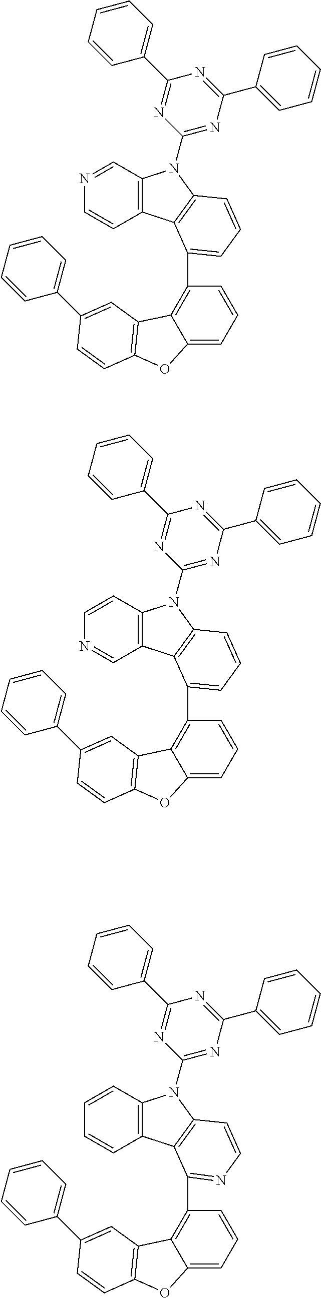 [SMILES: c1ccc(-c2ccc3oc4cccc(-c5cccc6c5c5ccncc5n6-c5nc(-c6ccccc6)nc(-c6ccccc6)n5)c4c3c2)cc1 ; c1ccc(-c2ccc3oc4cccc(-c5cccc6c5c5cnccc5n6-c5nc(-c6ccccc6)nc(-c6ccccc6)n5)c4c3c2)cc1 ; c1ccc(-c2ccc3oc4cccc(-c5nccc6c5c5ccccc5n6-c5nc(-c6ccccc6)nc(-c6ccccc6)n5)c4c3c2)cc1]

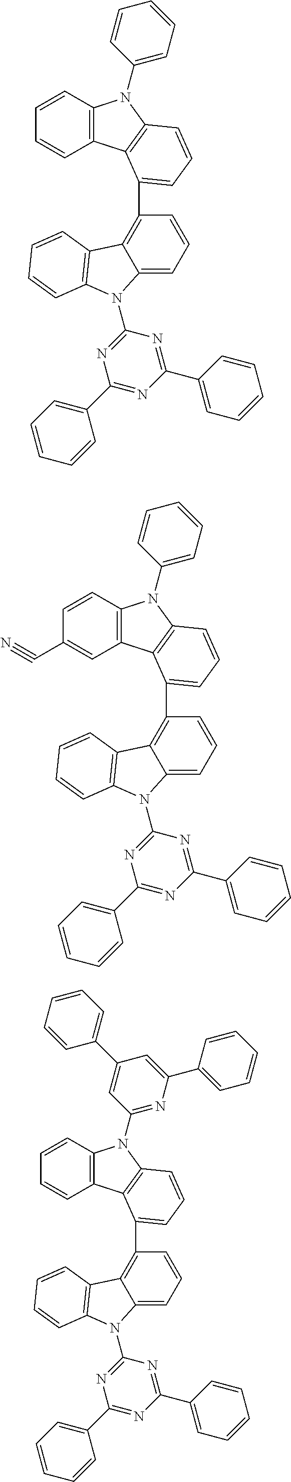

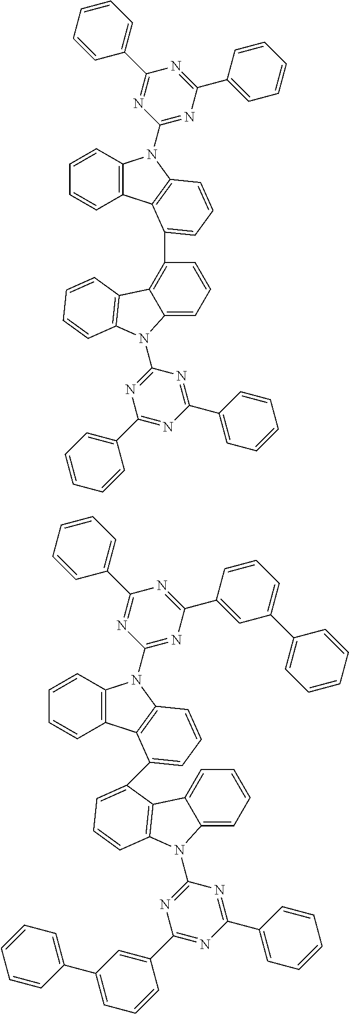

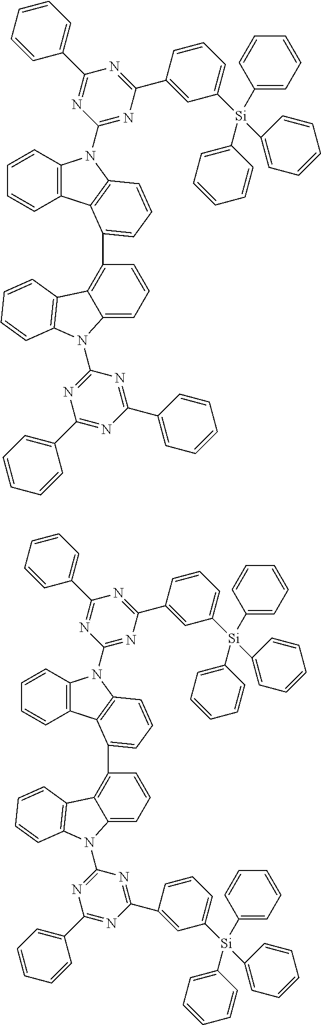 [SMILES: c1ccc(-c2nc(-c3ccccc3)nc(-n3c4ccccc4c4c(-c5cccc6c5c5ccccc5n6-c5nc(-c6ccccc6)nc(-c6cccc([Si](c7ccccc7)(c7ccccc7)c7ccccc7)c6)n5)cccc43)n2)cc1 ; c1ccc(-c2nc(-c3cccc([Si](c4ccccc4)(c4ccccc4)c4ccccc4)c3)nc(-n3c4ccccc4c4c(-c5cccc6c5c5ccccc5n6-c5nc(-c6ccccc6)nc(-c6cccc([Si](c7ccccc7)(c7ccccc7)c7ccccc7)c6)n5)cccc43)n2)cc1]

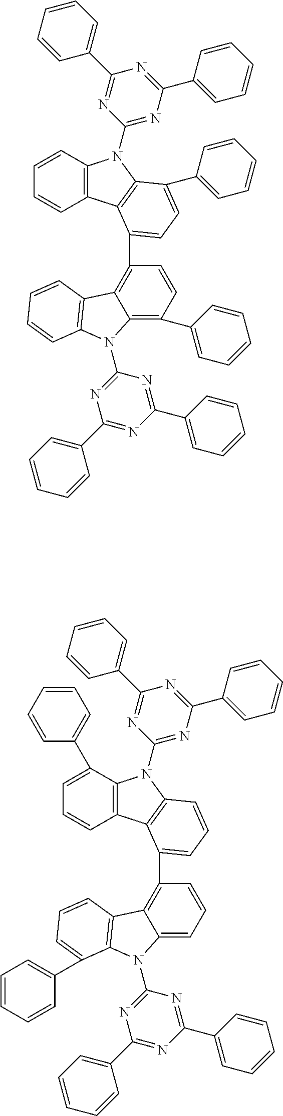 [SMILES: c1ccc(-c2nc(-c3ccccc3)nc(-n3c4ccccc4c4c(-c5ccc(-c6ccccc6)c6c5c5ccccc5n6-c5nc(-c6ccccc6)nc(-c6ccccc6)n5)ccc(-c5ccccc5)c43)n2)cc1 ; c1ccc(-c2nc(-c3ccccc3)nc(-n3c4cccc(-c5cccc6c5c5cccc(-c7ccccc7)c5n6-c5nc(-c6ccccc6)nc(-c6ccccc6)n5)c4c4cccc(-c5ccccc5)c43)n2)cc1]

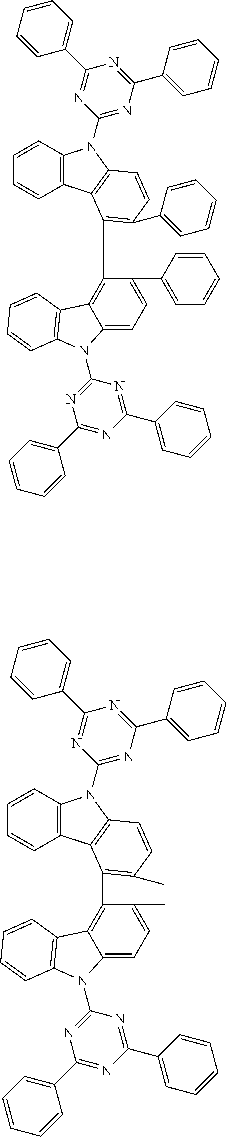 [SMILES: c1ccc(-c2nc(-c3ccccc3)nc(-n3c4ccccc4c4c(-c5c(-c6ccccc6)ccc6c5c5ccccc5n6-c5nc(-c6ccccc6)nc(-c6ccccc6)n5)c(-c5ccccc5)ccc43)n2)cc1 ; Cc1ccc2c(c1-c1c(C)ccc3c1c1ccccc1n3-c1nc(-c3ccccc3)nc(-c3ccccc3)n1)c1ccccc1n2-c1nc(-c2ccccc2)nc(-c2ccccc2)n1]

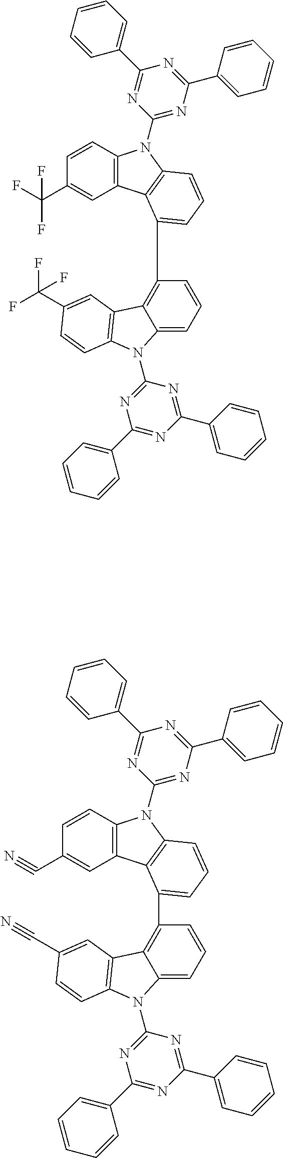 [SMILES: FC(F)(F)c1ccc2c(c1)c1c(-c3cccc4c3c3cc(C(F)(F)F)ccc3n4-c3nc(-c4ccccc4)nc(-c4ccccc4)n3)cccc1n2-c1nc(-c2ccccc2)nc(-c2ccccc2)n1 ; N#Cc1ccc2c(c1)c1c(-c3cccc4c3c3cc(C#N)ccc3n4-c3nc(-c4ccccc4)nc(-c4ccccc4)n3)cccc1n2-c1nc(-c2ccccc2)nc(-c2ccccc2)n1]

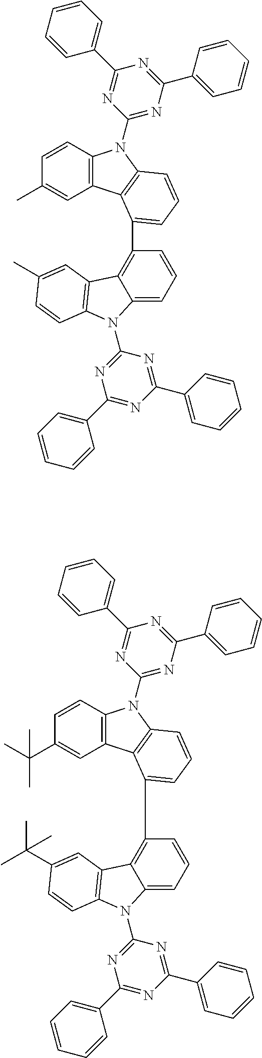 [SMILES: Cc1ccc2c(c1)c1c(-c3cccc4c3c3cc(C)ccc3n4-c3nc(-c4ccccc4)nc(-c4ccccc4)n3)cccc1n2-c1nc(-c2ccccc2)nc(-c2ccccc2)n1 ; CC(C)(C)c1ccc2c(c1)c1c(-c3cccc4c3c3cc(C(C)(C)C)ccc3n4-c3nc(-c4ccccc4)nc(-c4ccccc4)n3)cccc1n2-c1nc(-c2ccccc2)nc(-c2ccccc2)n1]

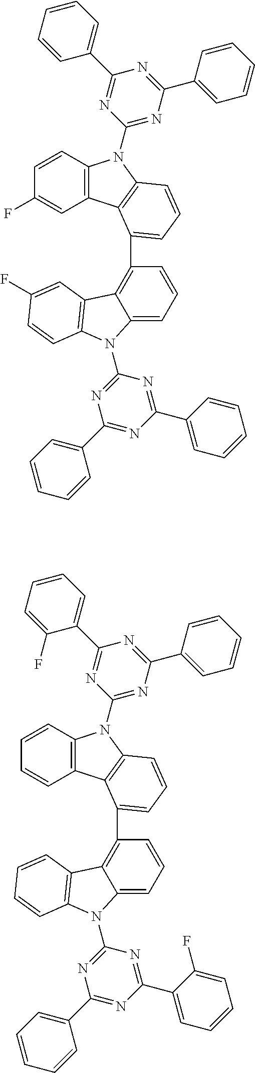 [SMILES: Fc1ccc2c(c1)c1c(-c3cccc4c3c3cc(F)ccc3n4-c3nc(-c4ccccc4)nc(-c4ccccc4)n3)cccc1n2-c1nc(-c2ccccc2)nc(-c2ccccc2)n1 ; Fc1ccccc1-c1nc(-c2ccccc2)nc(-n2c3ccccc3c3c(-c4cccc5c4c4ccccc4n5-c4nc(-c5ccccc5)nc(-c5ccccc5F)n4)cccc32)n1]

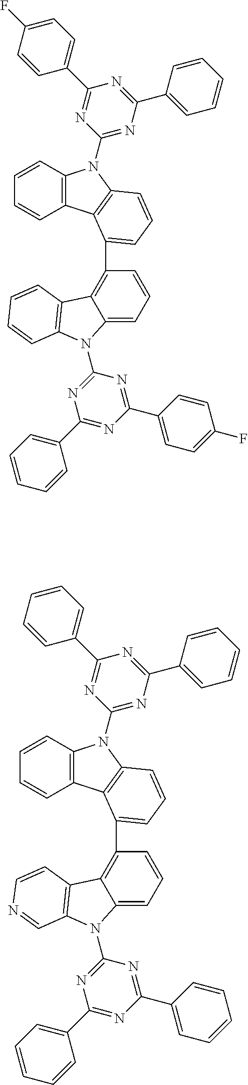 [SMILES: Fc1ccc(-c2nc(-c3ccccc3)nc(-n3c4ccccc4c4c(-c5cccc6c5c5ccccc5n6-c5nc(-c6ccccc6)nc(-c6ccc(F)cc6)n5)cccc43)n2)cc1 ; c1ccc(-c2nc(-c3ccccc3)nc(-n3c4ccccc4c4c(-c5cccc6c5c5ccncc5n6-c5nc(-c6ccccc6)nc(-c6ccccc6)n5)cccc43)n2)cc1]

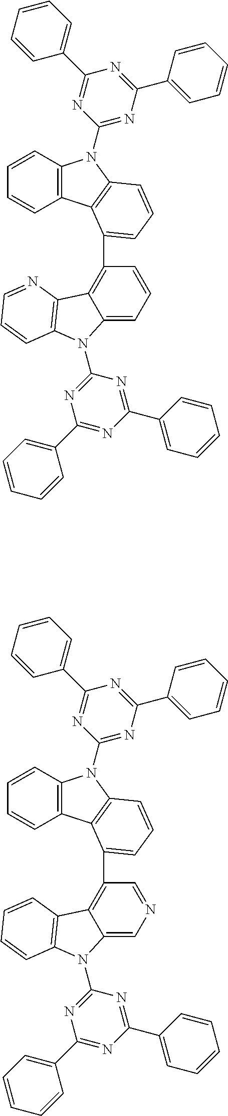 [SMILES: c1ccc(-c2nc(-c3ccccc3)nc(-n3c4ccccc4c4c(-c5cccc6c5c5ncccc5n6-c5nc(-c6ccccc6)nc(-c6ccccc6)n5)cccc43)n2)cc1 ; c1ccc(-c2nc(-c3ccccc3)nc(-n3c4ccccc4c4c(-c5cncc6c5c5ccccc5n6-c5nc(-c6ccccc6)nc(-c6ccccc6)n5)cccc43)n2)cc1]

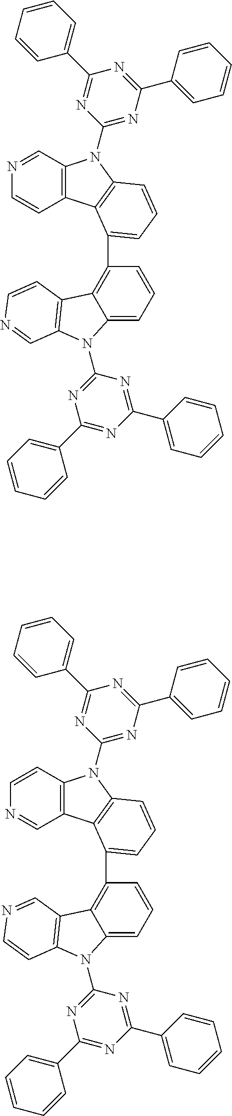 [SMILES: c1ccc(-c2nc(-c3ccccc3)nc(-n3c4cnccc4c4c(-c5cccc6c5c5ccncc5n6-c5nc(-c6ccccc6)nc(-c6ccccc6)n5)cccc43)n2)cc1 ; c1ccc(-c2nc(-c3ccccc3)nc(-n3c4ccncc4c4c(-c5cccc6c5c5cnccc5n6-c5nc(-c6ccccc6)nc(-c6ccccc6)n5)cccc43)n2)cc1]

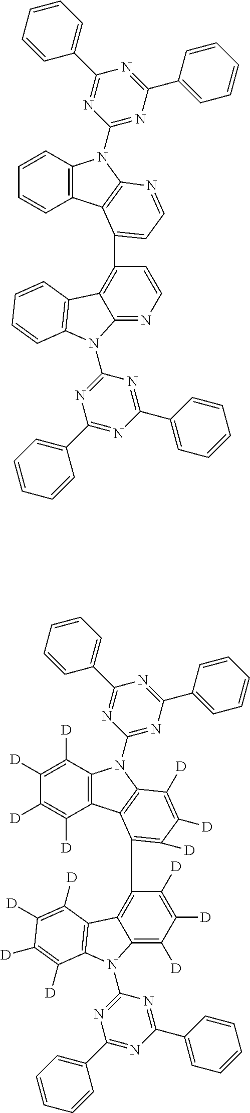 [SMILES: c1ccc(-c2nc(-c3ccccc3)nc(-n3c4ccccc4c4c(-c5ccnc6c5c5ccccc5n6-c5nc(-c6ccccc6)nc(-c6ccccc6)n5)ccnc43)n2)cc1 ; [2H]c1c([2H])c([2H])c2c(c1[2H])c1c(-c3c([2H])c([2H])c([2H])c4c3c3c([2H])c([2H])c([2H])c([2H])c3n4-c3nc(-c4ccccc4)nc(-c4ccccc4)n3)c([2H])c([2H])c([2H])c1n2-c1nc(-c2ccccc2)nc(-c2ccccc2)n1]

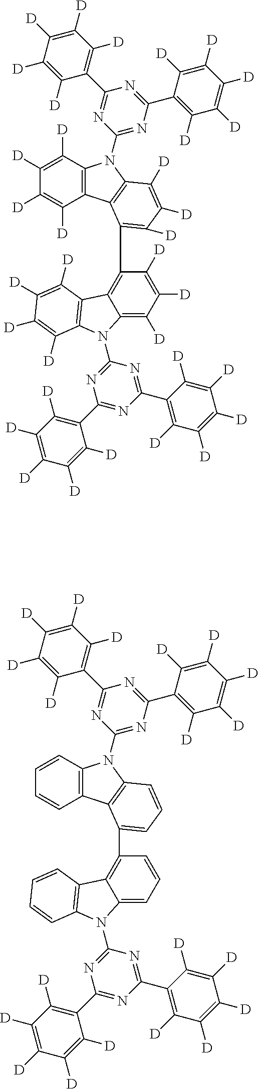

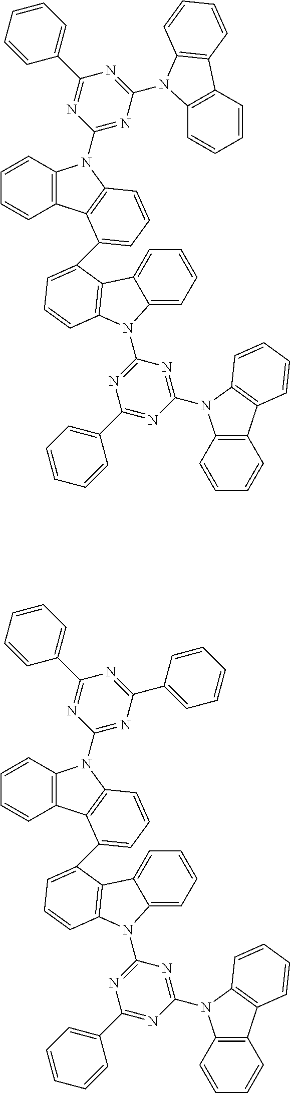 [SMILES: c1ccc(-c2nc(-n3c4ccccc4c4ccccc43)nc(-n3c4ccccc4c4c(-c5cccc6c5c5ccccc5n6-c5nc(-c6ccccc6)nc(-n6c7ccccc7c7ccccc76)n5)cccc43)n2)cc1 ; c1ccc(-c2nc(-c3ccccc3)nc(-n3c4ccccc4c4c(-c5cccc6c5c5ccccc5n6-c5nc(-c6ccccc6)nc(-n6c7ccccc7c7ccccc76)n5)cccc43)n2)cc1]

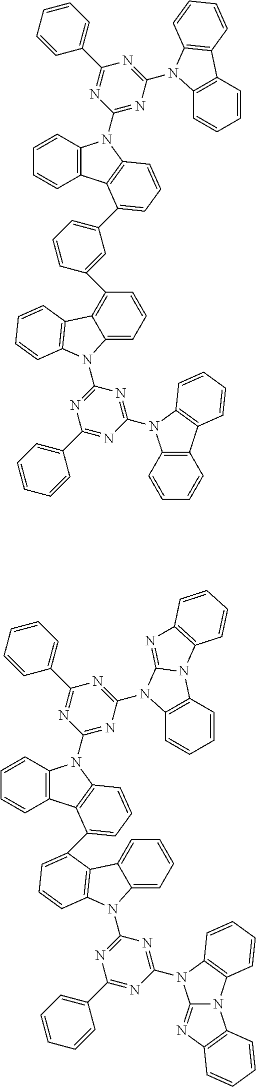 [SMILES: c1ccc(-c2nc(-n3c4ccccc4c4ccccc43)nc(-n3c4ccccc4c4c(-c5cccc(-c6cccc7c6c6ccccc6n7-c6nc(-c7ccccc7)nc(-n7c8ccccc8c8ccccc87)n6)c5)cccc43)n2)cc1 ; c1ccc(-c2nc(-n3c4ccccc4c4c(-c5cccc6c5c5ccccc5n6-c5nc(-c6ccccc6)nc(-n6c7ccccc7n7c8ccccc8nc67)n5)cccc43)nc(-n3c4ccccc4n4c5ccccc5nc34)n2)cc1]

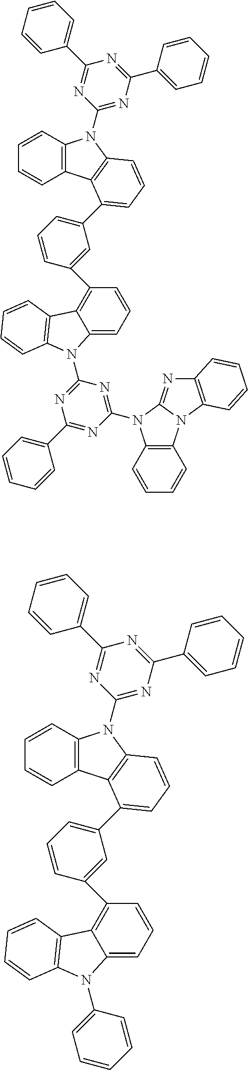 [SMILES: c1ccc(-c2nc(-c3ccccc3)nc(-n3c4ccccc4c4c(-c5cccc(-c6cccc7c6c6ccccc6n7-c6nc(-c7ccccc7)nc(-n7c8ccccc8n8c9ccccc9nc78)n6)c5)cccc43)n2)cc1 ; c1ccc(-c2nc(-c3ccccc3)nc(-n3c4ccccc4c4c(-c5cccc(-c6cccc7c6c6ccccc6n7-c6ccccc6)c5)cccc43)n2)cc1]

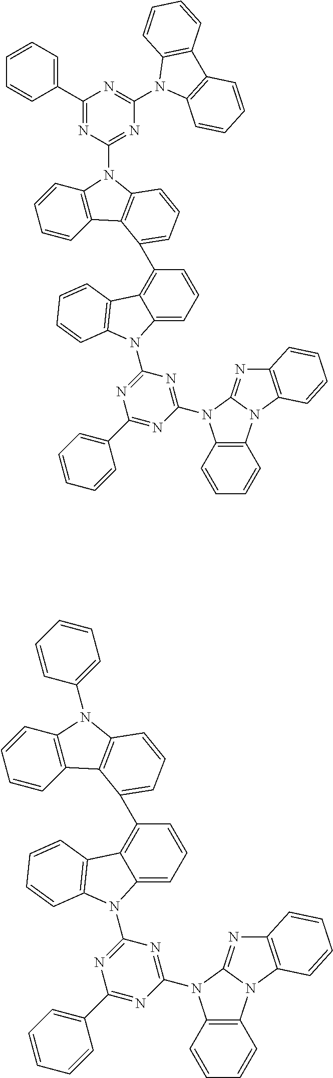 [SMILES: c1ccc(-c2nc(-n3c4ccccc4c4ccccc43)nc(-n3c4ccccc4c4c(-c5cccc6c5c5ccccc5n6-c5nc(-c6ccccc6)nc(-n6c7ccccc7n7c8ccccc8nc67)n5)cccc43)n2)cc1 ; c1ccc(-c2nc(-n3c4ccccc4c4c(-c5cccc6c5c5ccccc5n6-c5ccccc5)cccc43)nc(-n3c4ccccc4n4c5ccccc5nc34)n2)cc1]

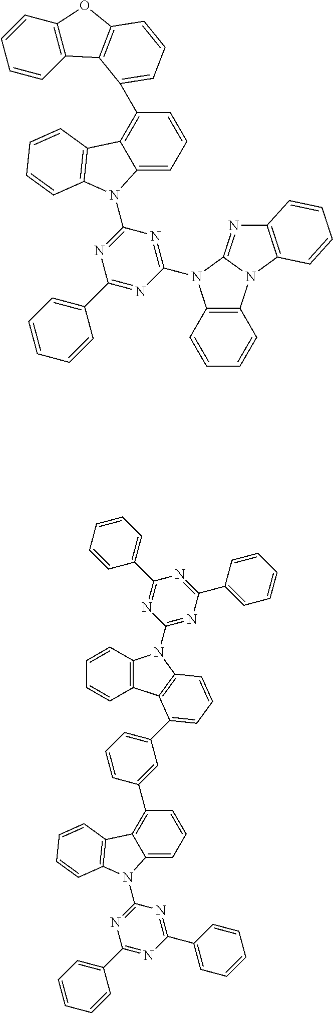 [SMILES: c1ccc(-c2nc(-n3c4ccccc4c4c(-c5cccc6oc7ccccc7c56)cccc43)nc(-n3c4ccccc4n4c5ccccc5nc34)n2)cc1 ; c1ccc(-c2nc(-c3ccccc3)nc(-n3c4ccccc4c4c(-c5cccc(-c6cccc7c6c6ccccc6n7-c6nc(-c7ccccc7)nc(-c7ccccc7)n6)c5)cccc43)n2)cc1]

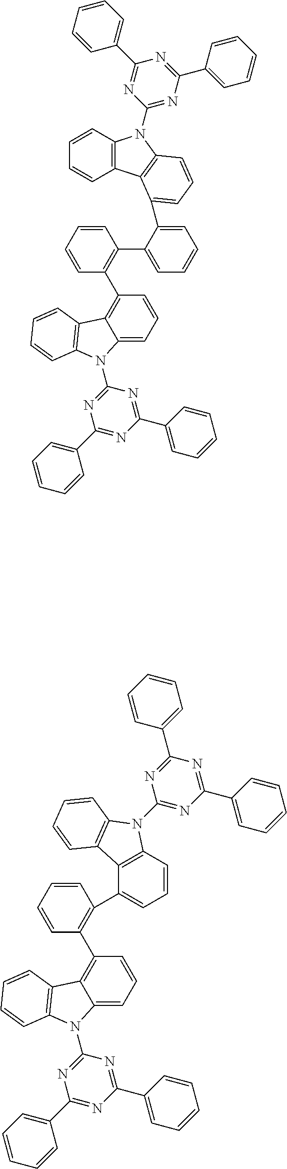 [SMILES: c1ccc(-c2nc(-c3ccccc3)nc(-n3c4ccccc4c4c(-c5ccccc5-c5ccccc5-c5cccc6c5c5ccccc5n6-c5nc(-c6ccccc6)nc(-c6ccccc6)n5)cccc43)n2)cc1 ; c1ccc(-c2nc(-c3ccccc3)nc(-n3c4ccccc4c4c(-c5ccccc5-c5cccc6c5c5ccccc5n6-c5nc(-c6ccccc6)nc(-c6ccccc6)n5)cccc43)n2)cc1]

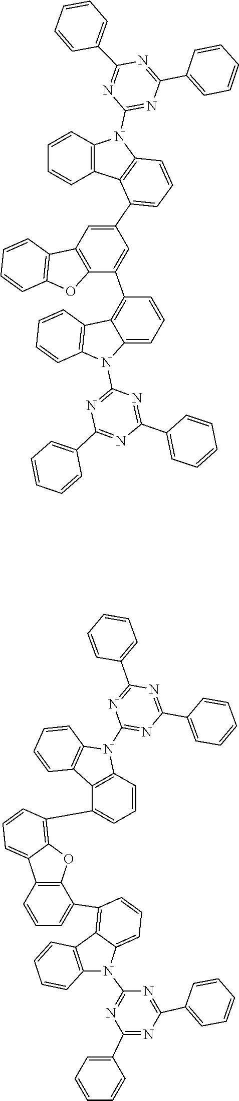 [SMILES: c1ccc(-c2nc(-c3ccccc3)nc(-n3c4ccccc4c4c(-c5cc(-c6cccc7c6c6ccccc6n7-c6nc(-c7ccccc7)nc(-c7ccccc7)n6)c6oc7ccccc7c6c5)cccc43)n2)cc1 ; c1ccc(-c2nc(-c3ccccc3)nc(-n3c4ccccc4c4c(-c5cccc6c5oc5c(-c7cccc8c7c7ccccc7n8-c7nc(-c8ccccc8)nc(-c8ccccc8)n7)cccc56)cccc43)n2)cc1]

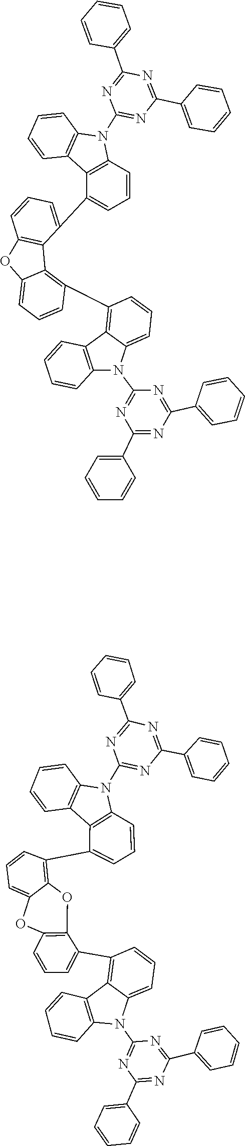 [SMILES: c1ccc(-c2nc(-c3ccccc3)nc(-n3c4ccccc4c4c(-c5cccc6oc7cccc(-c8cccc9c8c8ccccc8n9-c8nc(-c9ccccc9)nc(-c9ccccc9)n8)c7c56)cccc43)n2)cc1 ; c1ccc(-c2nc(-c3ccccc3)nc(-n3c4ccccc4c4c(-c5cccc6c5Oc5c(cccc5-c5cccc7c5c5ccccc5n7-c5nc(-c7ccccc7)nc(-c7ccccc7)n5)O6)cccc43)n2)cc1]

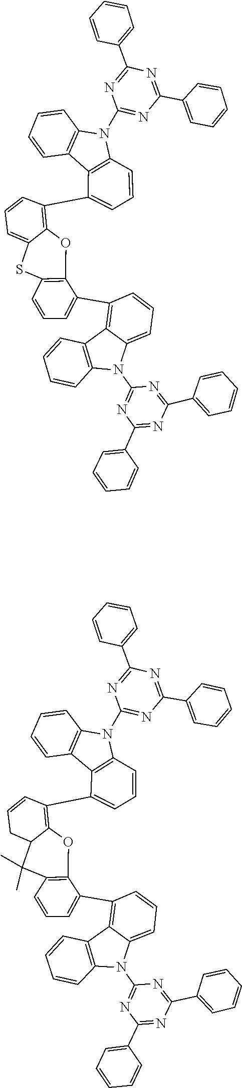 [SMILES: c1ccc(-c2nc(-c3ccccc3)nc(-n3c4ccccc4c4c(-c5cccc6c5Oc5c(cccc5-c5cccc7c5c5ccccc5n7-c5nc(-c7ccccc7)nc(-c7ccccc7)n5)S6)cccc43)n2)cc1 ; CC1(C)c2cccc(-c3cccc4c3c3ccccc3n4-c3nc(-c4ccccc4)nc(-c4ccccc4)n3)c2OC2=C(c3cccc4c3c3ccccc3n4-c3nc(-c4ccccc4)nc(-c4ccccc4)n3)C=CCC21]

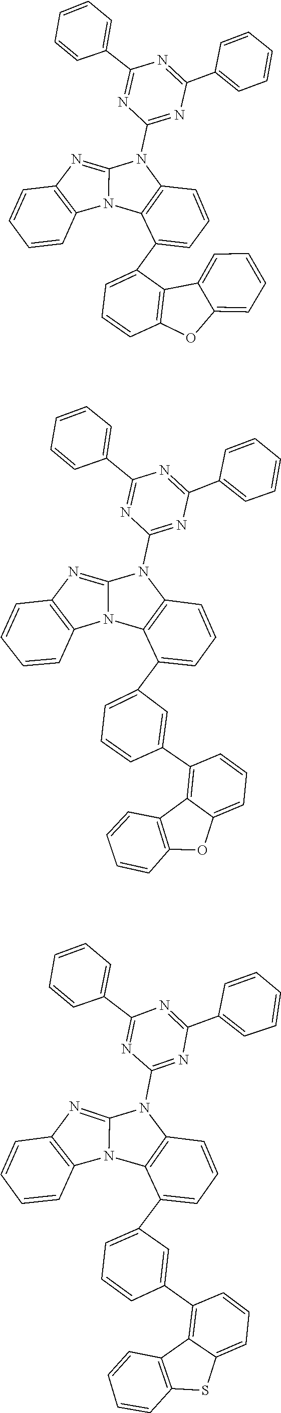 [SMILES: c1ccc(-c2nc(-c3ccccc3)nc(-n3c4cccc(-c5cccc6oc7ccccc7c56)c4n4c5ccccc5nc34)n2)cc1 ; c1ccc(-c2nc(-c3ccccc3)nc(-n3c4cccc(-c5cccc(-c6cccc7oc8ccccc8c67)c5)c4n4c5ccccc5nc34)n2)cc1 ; c1ccc(-c2nc(-c3ccccc3)nc(-n3c4cccc(-c5cccc(-c6cccc7sc8ccccc8c67)c5)c4n4c5ccccc5nc34)n2)cc1]

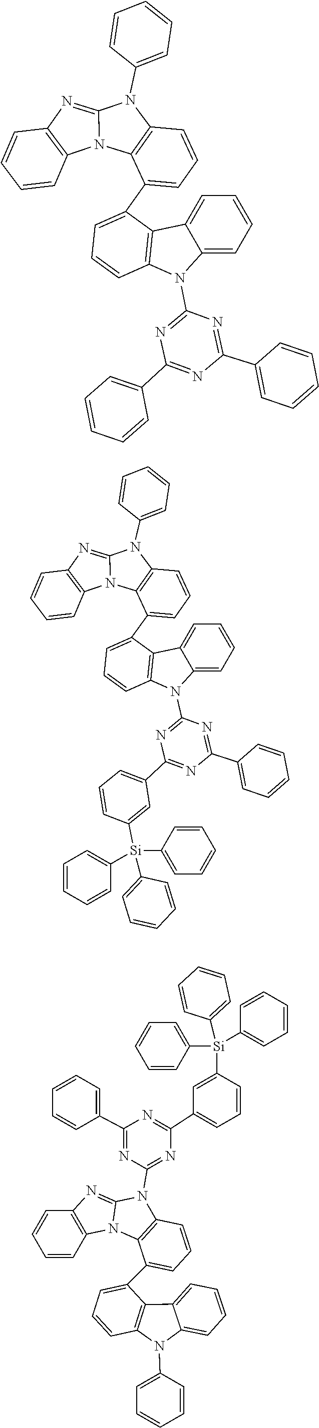

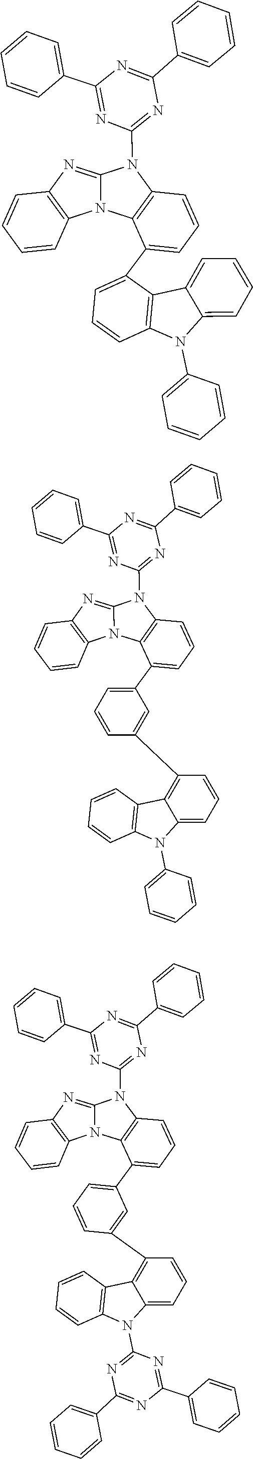

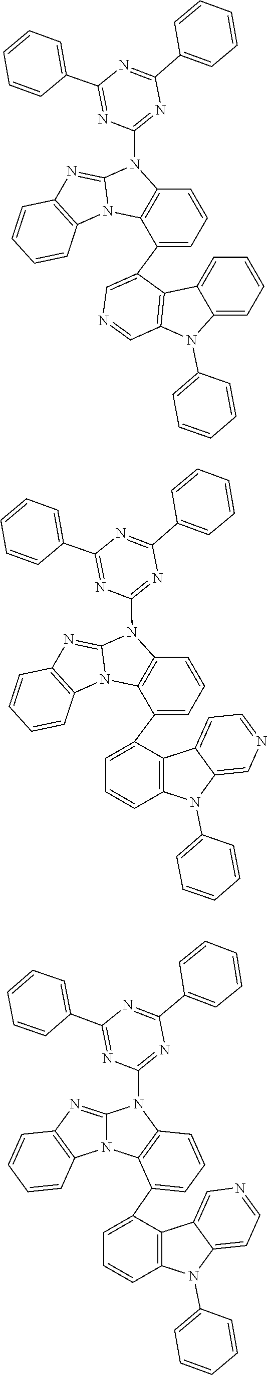

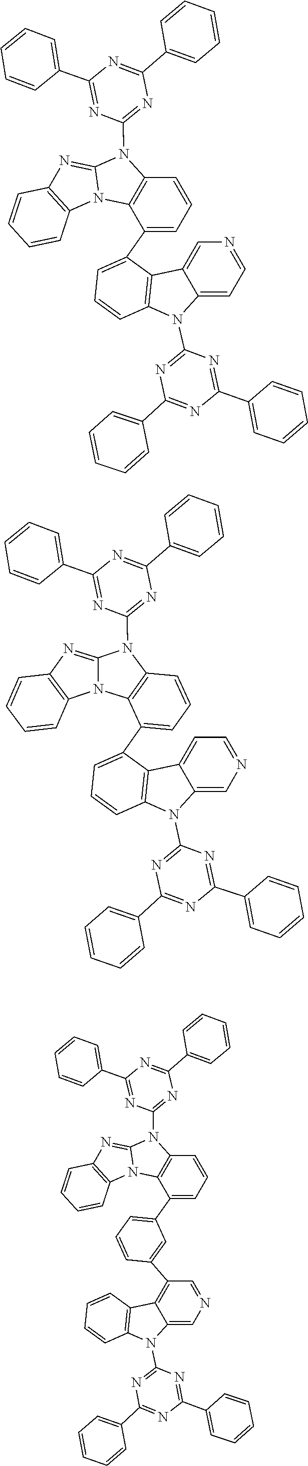 [SMILES: c1ccc(-c2nc(-c3ccccc3)nc(-n3c4ccncc4c4c(-c5cccc6c5n5c7ccccc7nc5n6-c5nc(-c6ccccc6)nc(-c6ccccc6)n5)cccc43)n2)cc1 ; c1ccc(-c2nc(-c3ccccc3)nc(-n3c4cnccc4c4c(-c5cccc6c5n5c7ccccc7nc5n6-c5nc(-c6ccccc6)nc(-c6ccccc6)n5)cccc43)n2)cc1 ; c1ccc(-c2nc(-c3ccccc3)nc(-n3c4ccccc4c4c(-c5cccc(-c6cccc7c6n6c8ccccc8nc6n7-c6nc(-c7ccccc7)nc(-c7ccccc7)n6)c5)cncc43)n2)cc1]

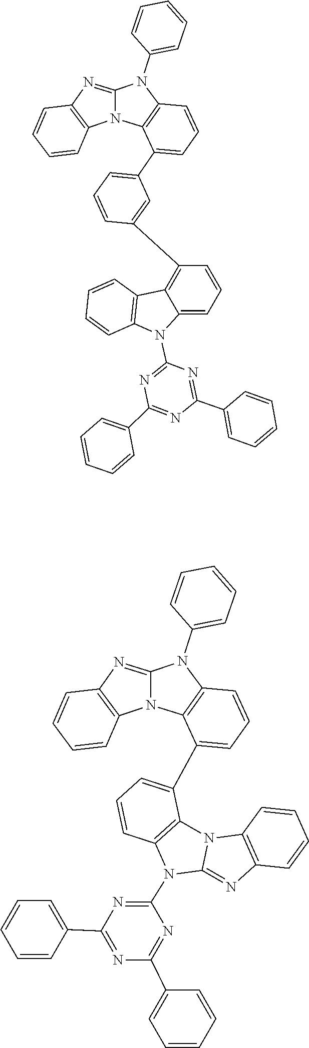 [SMILES: c1ccc(-c2nc(-c3ccccc3)nc(-n3c4ccccc4c4c(-c5cccc(-c6cccc7c6n6c8ccccc8nc6n7-c6ccccc6)c5)cccc43)n2)cc1 ; c1ccc(-c2nc(-c3ccccc3)nc(-n3c4cccc(-c5cccc6c5n5c7ccccc7nc5n6-c5ccccc5)c4n4c5ccccc5nc34)n2)cc1]

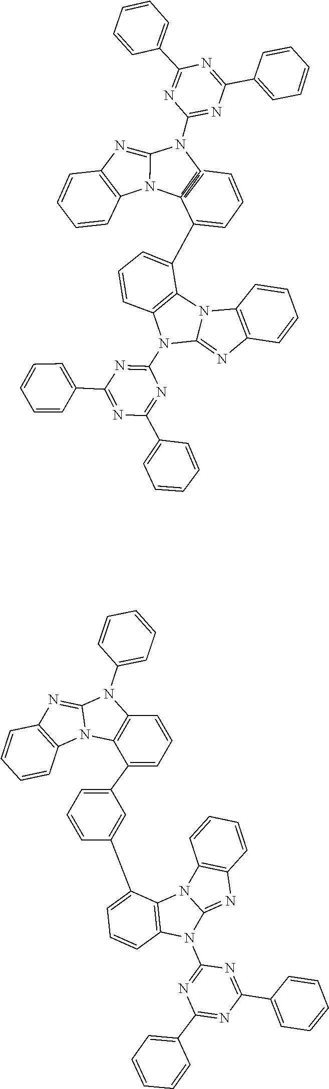

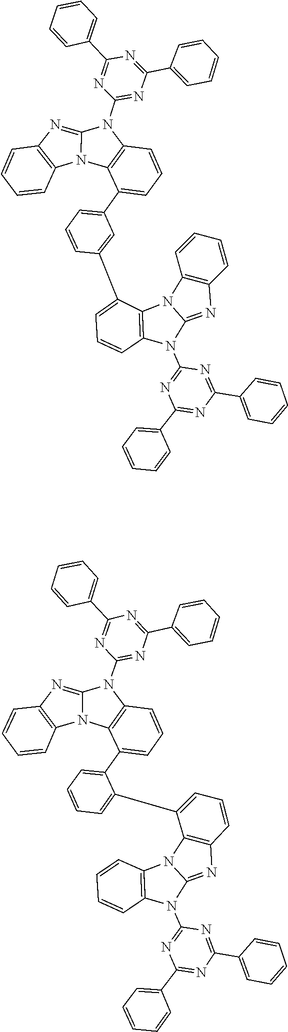 [SMILES: c1ccc(-c2nc(-c3ccccc3)nc(-n3c4cccc(-c5cccc(-c6cccc7c6n6c8ccccc8nc6n7-c6nc(-c7ccccc7)nc(-c7ccccc7)n6)c5)c4n4c5ccccc5nc34)n2)cc1 ; c1ccc(-c2nc(-c3ccccc3)nc(-n3c4ccccc4n4c5c(-c6ccccc6-c6cccc7c6n6c8ccccc8nc6n7-c6nc(-c7ccccc7)nc(-c7ccccc7)n6)cccc5nc34)n2)cc1]

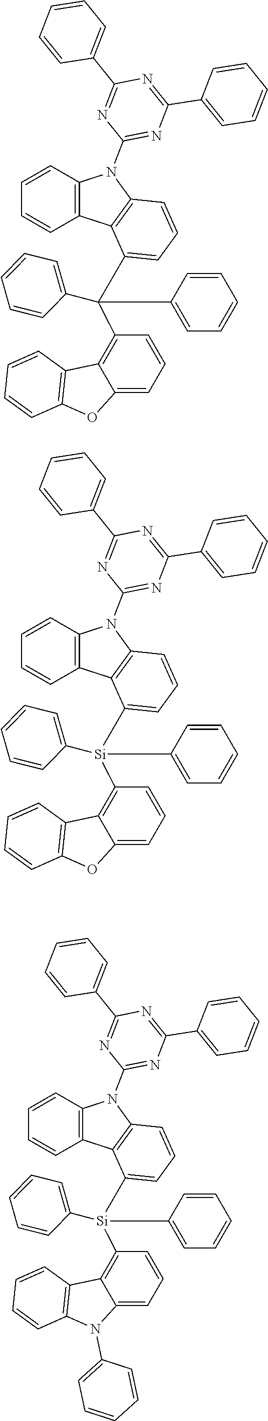

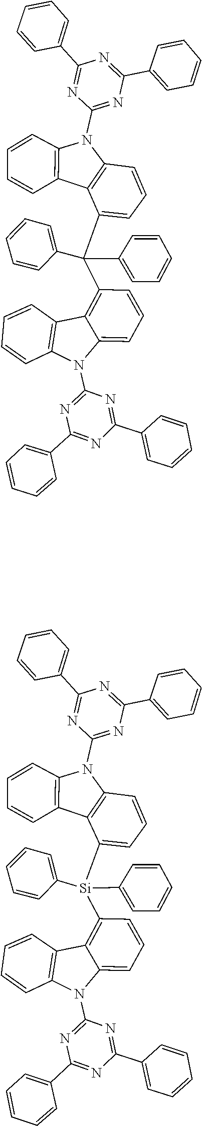 [SMILES: c1ccc(-c2nc(-c3ccccc3)nc(-n3c4ccccc4c4c(C(c5ccccc5)(c5ccccc5)c5cccc6c5c5ccccc5n6-c5nc(-c6ccccc6)nc(-c6ccccc6)n5)cccc43)n2)cc1 ; c1ccc(-c2nc(-c3ccccc3)nc(-n3c4ccccc4c4c([Si](c5ccccc5)(c5ccccc5)c5cccc6c5c5ccccc5n6-c5nc(-c6ccccc6)nc(-c6ccccc6)n5)cccc43)n2)cc1]

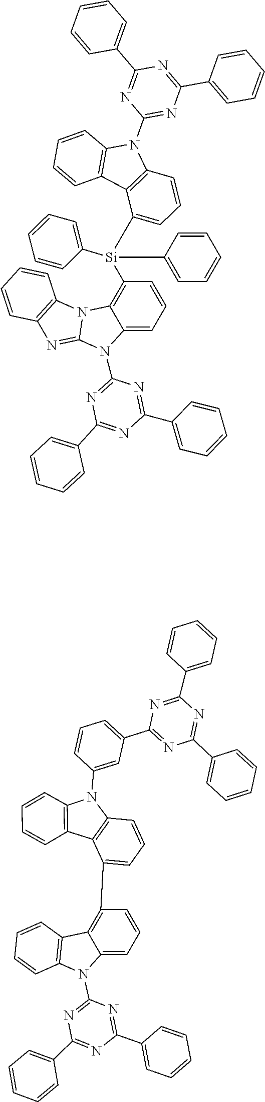 [SMILES: c1ccc(-c2nc(-c3ccccc3)nc(-n3c4ccccc4c4c([Si](c5ccccc5)(c5ccccc5)c5cccc6c5n5c7ccccc7nc5n6-c5nc(-c6ccccc6)nc(-c6ccccc6)n5)cccc43)n2)cc1 ; c1ccc(-c2nc(-c3ccccc3)nc(-c3cccc(-n4c5ccccc5c5c(-c6cccc7c6c6ccccc6n7-c6nc(-c7ccccc7)nc(-c7ccccc7)n6)cccc54)c3)n2)cc1]

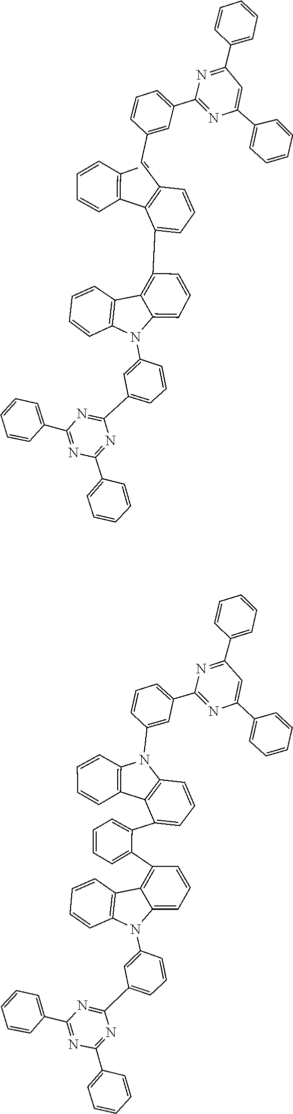 [SMILES: Cc1ccccc1-c1c(C=Cc2cccc(-c3nc(-c4ccccc4)cc(-c4ccccc4)n3)c2)cccc1-c1cccc2c1c1ccccc1n2-c1cccc(-c2nc(-c3ccccc3)nc(-c3ccccc3)n2)c1 ; c1ccc(-c2cc(-c3ccccc3)nc(-c3cccc(-n4c5ccccc5c5c(-c6ccccc6-c6cccc7c6c6ccccc6n7-c6cccc(-c7nc(-c8ccccc8)nc(-c8ccccc8)n7)c6)cccc54)c3)n2)cc1]

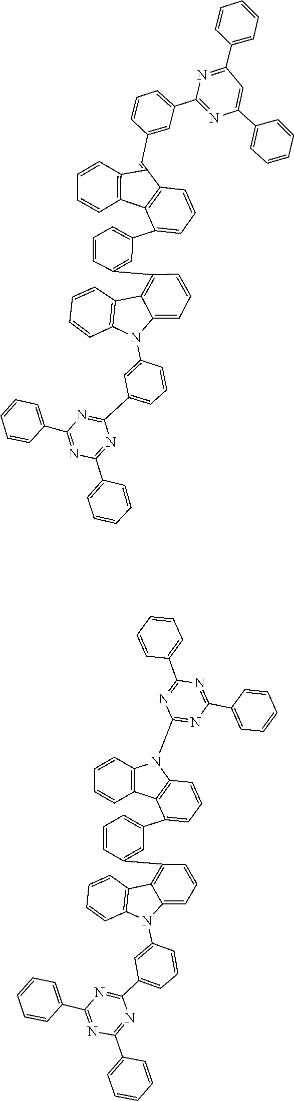 [SMILES: C(=C1\c2ccccc2-c2c1cccc2-c1cccc(-c2cccc3c2c2ccccc2n3-c2cccc(-c3nc(-c4ccccc4)nc(-c4ccccc4)n3)c2)c1)/c1cccc(-c2nc(-c3ccccc3)cc(-c3ccccc3)n2)c1 ; Cc1ccc2c(c1-c1cccc(-c3cccc4c3c3ccccc3n4-c3nc(-c4ccccc4)nc(-c4ccccc4)n3)c1)c1ccccc1n2-c1cccc(-c2nc(-c3ccccc3)nc(-c3ccccc3)n2)c1]

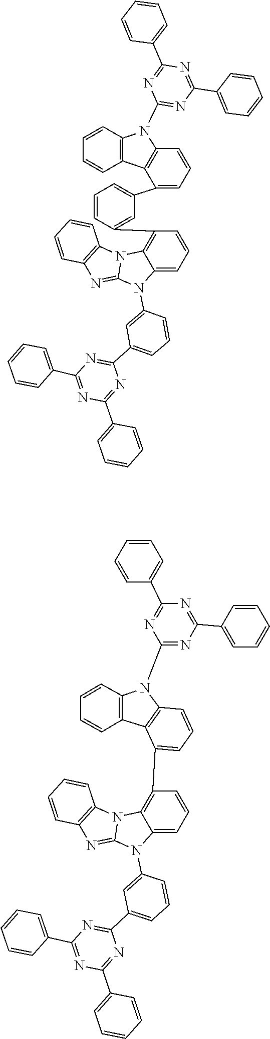 [SMILES: c1ccc(-c2nc(-c3ccccc3)nc(-c3cccc(-n4c5cccc(-c6cccc(-c7cccc8c7c7ccccc7n8-c7nc(-c8ccccc8)nc(-c8ccccc8)n7)c6)c5n5c6ccccc6nc45)c3)n2)cc1 ; c1ccc(-c2nc(-c3ccccc3)nc(-c3cccc(-n4c5cccc(-c6cccc7c6c6ccccc6n7-c6nc(-c7ccccc7)nc(-c7ccccc7)n6)c5n5c6ccccc6nc45)c3)n2)cc1]

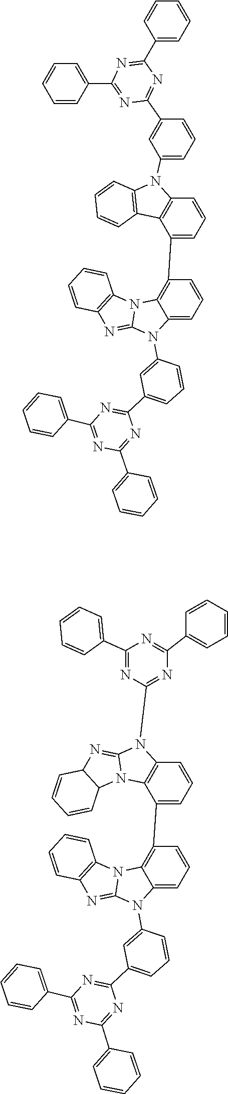 [SMILES: c1ccc(-c2nc(-c3ccccc3)nc(-c3cccc(-n4c5ccccc5c5c(-c6cccc7c6n6c8ccccc8nc6n7-c6cccc(-c7nc(-c8ccccc8)nc(-c8ccccc8)n7)c6)cccc54)c3)n2)cc1 ; C1=CC2N=C3N(c4nc(-c5ccccc5)nc(-c5ccccc5)n4)c4cccc(-c5cccc6c5n5c7ccccc7nc5n6-c5cccc(-c6nc(-c7ccccc7)nc(-c7ccccc7)n6)c5)c4N3C2C=C1]

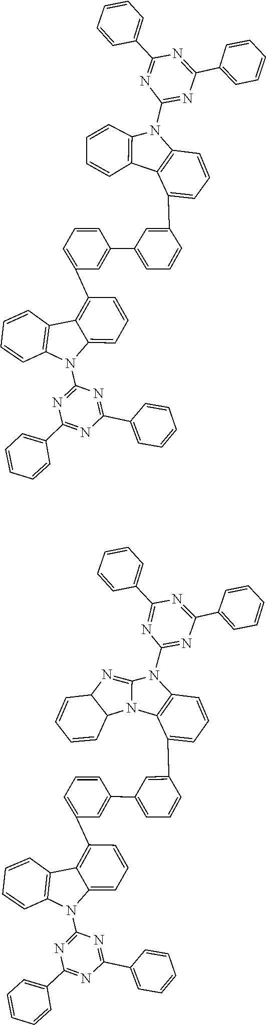 [SMILES: c1ccc(-c2nc(-c3ccccc3)nc(-n3c4ccccc4c4c(-c5cccc(-c6cccc(-c7cccc8c7c7ccccc7n8-c7nc(-c8ccccc8)nc(-c8ccccc8)n7)c6)c5)cccc43)n2)cc1 ; C1=CC2N=C3N(c4nc(-c5ccccc5)nc(-c5ccccc5)n4)c4cccc(-c5cccc(-c6cccc(-c7cccc8c7c7ccccc7n8-c7nc(-c8ccccc8)nc(-c8ccccc8)n7)c6)c5)c4N3C2C=C1]

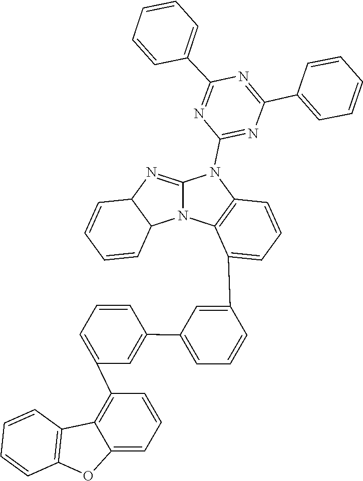 [SMILES: C1=CC2N=C3N(c4nc(-c5ccccc5)nc(-c5ccccc5)n4)c4cccc(-c5cccc(-c6cccc(-c7cccc8oc9ccccc9c78)c6)c5)c4N3C2C=C1]

A further means of improving the performance data of electronic devices, especially of organic electroluminescent devices, is to use combinations of two or more host materials in the emitting layer. U.S. Pat. No. 6,392,250 B1 discloses, for example, the use of a mixture consisting of an electron transport material, a hole transport material and a fluorescent emitter in the emission layer of an OLED. U.S. Pat. No. 6,803,720 B1 discloses the use of a mixture comprising a phosphorescent emitter and a hole transport material and an electron transport material in the emission layer of an OLED.

Therefore, it is further preferred that the composition of the present invention further comprises at least one hole-transporting host material additionally to the electron-transporting material.

Preferably, the at least one hole-transporting host material is selected from the group of the carbazole and triarylamine derivatives, more particularly the biscarbazoles, the bridged carbazoles, the triarylamines, the dibenzofuran-carbazole derivatives or dibenzofuran-amine derivatives, and the carbazoleamines.

More preferably, the at least one hole-transporting host material is selected from compounds of formula (h-1) or (h-2),

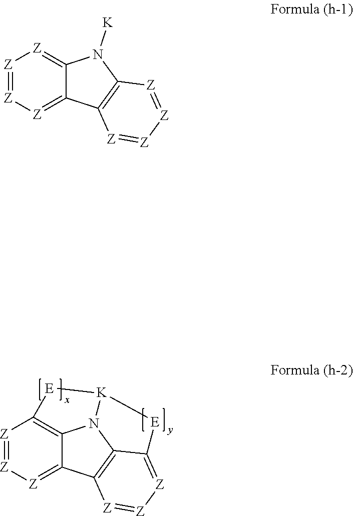

where:
K is Ar⁴ or -L⁵-N(Ar)₂;
Z is C—R^{Z} or C—R^{A}; or two adjacent groups Z form a condensed ring together;
R^{A} is -L³-Ar⁵ or -L⁴-N(Ar)₂;
R^{Z} is the same or different at each instance and is selected from H, D, F, Cl, Br, I, N(Ar)₂, N(R)₂, OAr, SAr, CN, NO₂, OR, SR, COOR, C(═O)N(R)₂, Si(R)₃, B(OR)₂, C(═O)R, P(═O)(R)₂, S(═O)R, S(═O)₂R, OSO₂R, a straight-chain alkyl group having 1 to 20 carbon atoms or an alkenyl or alkynyl group having 2 to 20 carbon atoms or a branched or cyclic alkyl group having 3 to 20 carbon atoms, where the alkyl, alkenyl or alkynyl group may in each case be substituted by one or more R radicals, where one or more nonadjacent CH₂ groups may be replaced by Si(R)₂, C═O, NR, O, S or CONR, or an aromatic or heteroaromatic ring system which has 5 to 60 aromatic ring atoms, preferably 5 to 40 aromatic ring atoms, and may be substituted in each case by one or more R radicals;
L⁴, L⁵ are the same or different at each instance and are a single bond or an aromatic or heteroaromatic ring system which has 5 to 30 aromatic ring atoms and may be substituted by one or more R radicals;
L³ is a single bond or an aromatic or heteroaromatic ring system which has 5 to 30 aromatic ring atoms and may be substituted by one or more R radicals, where one radical R on L³ may form a ring with a radical R^{Z} on the carbazole;
Ar⁴ is an aromatic ring system having 6 to 40 aromatic ring atoms or a heteroaromatic ring system having 5 to 40 aromatic ring atoms, which may be substituted by one or more R radicals;
Ar⁵ is the same or different at each instance and is an unsubstituted or substituted heteroaromatic ring system having 5 to 40 aromatic ring atoms, which may be substituted by one or more R;
R^{Z} is the same or different at each instance and is H, D, F, Cl, Br, I, N(Ar)₂, N(R)₂, OAr, SAr, CN, NO₂, OR, SR, COOR, C(═O)N(R)₂, Si(R)₃, B(OR)₂, C(═O)R, P(═O)(R)₂, S(═O)R, S(═O)₂R, OSO₂R, a straight-chain alkyl group having 1 to 20 carbon atoms or an alkenyl or alkynyl group having 2 to 20 carbon atoms or a branched or cyclic alkyl group having 3 to 20 carbon atoms, where the alkyl, alkenyl or alkynyl group may in each case be substituted by one or more R radicals, where one or more nonadjacent CH₂ groups may be replaced by Si(R)₂, C═O, NR, 0, S or CONR, or an aromatic or heteroaromatic ring system which has 5 to 60 aromatic ring atoms, preferably 5 to 40 aromatic ring atoms, and may be substituted in each case by one or more R radicals; at the same time, two R^{Z} radicals together may also form a ring system;
E is on each occurrence, independently, a single bond or a group C(R⁰)₂;
R⁰ is selected on each occurrence, independently, from a straight-chain alkyl group having 1 to 10 carbon atoms or a branched or cyclic alkyl group having 3 to 10 carbon atoms, which may in each case be substituted by one or more R′ radicals;
x, y are selected, independently, from 0 or 1, wherein when x or y is 0, then the corresponding group E is absent; and x+y=1 or 2;
with the proviso that the compounds of formulae (h-1) and (h-2) comprise at least one group Z, which stands for R^{A};
and where R, R′ and Ar have the same definitions as above.

Preferably, L⁴, L⁵ are the same or different at each instance and are a single bond or an aromatic or heteroaromatic ring system which has 5 to 25, more preferably 5 to 20, even more preferably 6 to 18 aromatic ring atoms and may be substituted by one or more R radicals.

Preferably, L³ is a single bond or an aromatic or heteroaromatic ring system which has 5 to 25, aromatic ring atoms, more preferably 5 to 20, even more preferably 6 to 18 aromatic ring atoms and may be substituted by one or more R radicals, where one radical R on L³ may form a ring with a radical R^{Z} on the carbazole;

Preferably, the group Ar⁵ is a an unsubstituted or substituted heteroaromatic ring system selected from the groups of formulae (Ar5-1) to (Ar5-6).

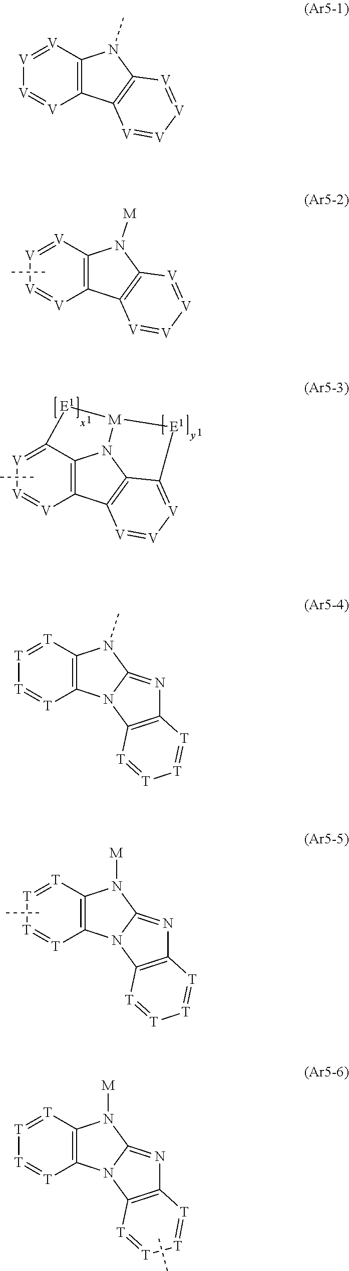

where the dashed bond indicates the bonding to L³ or Z;
V is C—R^{V}, with the proviso that V stands for C when it is bonded to the group of formula (h-1) or (h-2); or two adjacent groups V form a condensed ring together;
T is C—R^{T}, with the proviso that T stands for C when it is bonded to the group of formula (h-1) or (h-2), or two adjacent groups T form a condensed ring together;
M is an aromatic ring system having 6 to 40 aromatic ring atoms or a heteroaromatic ring system having 5 to 40 aromatic ring atoms, which may be substituted by one or more R radicals;
E¹ is on each occurrence, independently, a single bond or a group C(R⁰)₂; where R⁰ has the same meaning as above;
R^{T}, R^{V} is the same or different at each instance and is selected from H, D, F, Cl, Br, I, N(Ar)₂, N(R)₂, OAr, SAr, CN, NO₂, OR, SR, COOR, C(═O)N(R)₂, Si(R)₃, B(OR)₂, C(═O)R, P(═O)(R)₂, S(═O)R, S(═O)₂R, OSO₂R, a straight-chain alkyl group having 1 to 20 carbon atoms or an alkenyl or alkynyl group having 2 to 20 carbon atoms or a branched or cyclic alkyl group having 3 to 20 carbon atoms, where the alkyl, alkenyl or alkynyl group may in each case be substituted by one or more R radicals, where one or more nonadjacent CH₂ groups may be replaced by Si(R)₂, C═O, NR, O, S or CONR, or an aromatic or heteroaromatic ring system which has 5 to 60 aromatic ring atoms, preferably 5 to 40 aromatic ring atoms, and may be substituted in each case by one or more R radicals; at the same time, two R^{T} radicals together may form a ring system and two R^{V} radicals together may form a ring system;
x¹, y¹ are selected, independently, from 0 or 1, wherein when x¹ or y¹ is 0, then the corresponding group E¹ is absent; with the proviso that x¹+y¹=1 or 2;
and where R and Ar have the same definition as above.

In accordance with a preferred embodiment, the at least one hole-transporting host material is selected from compounds of formula (h-1-1) to (h-2-2),

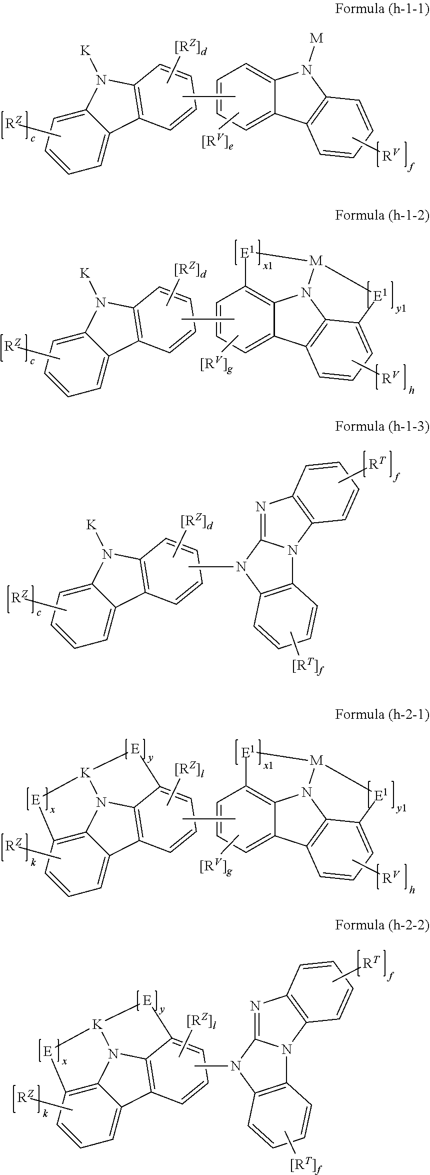

where the symbols have the same meaning as above, and where the indices have the following meaning:
x, y, x¹, y¹ have the same meaning as above;
c, f stands, independently, for 0, 1, 2, 3 or 4;
d, e stands, independently, for 0, 1, 2 or 3;
g stands for 0, 1, 2 or 3 if x¹=0; or for 0, 1 or 2 if x¹=1;
h stands for 0, 1, 2, 3 or 4 if y¹=0; or for 0, 1, 2 or 3 if y¹=1;
k stands for 0, 1, 2, 3 or 4 if x=0; or for 0, 1, 2 or 3 if x=1; and
l stands for 0, 1, 2 or 3 if y=0; or for 0, 1 or 2 if y=1.

Example of hole-transporting host materials suitable as second host material in the composition are depicted in the table below:

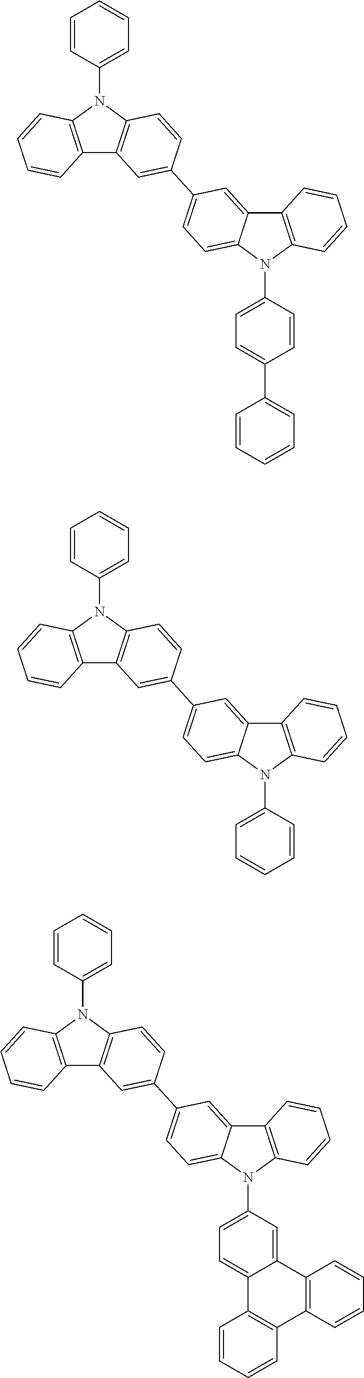 [SMILES: c1ccc(-c2ccc(-n3c4ccccc4c4cc(-c5ccc6c(c5)c5ccccc5n6-c5ccccc5)ccc43)cc2)cc1 ; c1ccc(-n2c3ccccc3c3cc(-c4ccc5c(c4)c4ccccc4n5-c4ccccc4)ccc32)cc1 ; c1ccc(-n2c3ccccc3c3cc(-c4ccc5c(c4)c4ccccc4n5-c4ccc5c6ccccc6c6ccccc6c5c4)ccc32)cc1]

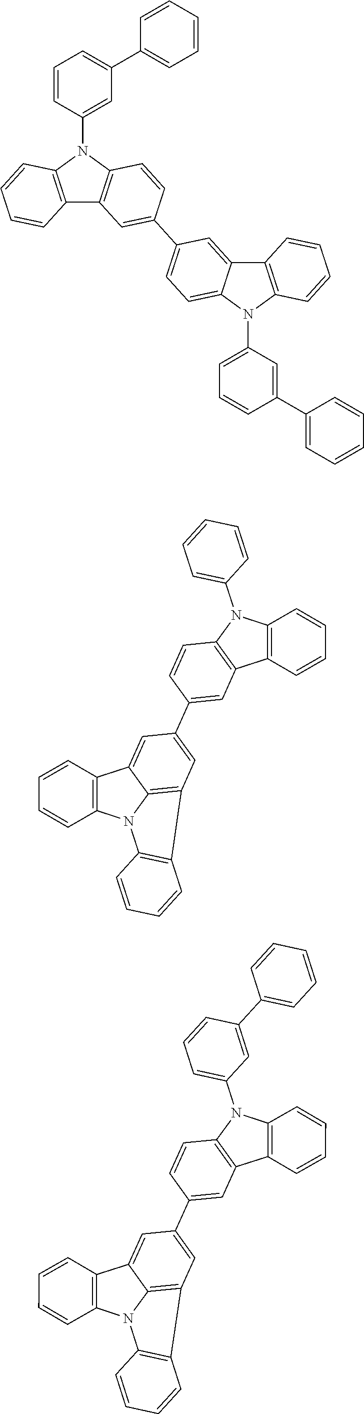 [SMILES: c1ccc(-c2cccc(-n3c4ccccc4c4cc(-c5ccc6c(c5)c5ccccc5n6-c5cccc(-c6ccccc6)c5)ccc43)c2)cc1 ; c1ccc(-n2c3ccccc3c3cc(-c4cc5c6ccccc6n6c7ccccc7c(c4)c56)ccc32)cc1 ; c1ccc(-c2cccc(-n3c4ccccc4c4cc(-c5cc6c7ccccc7n7c8ccccc8c(c5)c67)ccc43)c2)cc1]

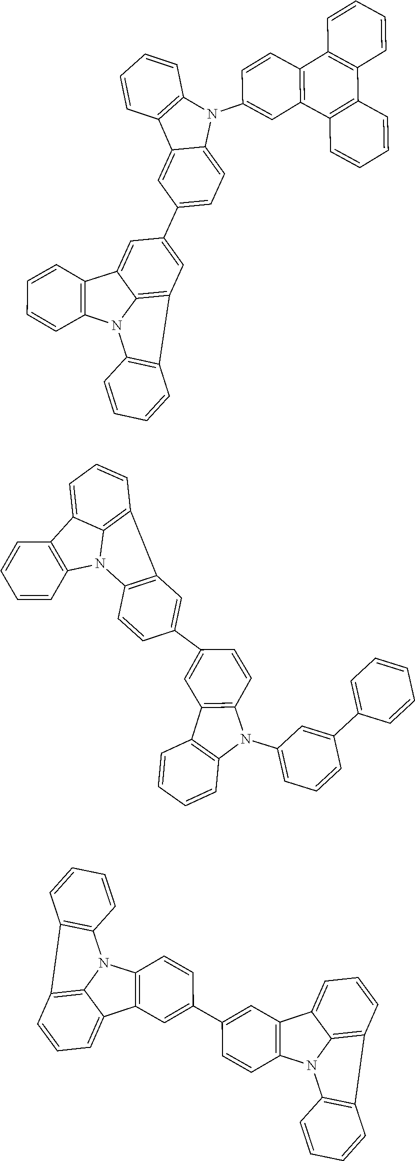 [SMILES: c1ccc2c(c1)c1ccccc1c1cc(-n3c4ccccc4c4cc(-c5cc6c7ccccc7n7c8ccccc8c(c5)c67)ccc43)ccc21 ; c1ccc(-c2cccc(-n3c4ccccc4c4cc(-c5ccc6c(c5)c5cccc7c8ccccc8n6c75)ccc43)c2)cc1 ; c1ccc2c(c1)c1cccc3c4cc(-c5ccc6c(c5)c5cccc7c8ccccc8n6c75)ccc4n2c13]

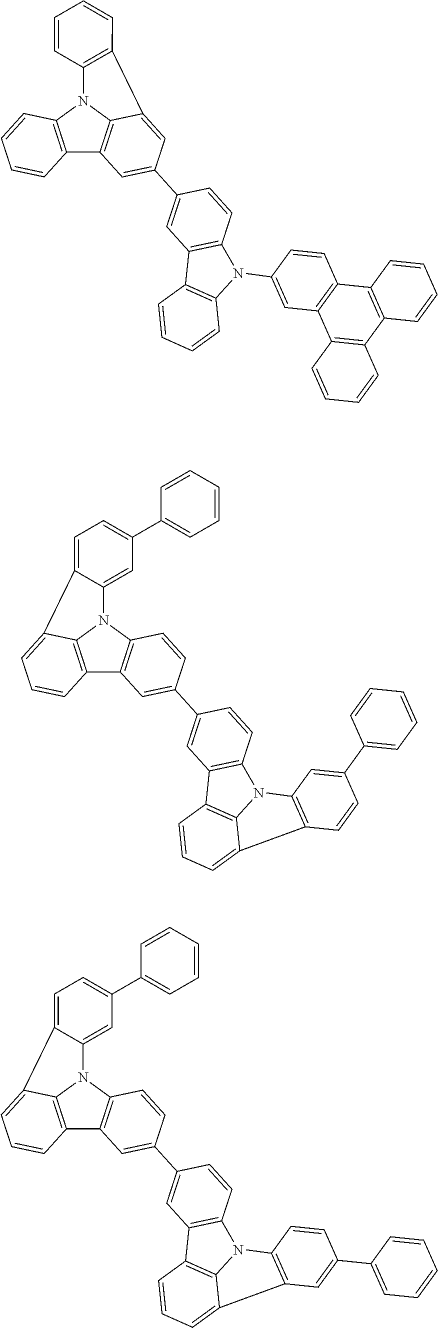 [SMILES: c1ccc2c(c1)c1ccccc1c1cc(-n3c4ccccc4c4cc(-c5cc6c7ccccc7n7c8ccccc8c(c5)c67)ccc43)ccc21 ; c1ccc(-c2ccc3c4cccc5c6cc(-c7ccc8c(c7)c7cccc9c%10ccc(-c%11ccccc%11)cc%10n8c79)ccc6n(c3c2)c54)cc1 ; c1ccc(-c2ccc3c(c2)c2cccc4c5cc(-c6ccc7c(c6)c6cccc8c9ccc(-c%10ccccc%10)cc9n7c68)ccc5n3c24)cc1]

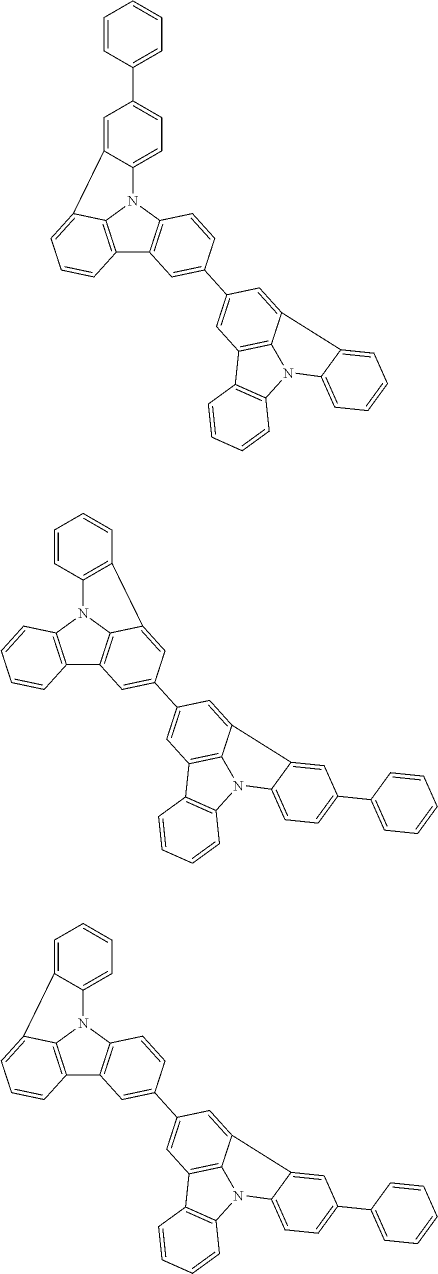 [SMILES: c1ccc(-c2ccc3c(c2)c2cccc4c5cc(-c6cc7c8ccccc8n8c9ccccc9c(c6)c78)ccc5n3c24)cc1 ; c1ccc(-c2ccc3c(c2)c2cc(-c4cc5c6ccccc6n6c7ccccc7c(c4)c56)cc4c5ccccc5n3c42)cc1 ; c1ccc(-c2ccc3c(c2)c2cc(-c4ccc5c(c4)c4cccc6c7ccccc7n5c64)cc4c5ccccc5n3c42)cc1]

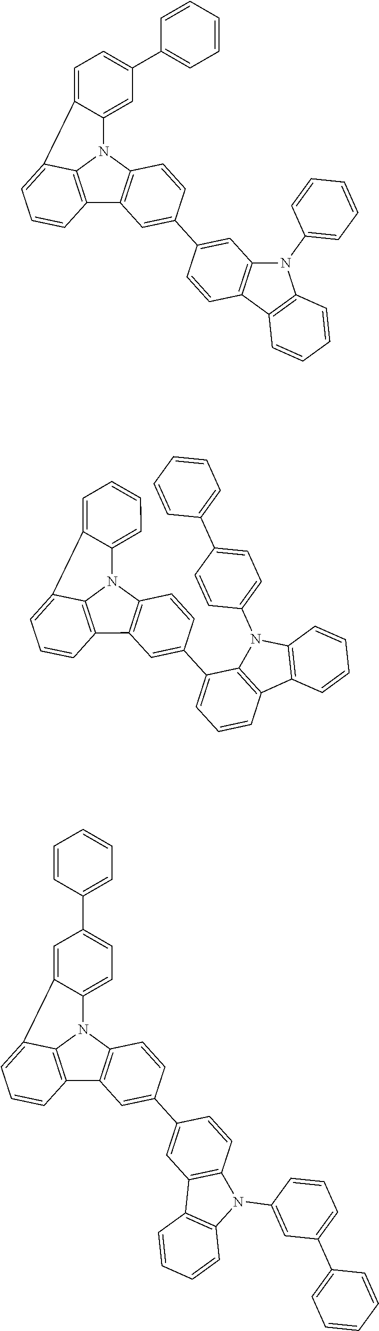 [SMILES: c1ccc(-c2ccc3c4cccc5c6cc(-c7ccc8c9ccccc9n(-c9ccccc9)c8c7)ccc6n(c3c2)c54)cc1 ; c1ccc(-c2ccc(-n3c4ccccc4c4cccc(-c5ccc6c(c5)c5cccc7c8ccccc8n6c75)c43)cc2)cc1 ; c1ccc(-c2cccc(-n3c4ccccc4c4cc(-c5ccc6c(c5)c5cccc7c8cc(-c9ccccc9)ccc8n6c75)ccc43)c2)cc1]

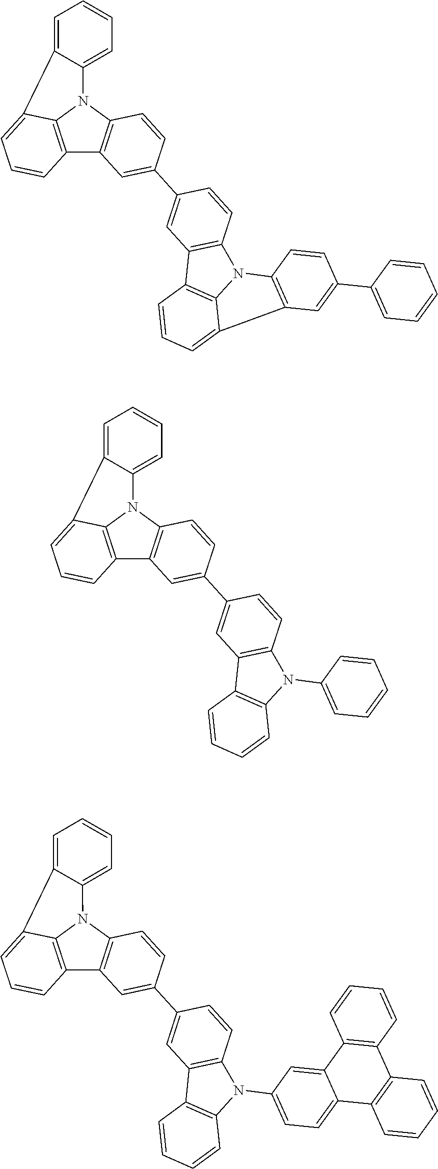 [SMILES: c1ccc(-c2ccc3c(c2)c2cccc4c5cc(-c6ccc7c(c6)c6cccc8c9ccccc9n7c86)ccc5n3c24)cc1 ; c1ccc(-n2c3ccccc3c3cc(-c4ccc5c(c4)c4cccc6c7ccccc7n5c64)ccc32)cc1 ; c1ccc2c(c1)c1ccccc1c1cc(-n3c4ccccc4c4cc(-c5ccc6c(c5)c5cccc7c8ccccc8n6c75)ccc43)ccc21]

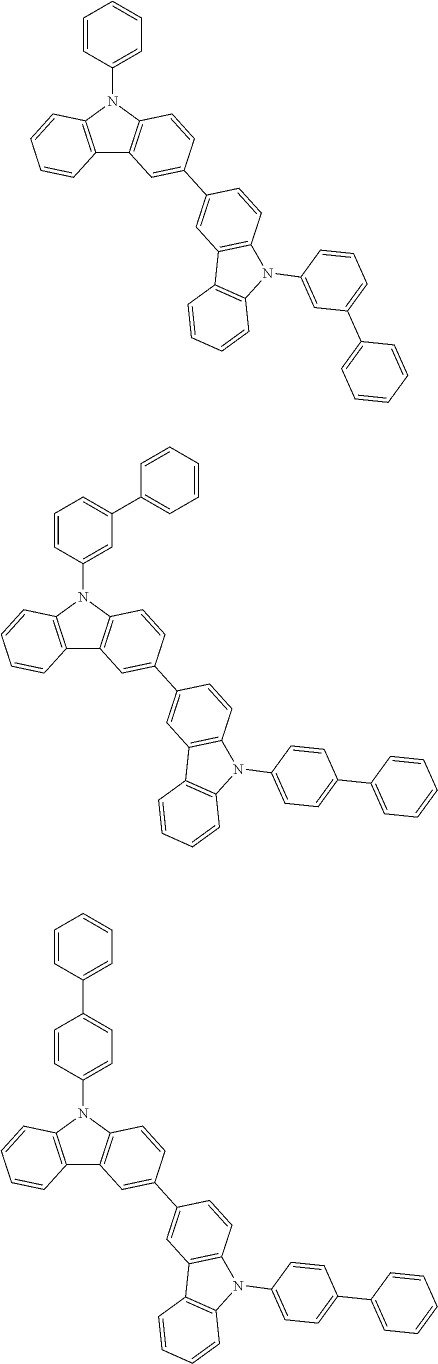 [SMILES: c1ccc(-c2cccc(-n3c4ccccc4c4cc(-c5ccc6c(c5)c5ccccc5n6-c5ccccc5)ccc43)c2)cc1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccc(-c6ccccc6)cc5)ccc43)cc2)cc1]

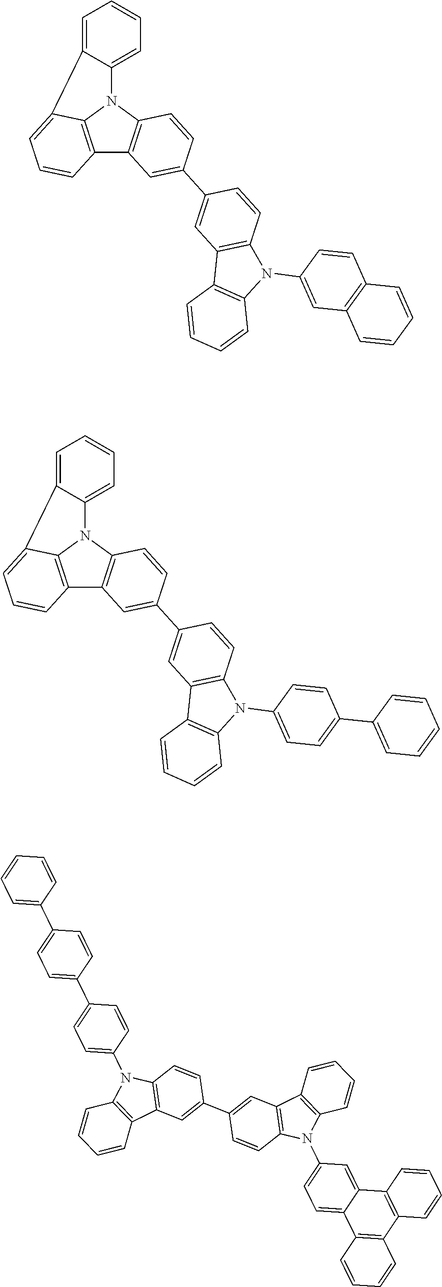 [SMILES: c1ccc2cc(-n3c4ccccc4c4cc(-c5ccc6c(c5)c5cccc7c8ccccc8n6c75)ccc43)ccc2c1 ; c1ccc(-c2ccc(-n3c4ccccc4c4cc(-c5ccc6c(c5)c5cccc7c8ccccc8n6c75)ccc43)cc2)cc1 ; c1ccc(-c2ccc(-c3ccc(-n4c5ccccc5c5cc(-c6ccc7c(c6)c6ccccc6n7-c6ccc7c8ccccc8c8ccccc8c7c6)ccc54)cc3)cc2)cc1]

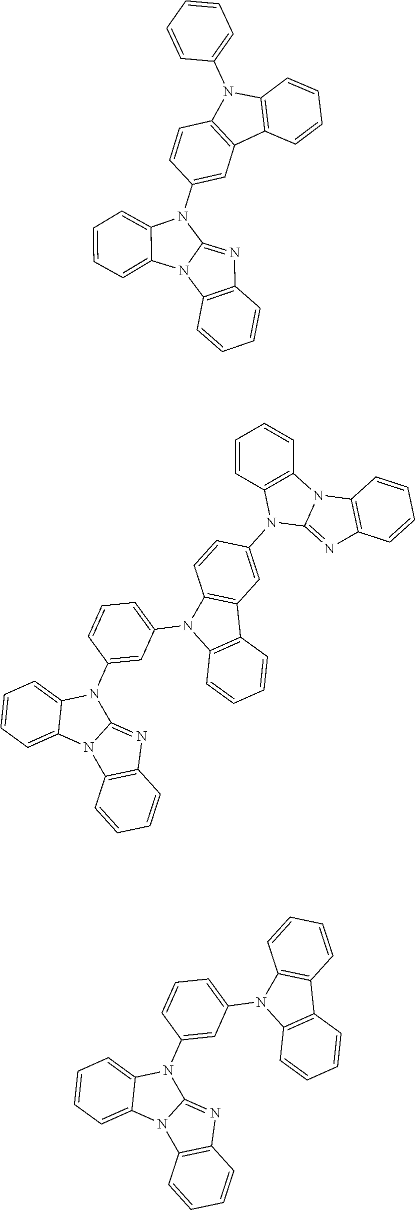 [SMILES: c1ccc(-n2c3ccccc3c3cc(-n4c5ccccc5n5c6ccccc6nc45)ccc32)cc1 ; c1cc(-n2c3ccccc3c3cc(-n4c5ccccc5n5c6ccccc6nc45)ccc32)cc(-n2c3ccccc3n3c4ccccc4nc23)c1 ; c1cc(-n2c3ccccc3c3ccccc32)cc(-n2c3ccccc3n3c4ccccc4nc23)c1]

Furthermore, it is preferred that the at least one blue phosphorescent metal complex is selected from platinum complexes.

Preferably, the at least one blue phosphorescent metal complex has a LUMO of from −1.8 eV to −2.2 eV, and the at least one blue phosphorescent metal complex has preferably a HOMO of from −5.0 eV to −5.6 eV, as defined by quantum-chemical calculations.

Preferably, the energy of the lowest triplet state T₁ of the at least one blue phosphorescent metal complex is higher then 2.55 eV, more preferably higher than 2.65 eV, even more preferably higher than to 2.75 eV, as defined by quantum-chemical calculations.

As mentioned above, the energy levels of molecular orbitals, like the highest occupied molecular orbital (HOMO) and the lowest unoccupied molecular orbital (LUMO), and of the lowest triplet state T₁ or of the lowest excited singlet state S, of materials are determined via quantum-chemical calculations. In order to calculate organic substances without metals, firstly a geometry optimisation is carried out using the “Ground State/Semi-empirical/Default Spin/AM1/Charge 0/Spin Singlet” method. An energy calculation is subsequently carried out on the basis of the optimised geometry. The “TD-SCF/DFT/Default Spin/B3PW91” method with the “6-31G(d)” base set (charge 0, spin singlet) is used here. For metal-containing compounds, the geometry is optimised via the “Ground State/Hartree-Fock/Default Spin/LanL2 MB/Charge 0/Spin Singlet” method. The energy calculation is carried out analogously to the above-described method for the organic substances, with the difference that the “LanL2DZ” base set is used for the metal atom and the “6-31G(d)” base set is used for the ligands. The energy calculation gives the HOMO energy level HEh or LUMO energy level LEh in hartree units. The HOMO and LUMO energy levels in electron volts calibrated with reference to cyclic voltammetry measurements are determined therefrom as follows:

HOMO(eV)=((HEh*27.212)−0.9899)/1.1206

LUMO(eV)=((LEh*27.212)−2.0041)/1.385

For the purposes of this application, these values are to be regarded as HOMO and LUMO energy levels respectively of the materials.

The lowest triplet state T₁ is defined as the energy of the triplet state having the lowest energy which arises from the quantum-chemical calculation described.

The lowest excited singlet state S, is defined as the energy of the excited singlet state having the lowest energy which arises from the quantum-chemical calculation described.

The method described herein is independent of the software package used and always gives the same results. Examples of frequently used programs for this purpose are “Gaussian09 W” (Gaussian Inc.) and Q-Chem 4.1 (Q-Chem, Inc.).

Very suitable blue phosphorescent metal complexes are the compounds of formula (Pt-1) as defined below:

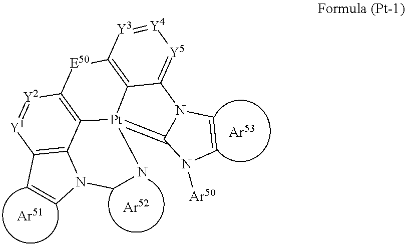

where:
Y¹, Y², Y³, Y⁴, Y⁵ stand, on each occurrence identically or differently, for a group CRY or N; or Y¹-Y² and/or Y³-Y⁴ or Y⁴-Y⁵ may form a condensed aryl or heteroaryl ring having 5 to 18 aromatic ring atoms, which may in each case also be substituted by one or more radicals R;
E⁵⁰ stands for on each occurrence, identically or differently, for C(R^{C0})₂, NR^{N0}, O or S;
Ar⁵⁰ is, on each occurrence, identically or differently, an aromatic or heteroaromatic ring system having 5 to 60, which may in each case also be substituted by one or more radicals R;
Ar⁵¹, Ar⁵², Ar⁵³ represent, identically or differently, a condensed aryl or heteroaryl ring having 5 to 18 aromatic ring atoms, which may in each case also be substituted by one or more radicals R;
R^{Y} stand on each occurrence, identically or differently, for a radical selected from H, D, F, Cl, Br, I, CHO, CN, C(═O)Ar, P(═O)(Ar)₂, S(═O)Ar, S(═O)₂Ar, N(R)₂, N(Ar)₂, NO₂, Si(R)₃, B(OR)₂, OSO₂R, a straight-chain alkyl, alkoxy or thioalkyl group having 1 to 40 C atoms or branched or a cyclic alkyl, alkoxy or thioalkyl group having 3 to 40 C atoms, each of which may be substituted by one or more radicals R, where in each case one or more non-adjacent CH₂ groups may be replaced by RC═CR, C≡C, Si(R)₂, Ge(R)₂, Sn(R)₂, C═O, C═S, C═Se, P(═O)(R), SO, SO₂, O, S or CONR and where one or more H atoms may be replaced by D, F, Cl, Br, I, CN or NO₂, an aromatic or heteroaromatic ring system having 5 to 60 aromatic ring atoms, which may in each case be substituted by one or more radicals R, and an aryloxy group having 5 to 60 aromatic ring atoms, which may be substituted by one or more radicals R; where two radicals R^{Y} may form an aliphatic, aromatic or heteroaromatic ring system together, which may be substituted by one or more radicals R;
R^{C0} stand on each occurrence, identically or differently, for a radical selected from H, D, a straight-chain alkyl group having 1 to 40 C atoms, which may be substituted by one or more radicals R, an aryl or heteroaryl group having 6 to 18 aromatic ring atoms, which may in each case be substituted by one or more radicals R; where two radicals R^{C} may form an aliphatic, aromatic or heteroaromatic ring system together, which may be substituted by one or more radicals R;
R^{NO} stand on each occurrence, identically or differently, for a radical selected from H, D, F, a straight-chain alkyl group having 1 to 40 C atoms or branched or a cyclic alkyl group having 3 to 40 C atoms, each of which may be substituted by one or more radicals R, and where one or more H atoms may be replaced by D, F or CN, an aromatic or heteroaromatic ring system having 5 to 60 aromatic ring atoms, which may in each case be substituted by one or more radicals R;
R and Ar have the same meaning as above.

Preferably, Ar⁵⁰ is, on each occurrence, identically or differently, an aromatic or heteroaromatic ring system having 5 to 40, more preferably 5 to 30, even more preferably 6 to 18 aromatic ring atoms, which may in each case also be substituted by one or more radicals R.

Preferably, Ar⁵¹, Ar⁵², Ar⁵³ represent, identically or differently, a condensed aryl or heteroaryl ring having 6 aromatic ring atoms, which may in each case also be substituted by one or more radicals R.

Preferably R^{Y} stands on each occurrence, identically or differently, for H, D, F, a straight-chain alkyl, alkoxy or thioalkyl group having 1 to 40, preferably 1 to 20, more preferably 1 to 10 C atoms or branched or a cyclic alkyl, alkoxy or thioalkyl group having 3 to 40, preferably 3 to 20, more preferably 3 to 10 C atoms, each of which may be substituted by one or more radicals R, where in each case one or more non-adjacent CH₂ groups may be replaced by RC═CR, C≡C, O or S and where one or more H atoms may be replaced by D or F, an aromatic or heteroaromatic ring system having 5 to 60, preferably 5 to 40, more preferably 5 to 30, particularly preferably 5 to 18 aromatic ring atoms, which may in each case be substituted by one or more radicals R.

Preferably, R^{C0} stand on each occurrence, identically or differently, for a radical selected from H, D, a straight-chain alkyl group having 1 to 10, preferably 1 to 6, more preferably 1 to 3 C atoms, which may be substituted by one or more radicals R, an aryl or heteroaryl group having 6 to 18, preferably 6 to 12 aromatic ring atoms, which may in each case be substituted by one or more radicals R; where two radicals R^{C}o may form an aliphatic, aromatic or heteroaromatic ring system together, which may be substituted by one or more radicals R.

Preferably, R^{N0} stand on each occurrence, identically or differently, for a radical selected from an aromatic or heteroaromatic ring system having 5 to 60, preferably 5 to 40, more preferably 5 to 30, particularly preferably 5 to 18 aromatic ring atoms aromatic ring atoms, which may in each case be substituted by one or more radicals R.

Examples of particularly suitable blue phosphorescent metal complexes are depicted below:

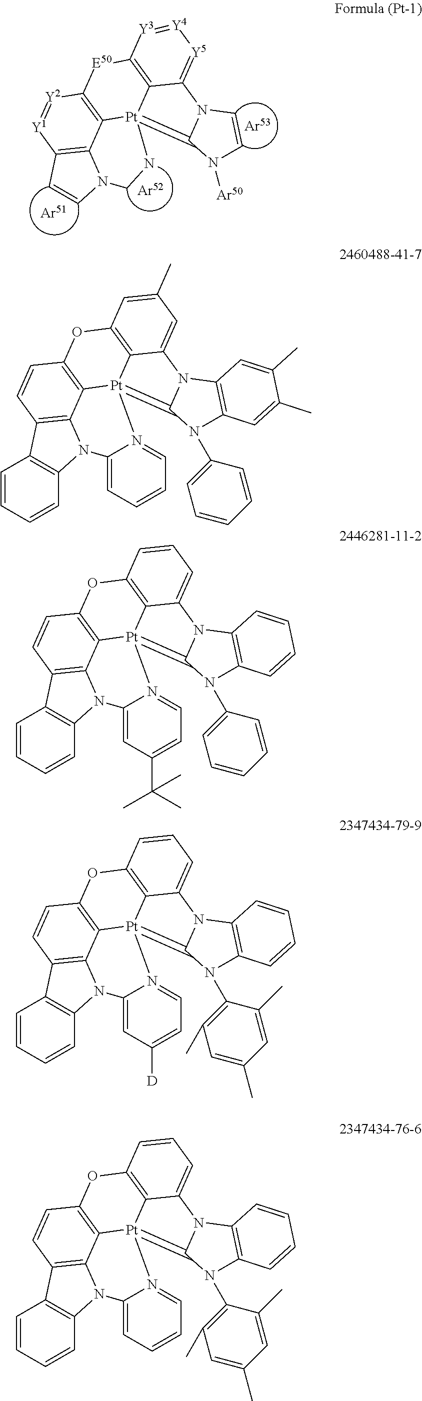

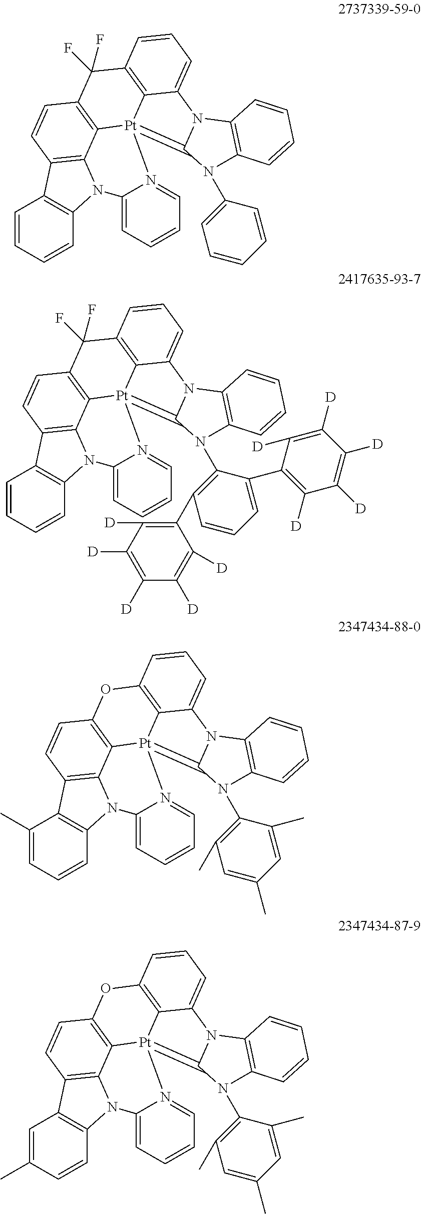

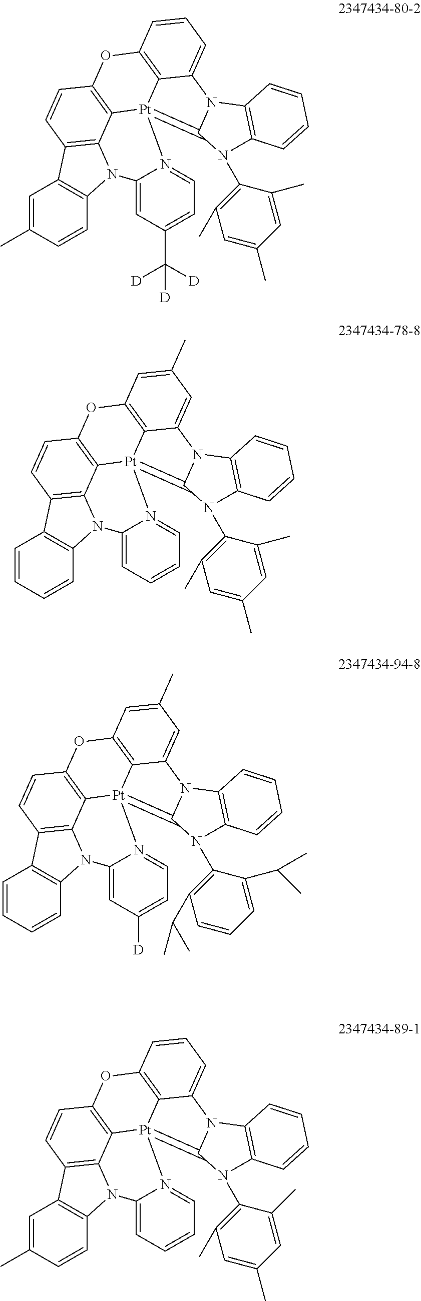

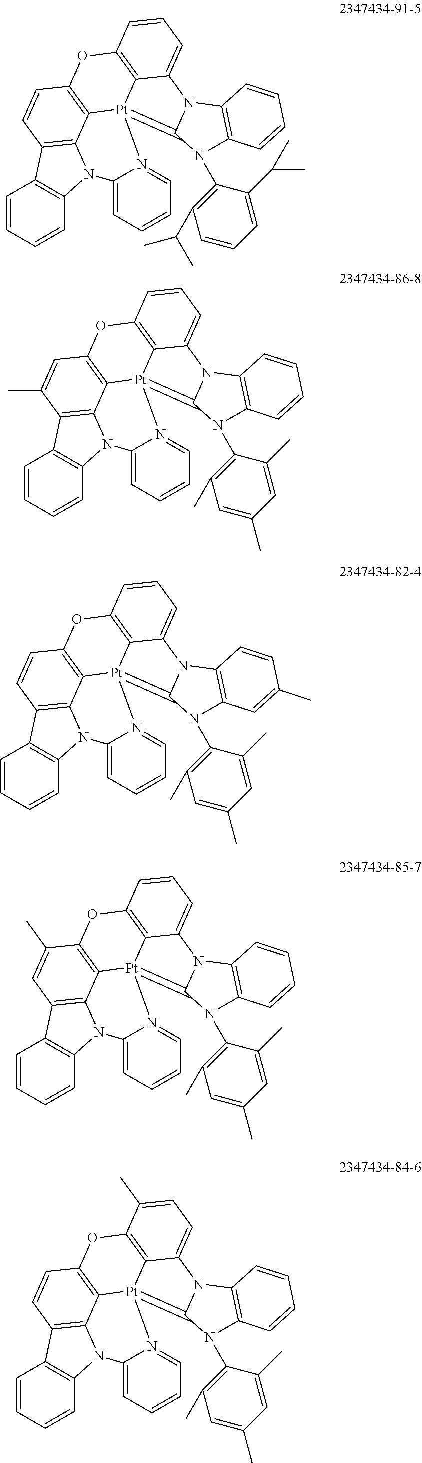

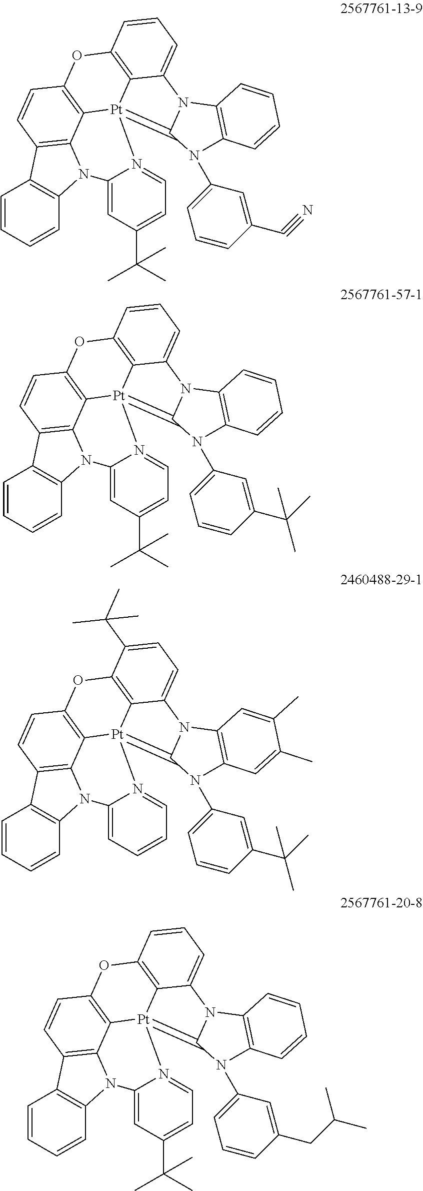

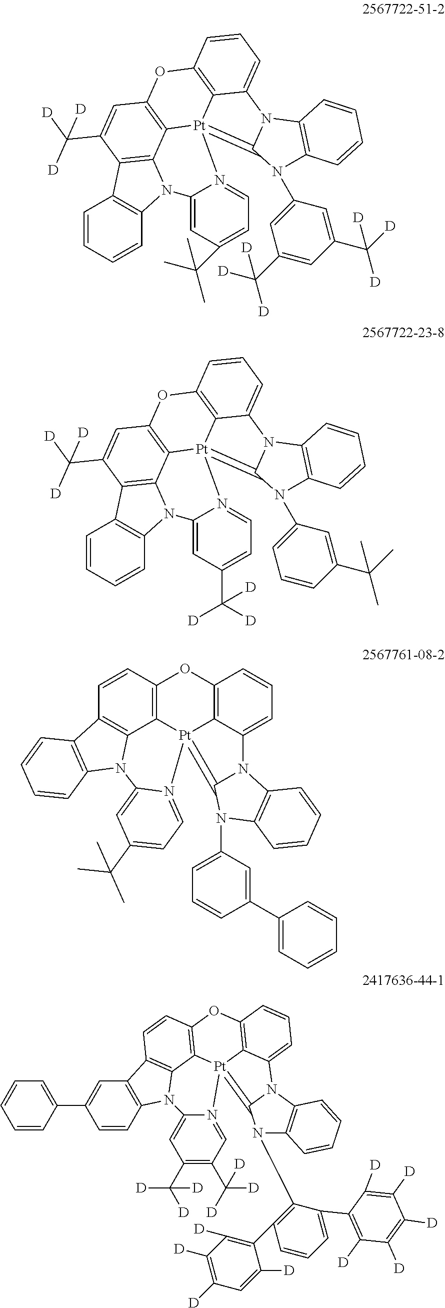

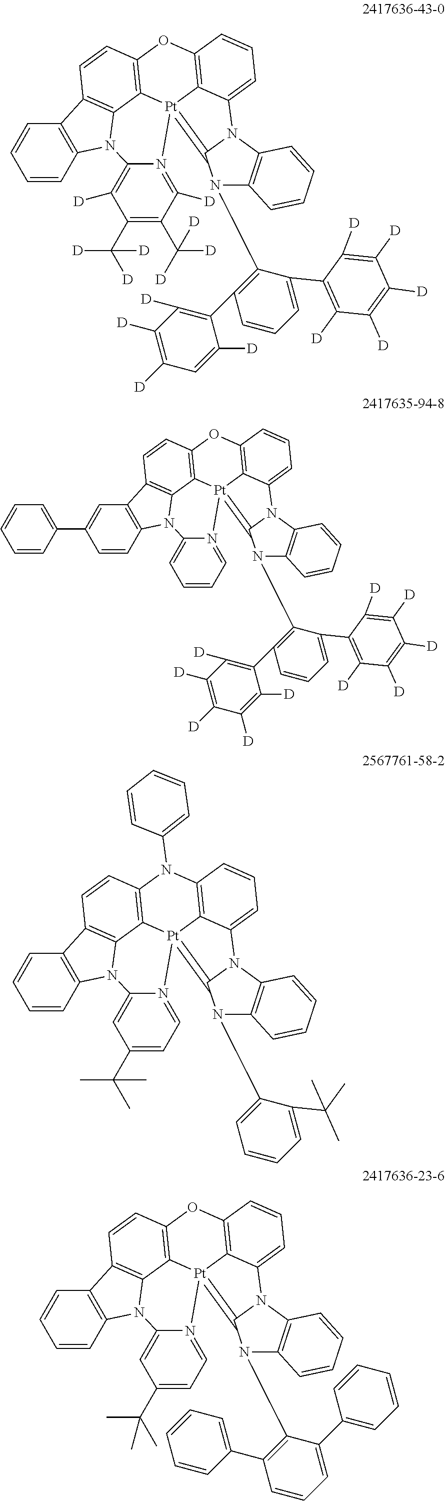

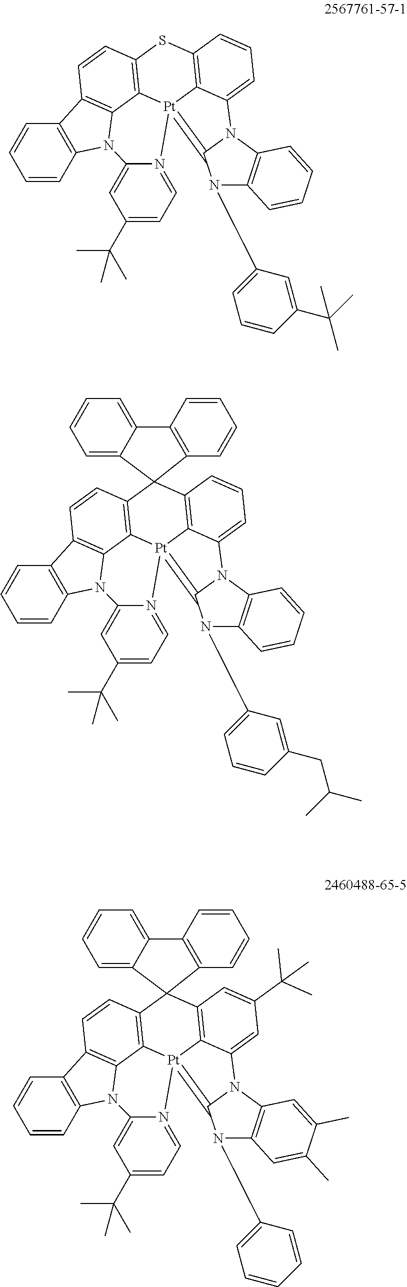

Preferably, the at least one fluorescent emitter in the composition has an emission peak wavelength between 420-550 nm, preferably 420-470 nm.

Preferred fluorescent emitters are aromatic anthracenamines, aromatic anthracenediamines, aromatic pyrenamines, aromatic pyrenediamines, aromatic chrysenamines or aromatic chrysenediamines. An aromatic anthracenamine is taken to mean a compound in which one diarylamino group is bonded directly to an anthracene group, preferably in the 9-position. An aromatic anthracenediamine is taken to mean a compound in which two diarylamino groups are bonded directly to an anthracene group, preferably in the 9,10-position. Aromatic pyrenamines, pyrenediamines, chrysenamines and chrysenediamines are defined analogously thereto, where the diarylamino groups are preferably bonded to the pyrene in the 1-position or in the 1,6-position. Further preferred emitters are indenofluorenamines or indenofluorenediamines, for example in accordance with WO 2006/108497 or WO 2006/122630, benzoindenofluorenamines or benzoindenofluorenediamines, for example in accordance with WO 2008/006449, and dibenzoindenofluorenamines or dibenzoindenofluorenediamines, for example in accordance with WO 2007/140847, and the indenofluorene derivatives containing condensed aryl groups which are disclosed in WO 2010/012328. Still further preferred emitters are benzanthracene derivatives as disclosed in WO 2015/158409, anthracene derivatives as disclosed in WO 2017/036573, fluorene dimers connected via heteroaryl groups like in WO 2016/150544 or phenoxazine derivatives as disclosed in WO 2017/028940 and WO 2017/028941. Preference is likewise given to the pyrenarylamines disclosed in WO 2012/048780 and WO 2013/185871. Preference is likewise given to the benzoindenofluorenamines disclosed in WO 2014/037077, the benzofluorenamines disclosed in WO 2014/106522 and the indenofluorenes disclosed in WO 2014/111269 or WO 2017/036574, WO 2018/007421. Also preferred are the emitters comprising dibenzofuran or indenodibenzofuran moieties as disclosed in WO 2018/095888, WO 2018/095940, WO 2019/076789, WO 2019/170572 as well as in WO 2020/043657, WO 2020/043646 and WO/2020/043640. Preference is likewise given to boron derivatives as disclosed, for example, in WO 2015/102118, CN108409769, CN107266484, WO2017195669, US2018069182 as well as in WO 2020/208051, WO2021/058406, and WO 2021/094269.

Preferably, the at least one fluorescent emitter has a full width at half maximum FWHM≤50 nm, preferably FWHM≤40 nmm, more preferably FWHM≤30 nm. The method to determine the FWHM is described in the experimental part below.

Preferably, the at least one fluorescent emitter has a LUMO of from −2.1 eV to −2.5 eV, preferably of from −2.2 eV to −2.4 eV as defined by quantum-chemical calculations.

Preferably, the at least one fluorescent emitter has a HOMO of from −4.8 eV to −5.2 eV, preferably of from −4.9 eV to −5.1 eV, as defined by quantum-chemical calculations.

Preferably, the energy of the lowest singlet state S₁ of the fluorescent emitter is of from 2.65 eV to 2.9 eV, preferably of form 2.7 to 2.8 eV, more preferably of from 2.7 to 2.75 eV as defined by quantum-chemical calculations.

Examples of suitable fluorescent emitters are depicted in the table below:

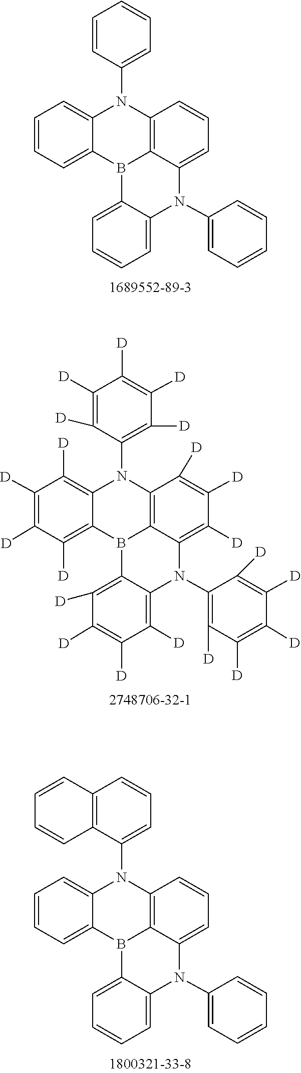 [SMILES: c1ccc(N2c3ccccc3B3c4ccccc4N(c4ccccc4)c4cccc2c43)cc1 ; [2H]c1c([2H])c([2H])c(N2c3c([2H])c([2H])c([2H])c([2H])c3B3c4c([2H])c([2H])c([2H])c([2H])c4N(c4c([2H])c([2H])c([2H])c([2H])c4[2H])c4c([2H])c([2H])c([2H])c2c43)c([2H])c1[2H] ; c1ccc(N2c3ccccc3B3c4ccccc4N(c4cccc5ccccc45)c4cccc2c43)cc1]

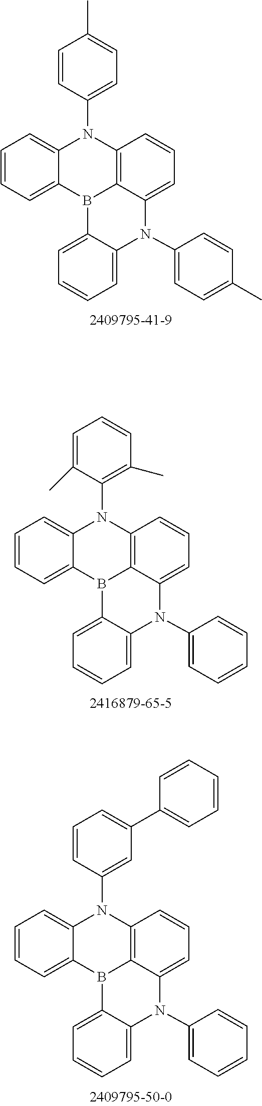 [SMILES: Cc1ccc(N2c3ccccc3B3c4ccccc4N(c4ccc(C)cc4)c4cccc2c43)cc1 ; Cc1cccc(C)c1N1c2ccccc2B2c3ccccc3N(c3ccccc3)c3cccc1c32 ; c1ccc(-c2cccc(N3c4ccccc4B4c5ccccc5N(c5ccccc5)c5cccc3c54)c2)cc1]

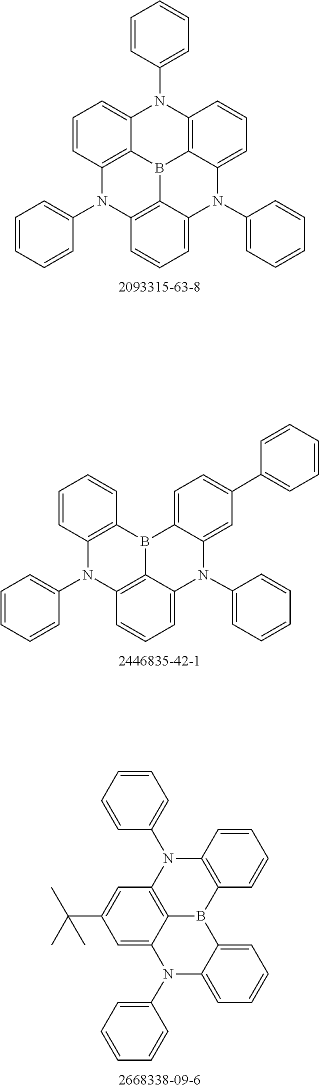 [SMILES: c1ccc(N2c3cccc4c3B3c5c2cccc5N(c2ccccc2)c2cccc(c23)N4c2ccccc2)cc1 ; c1ccc(-c2ccc3c(c2)N(c2ccccc2)c2cccc4c2B3c2ccccc2N4c2ccccc2)cc1 ; CC(C)(C)c1cc2c3c(c1)N(c1ccccc1)c1ccccc1B3c1ccccc1N2c1ccccc1]

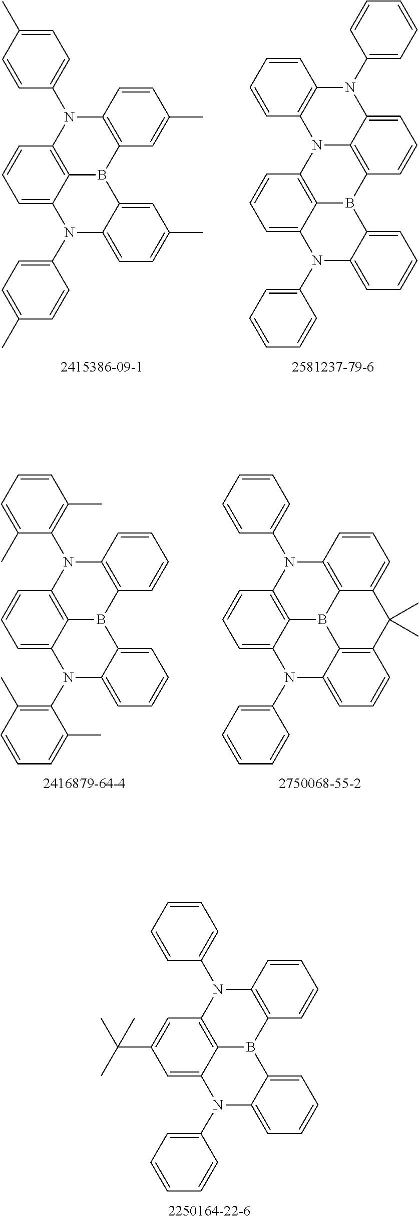 [SMILES: Cc1ccc(N2c3ccc(C)cc3B3c4cc(C)ccc4N(c4ccc(C)cc4)c4cccc2c43)cc1 ; c1ccc(N2c3ccccc3B3c4cccc5c4N(c4ccccc4N5c4ccccc4)c4cccc2c43)cc1 ; Cc1cccc(C)c1N1c2ccccc2B2c3ccccc3N(c3c(C)cccc3C)c3cccc1c32 ; CC1(C)c2cccc3c2B2c4c(cccc4N(c4ccccc4)c4cccc1c42)N3c1ccccc1 ; CC(C)(C)c1cc2c3c(c1)N(c1ccccc1)c1ccccc1B3c1ccccc1N2c1ccccc1]

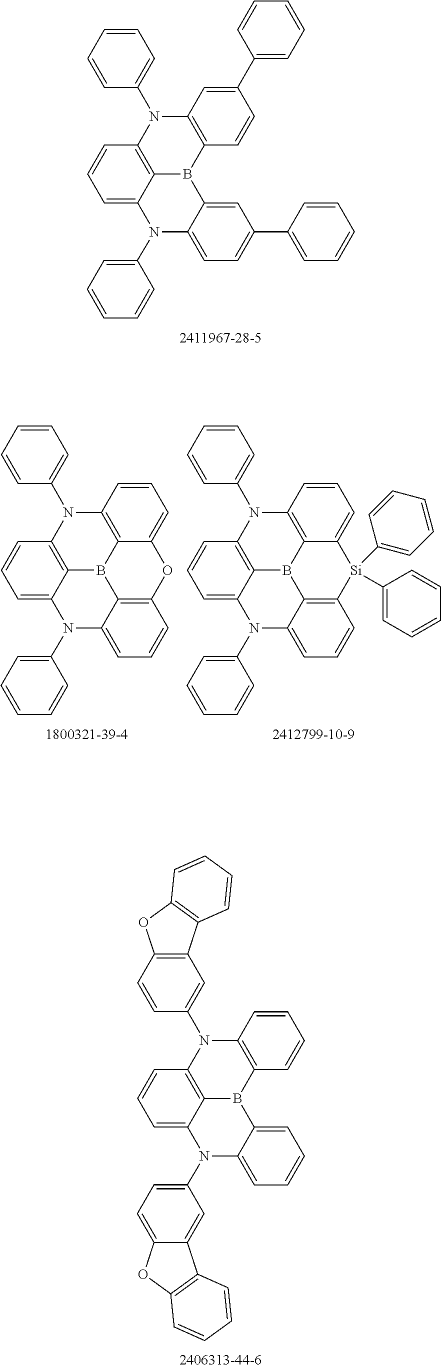

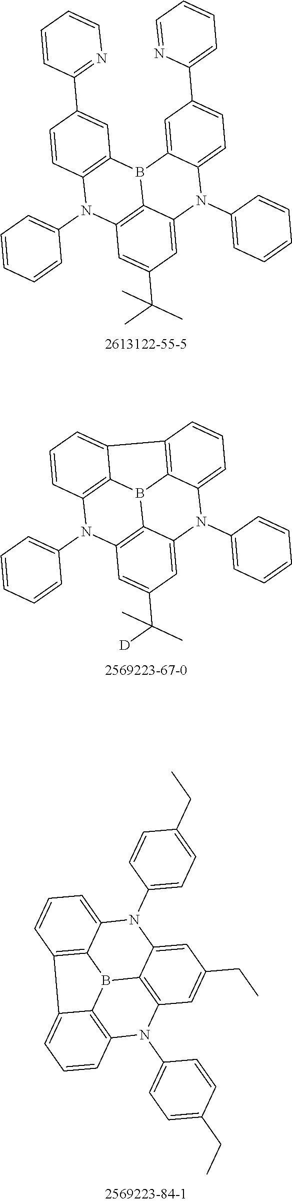 [SMILES: CC(C)(C)c1cc2c3c(c1)N(c1ccccc1)c1ccc(-c4ccccn4)cc1B3c1cc(-c3ccccn3)ccc1N2c1ccccc1 ; [2H]C(C)(C)c1cc2c3c(c1)N(c1ccccc1)c1cccc4c1B3c1c-4cccc1N2c1ccccc1 ; CCc1ccc(N2c3cccc4c3B3c5c-4cccc5N(c4ccc(CC)cc4)c4cc(CC)cc2c43)cc1]

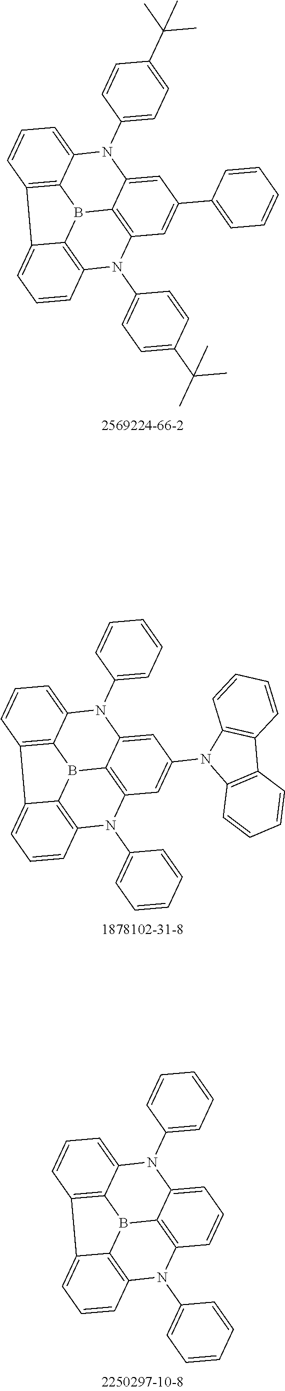 [SMILES: CC(C)(C)c1ccc(N2c3cccc4c3B3c5c-4cccc5N(c4ccc(C(C)(C)C)cc4)c4cc(-c5ccccc5)cc2c43)cc1 ; c1ccc(N2c3cccc4c3B3c5c-4cccc5N(c4ccccc4)c4cc(-n5c6ccccc6c6ccccc65)cc2c43)cc1 ; c1ccc(N2c3cccc4c3B3c5c-4cccc5N(c4ccccc4)c4cccc2c43)cc1]

The compositions according to the invention may also comprise further organic or inorganic compounds which are likewise used in the electronic device like, for example, further emitters or further host materials.

The composition of the present invention may be processed by vapour deposition or from solution. If the compositions are applied from solution, formulations of the composition of the invention comprising at least one further solvent are required. These formulations may, for example, be solutions, dispersions or emulsions. For this purpose, it may be preferable to use mixtures of two or more solvents.

The present invention therefore further provides a formulation comprising the composition of the invention and at least one solvent.

Suitable and preferred solvents are, for example, toluene, anisole, o-, m- or p-xylene, methyl benzoate, mesitylene, tetralin, veratrole, THF, methyl-THF, THP, chlorobenzene, dioxane, phenoxytoluene, especially 3-phenoxytoluene, (−)-fenchone, 1,2,3,5-tetramethylbenzene, 1,2,4,5-tetramethylbenzene, 1-methylnaphthalene, 2-methylbenzothiazole, 2-phenoxyethanol, 2-pyrrolidinone, 3-methylanisole, 4-methylanisole, 3,4-dimethylanisole, 3,5-dimethylanisole, acetophenone, α-terpineol, benzothiazole, butyl benzoate, cumene, cyclohexanol, cyclohexanone, cyclohexylbenzene, decalin, dodecylbenzene, ethyl benzoate, indane, methyl benzoate, NMP, p-cymene, phenetole, 1,4-diisopropylbenzene, dibenzyl ether, diethylene glycol butyl methyl ether, triethylene glycol butyl methyl ether, diethylene glycol dibutyl ether, triethylene glycol dimethyl ether, diethylene glycol monobutyl ether, tripropylene glycol dimethyl ether, tetraethylene glycol dimethyl ether, 2-isopropylnaphthalene, pentylbenzene, hexylbenzene, heptylbenzene, octylbenzene, 1,1-bis(3,4-dimethylphenyl)ethane, hexamethylindane or mixtures of these solvents.

The present invention also provides for the use of the present composition in an organic electronic device, preferably in an emitting layer.

The organic electronic device is preferably selected from organic integrated circuits (OICs), organic field-effect transistors (OFETs), organic thin-film transistors (OTFTs), organic electroluminescent devices, organic solar cells (OSCs), organic optical detectors and organic photoreceptors, particular preference being given to organic electroluminescent devices.

Very particularly preferred organic electroluminescent devices containing the present compositions, as described above or described as preferred, are organic light-emitting transistors (OLETs), organic field-quench devices (OFQDs), organic light-emitting electrochemical cells (OLECs, LECs, LEECs), organic laser diodes (0-lasers) and organic light-emitting diodes (OLEDs); OLECs and OLEDs are especially preferred and OLEDs are the most preferred.

In a particularly preferred embodiment of the present invention, the electronic device is an organic electroluminescent device, most preferably an organic light-emitting diode (OLED), containing the composition as described above in the emission layer (EML). Light emission layer and light-emitting layer are used synonymously here.

In a particularly preferred embodiment of the present invention, the organic electroluminescent device is therefore one comprising an anode, a cathode and at least one organic layer comprising at least one light-emitting layer, wherein the at least one light-emitting layer comprises the composition as described above.

The light-emitting layer in the device of the invention, as described above, comprises preferably:
50% to 99% by volume of a host compound, wherein the host compound comprises at least one electron-transporting host material of the formula (1), (2) or (3) as described above; 1 to 30% by volume of a blue phosphorescent metal complex as a sensitizer; and 0.05 to 5% by volume of a fluorescent emitter,
based on the overall composition of the light emitting layer.

More preferably, the light-emitting layer in the device of the invention, as described above, comprises:
10% to 40%, preferably 15% to 35% by volume of an electron-transporting host material of the formula (1), (2) or (3) as described above;
40% to 80%, preferably 50 to 70% by volume of a hole-transporting host materials of formula (h-1) or (h-2) as described above;
1 to 30%, preferably 5 to 25% by volume of a blue phosphorescent metal complex as a sensitizer; and
0.05 to 5%, preferably 0.05 to 3% by volume of a fluorescent emitter, based on the overall composition of the light emitting layer.

If the compounds are processed from solution, preference is given to using the corresponding amounts in % by weight rather than the above-specified amounts in % by volume.

Apart from the cathode, anode and the layer comprising the composition of the invention, an electronic device may comprise further layers. These are selected, for example, from in each case one or more hole injection layers, hole transport layers, hole blocker layers, light-emitting layers, electron transport layers, electron injection layers, electron blocker layers, exciton blocker layers, interlayers, charge generation layers (IDMC 2003, Taiwan; Session 21 OLED (5), T. Matsumoto, T. Nakada, J. Endo, K. Mori, N. Kawamura, A. Yokoi, J. Kido, Multiphoton Organic EL Device Having Charge Generation Layer) and/or organic or inorganic p/n junctions. However, it should be pointed out that not necessarily every one of these layers need be present.

The sequence of layers in an organic electroluminescent device is preferably as follows: anode/hole injection layer/hole transport layer/light-emitting layer/electron transport layer/electron injection layer/cathode.

The sequence of the layers is a preferred sequence.

At the same time, it should be pointed out again that not all the layers mentioned need be present and/or that further layers may additionally be present.

An organic electroluminescent device of the invention may contain two or more light-emitting layers. According to the invention, at least one of the light-emitting layers contains a compositions as described above. More preferably, these emission layers in this case have several emission maxima between 380 nm and 750 nm overall, such that the overall result is white emission; in other words, various emitting compounds which may fluoresce or phosphoresce and which emit blue or yellow or orange or red light are used in the light-emitting layers. Especially preferred are three-layer systems, i.e. systems having three light-emitting layers, where the three layers show blue, green and orange or red emission (for the basic construction see, for example, WO 2005/011013). It should be noted that, for the production of white light, rather than a plurality of colour-emitting emitter compounds, an emitter compound used individually which emits over a broad wavelength range may also be suitable.

Suitable charge transport materials as usable in the hole injection or hole transport layer or electron blocker layer or in the electron transport layer of the organic electroluminescent device of the invention are, for example, the compounds disclosed in Y. Shirota et al., Chem. Rev. 2007, 107(4), 953-1010, or other materials as used in these layers according to the prior art.

Materials used for the electron transport layer may be any materials as used according to the prior art as electron transport materials in the electron transport layer. Especially suitable are aluminium complexes, for example Alq₃, zirconium complexes, for example Zrq₄, benzimidazole derivatives, triazine derivatives, pyrimidine derivatives, pyridine derivatives, pyrazine derivatives, quinoxaline derivatives, quinoline derivatives, oxadiazole derivatives, aromatic ketones, lactams, boranes, diazaphosphole derivatives and phosphine oxide derivatives. Further suitable materials are derivatives of the abovementioned compounds as disclosed in JP 2000/053957, WO 2003/060956, WO 2004/028217, WO 2004/080975 and WO 2010/072300. WO 2009/124627 relates to 9,9′-disubstituted fluorene derivatives being suitable for example as electron transport material; here, the 9,9′-positions can be substituted with triazine containing groups as shown in the following examples:

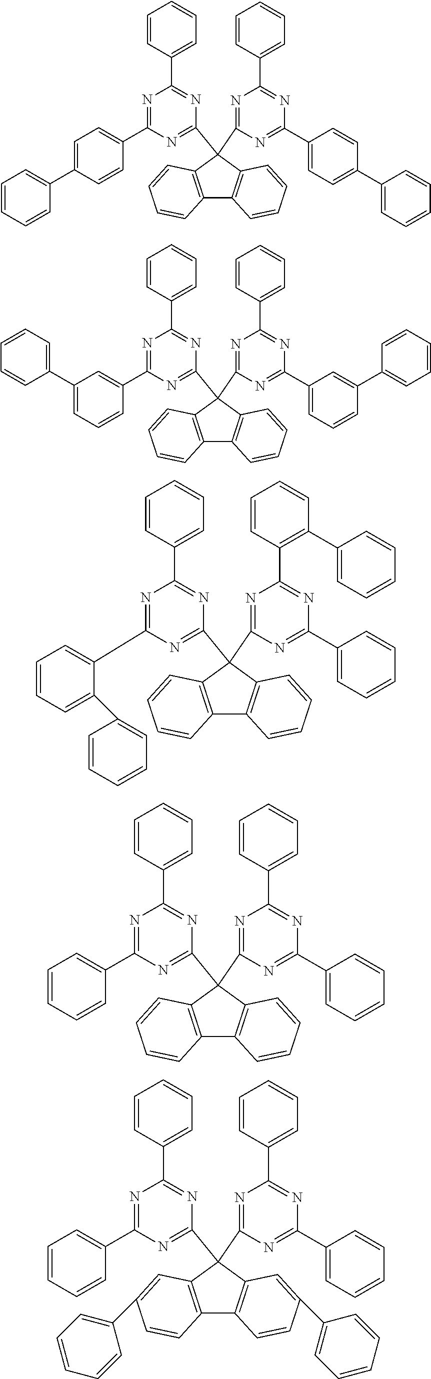

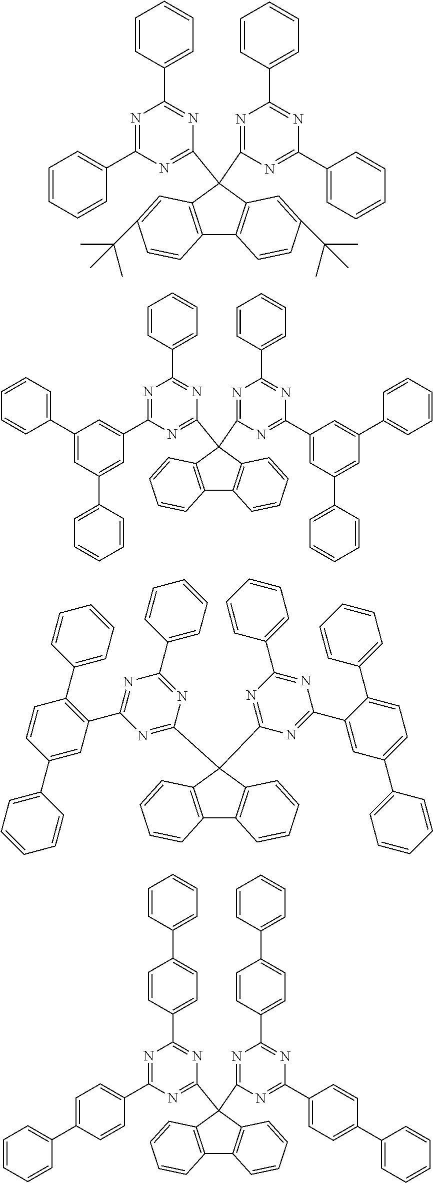

Preferred hole transport materials are especially materials which can be used in a hole transport, hole injection or electron blocker layer, such as indenofluoreneamine derivatives (for example according to WO 06/122630 or WO 06/100896), the amine derivatives disclosed in EP 1661888, hexaazatriphenylene derivatives (for example according to WO 01/049806), amine derivatives having fused aromatic systems (for example according to U.S. Pat. No. 5,061,569), the amine derivatives disclosed in WO 95/09147, monobenzoindenofluoreneamines (for example according to WO 08/006449), dibenzoindenofluoreneamines (for example according to WO 07/140847), spirobifluoreneamines (for example according to WO 2012/034627 or the as yet unpublished EP 12000929.5), fluoreneamines (for example according to WO 2014/015937, WO 2014/015938 and WO 2014/015935), spirodibenzopyranamines (for example according to WO 2013/083216) and dihydroacridine derivatives (for example WO 2012/150001).

The following compounds HT-1 to HT-30 are particularly well suited for use in a layer with hole transporting function of an OLED. This applies not only to OLEDs according to the definitions and claims of the present application, but to OLEDs in general:

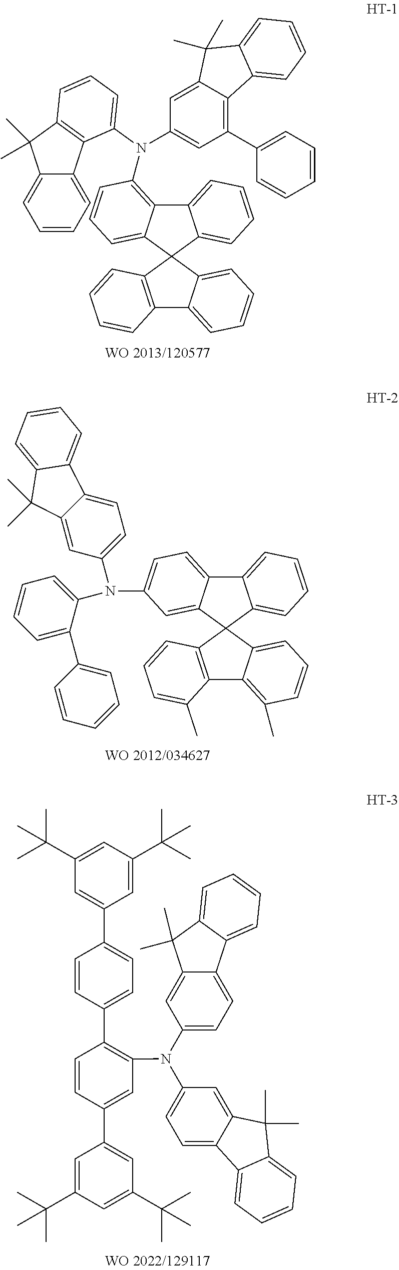 [SMILES: CC1(C)c2ccccc2-c2c(-c3ccccc3)cc(N(c3cccc4c3-c3ccccc3C4(C)C)c3cccc4c3-c3ccccc3C43c4ccccc4-c4ccccc43)cc21 ; Cc1cccc2c1-c1c(C)cccc1C21c2ccccc2-c2ccc(N(c3ccc4c(c3)C(C)(C)c3ccccc3-4)c3ccccc3-c3ccccc3)cc21 ; CC(C)(C)c1cc(-c2ccc(-c3ccc(-c4cc(C(C)(C)C)cc(C(C)(C)C)c4)cc3N(c3ccc4c(c3)C(C)(C)c3ccccc3-4)c3ccc4c(c3)C(C)(C)c3ccccc3-4)cc2)cc(C(C)(C)C)c1]

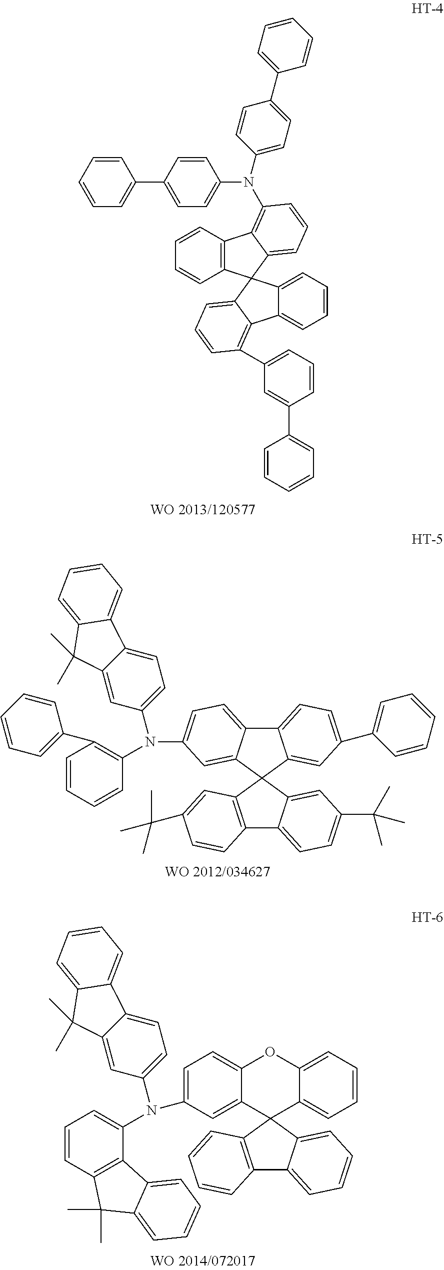 [SMILES: c1ccc(-c2ccc(N(c3ccc(-c4ccccc4)cc3)c3cccc4c3-c3ccccc3C43c4ccccc4-c4c(-c5cccc(-c6ccccc6)c5)cccc43)cc2)cc1 ; CC(C)(C)c1ccc2c(c1)C1(c3cc(-c4ccccc4)ccc3-c3ccc(N(c4ccc5c(c4)C(C)(C)c4ccccc4-5)c4ccccc4-c4ccccc4)cc31)c1cc(C(C)(C)C)ccc1-2 ; CC1(C)c2ccccc2-c2ccc(N(c3ccc4c(c3)C3(c5ccccc5O4)c4ccccc4-c4ccccc43)c3cccc4c3-c3ccccc3C4(C)C)cc21]

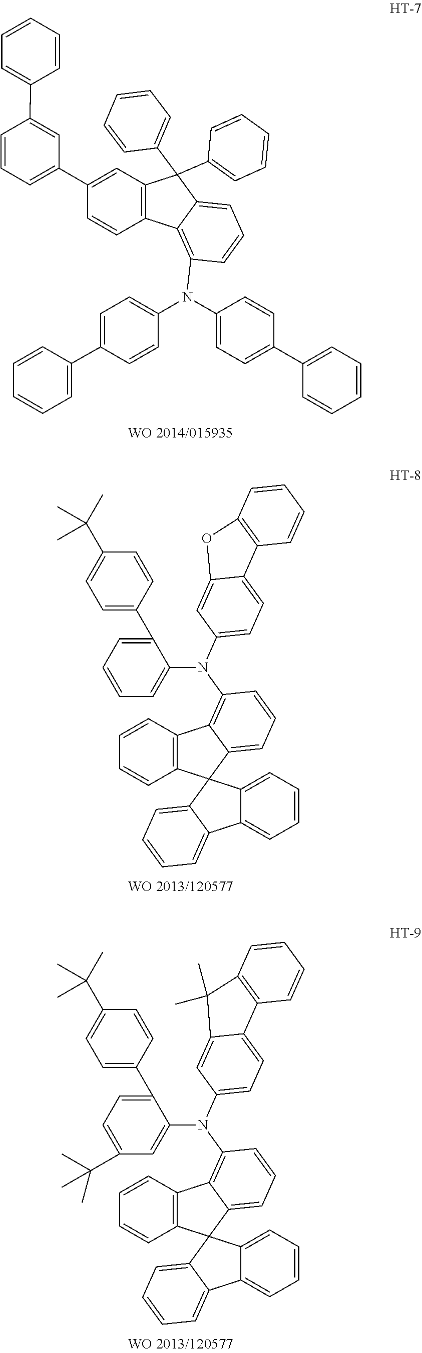 [SMILES: c1ccc(-c2ccc(N(c3ccc(-c4ccccc4)cc3)c3cccc4c3-c3ccc(-c5cccc(-c6ccccc6)c5)cc3C4(c3ccccc3)c3ccccc3)cc2)cc1 ; CC(C)(C)c1ccc(-c2ccccc2N(c2ccc3c(c2)oc2ccccc23)c2cccc3c2-c2ccccc2C32c3ccccc3-c3ccccc32)cc1 ; CC(C)(C)c1ccc(-c2ccc(C(C)(C)C)cc2N(c2ccc3c(c2)C(C)(C)c2ccccc2-3)c2cccc3c2-c2ccccc2C32c3ccccc3-c3ccccc32)cc1]

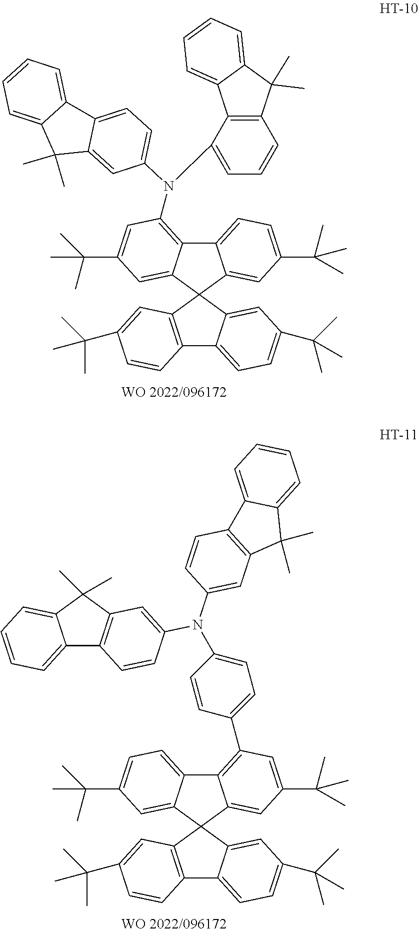 [SMILES: CC(C)(C)c1ccc2c(c1)C1(c3cc(C(C)(C)C)ccc3-2)c2cc(C(C)(C)C)ccc2-c2c(N(c3ccc4c(c3)C(C)(C)c3ccccc3-4)c3cccc4c3-c3ccccc3C4(C)C)cc(C(C)(C)C)cc21 ; CC(C)(C)c1ccc2c(c1)C1(c3cc(C(C)(C)C)ccc3-2)c2cc(C(C)(C)C)ccc2-c2c(-c3ccc(N(c4ccc5c(c4)C(C)(C)c4ccccc4-5)c4ccc5c(c4)C(C)(C)c4ccccc4-5)cc3)cc(C(C)(C)C)cc21]

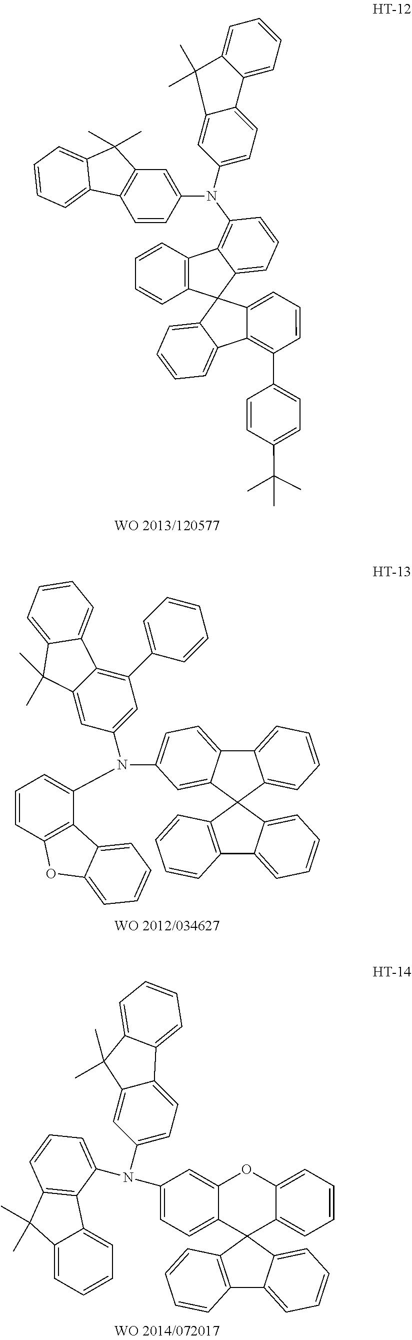

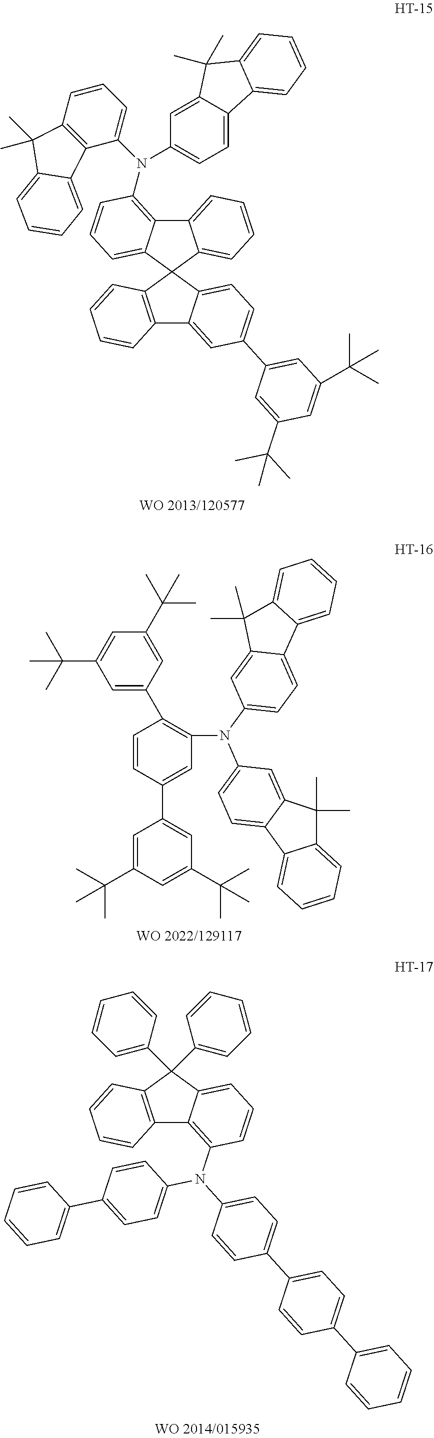

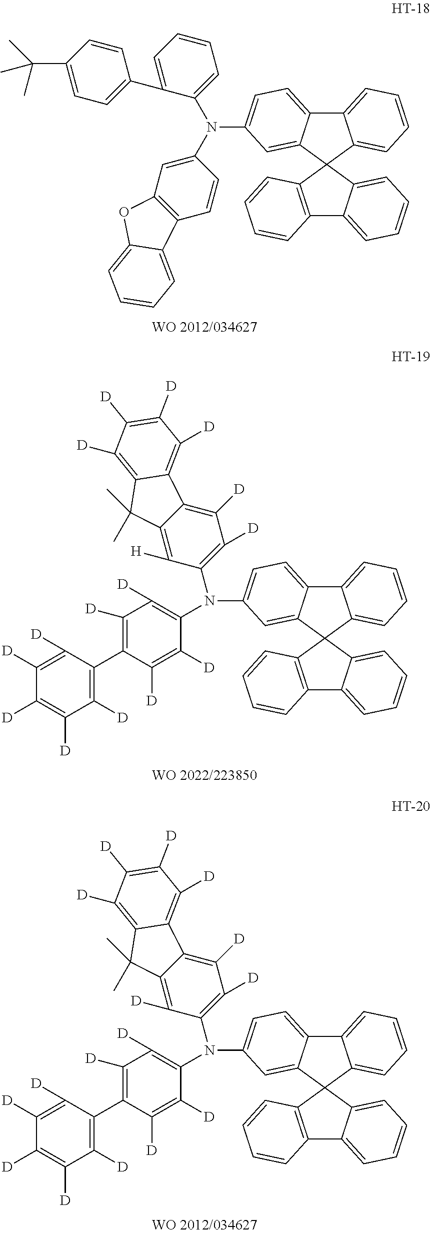 [SMILES: CC(C)(C)c1ccc(-c2ccccc2N(c2ccc3c(c2)C2(c4ccccc4-c4ccccc42)c2ccccc2-3)c2ccc3c(c2)oc2ccccc23)cc1 ; [2H]c1c(N(c2ccc3c(c2)C2(c4ccccc4-c4ccccc42)c2ccccc2-3)c2c([2H])c([2H])c(-c3c([2H])c([2H])c([2H])c([2H])c3[2H])c([2H])c2[2H])cc2c(c1[2H])-c1c([2H])c([2H])c([2H])c([2H])c1C2(C)C ; [2H]c1c([2H])c([2H])c(-c2c([2H])c([2H])c(N(c3ccc4c(c3)C3(c5ccccc5-c5ccccc53)c3ccccc3-4)c3c([2H])c([2H])c4c(c3[2H])C(C)(C)c3c([2H])c([2H])c([2H])c([2H])c3-4)c([2H])c2[2H])c([2H])c1[2H]]

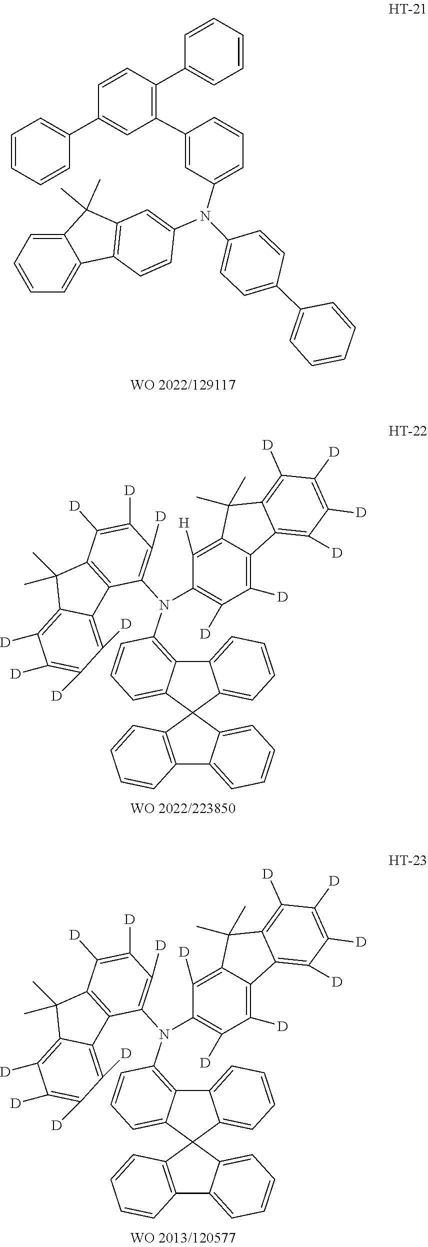 [SMILES: CC1(C)c2ccccc2-c2ccc(N(c3ccc(-c4ccccc4)cc3)c3cccc(-c4cc(-c5ccccc5)ccc4-c4ccccc4)c3)cc21 ; [2H]c1c(N(c2cccc3c2-c2ccccc2C32c3ccccc3-c3ccccc32)c2c([2H])c([2H])c([2H])c3c2-c2c([2H])c([2H])c([2H])c([2H])c2C3(C)C)cc2c(c1[2H])-c1c([2H])c([2H])c([2H])c([2H])c1C2(C)C ; [2H]c1c([2H])c([2H])c2c(c1[2H])-c1c([2H])c([2H])c(N(c3cccc4c3-c3ccccc3C43c4ccccc4-c4ccccc43)c3c([2H])c([2H])c([2H])c4c3-c3c([2H])c([2H])c([2H])c([2H])c3C4(C)C)c([2H])c1C2(C)C]

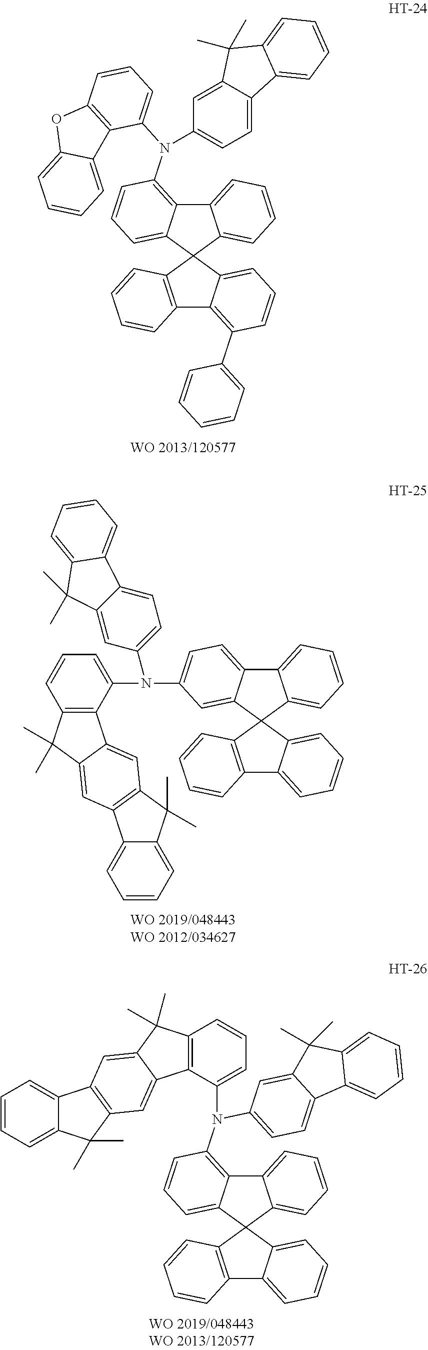 [SMILES: CC1(C)c2ccccc2-c2ccc(N(c3cccc4c3-c3ccccc3C43c4ccccc4-c4c(-c5ccccc5)cccc43)c3cccc4oc5ccccc5c34)cc21 ; CC1(C)c2ccccc2-c2ccc(N(c3ccc4c(c3)C3(c5ccccc5-c5ccccc53)c3ccccc3-4)c3cccc4c3-c3cc5c(cc3C4(C)C)-c3ccccc3C5(C)C)cc21 ; CC1(C)c2ccccc2-c2ccc(N(c3cccc4c3-c3cc5c(cc3C4(C)C)-c3ccccc3C5(C)C)c3cccc4c3-c3ccccc3C43c4ccccc4-c4ccccc43)cc21]

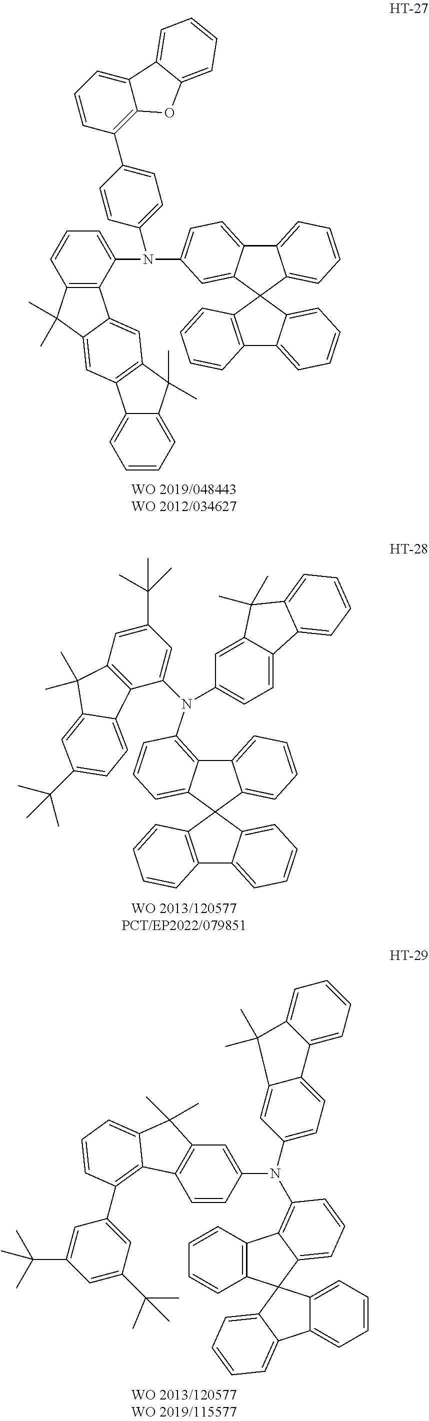 [SMILES: CC1(C)c2ccccc2-c2cc3c(cc21)-c1c(N(c2ccc(-c4cccc5c4oc4ccccc45)cc2)c2ccc4c(c2)C2(c5ccccc5-c5ccccc52)c2ccccc2-4)cccc1C3(C)C ; CC(C)(C)c1ccc2c(c1)C(C)(C)c1cc(C(C)(C)C)cc(N(c3ccc4c(c3)C(C)(C)c3ccccc3-4)c3cccc4c3-c3ccccc3C43c4ccccc4-c4ccccc43)c1-2 ; CC(C)(C)c1cc(-c2cccc3c2-c2ccc(N(c4ccc5c(c4)C(C)(C)c4ccccc4-5)c4cccc5c4-c4ccccc4C54c5ccccc5-c5ccccc54)cc2C3(C)C)cc(C(C)(C)C)c1]

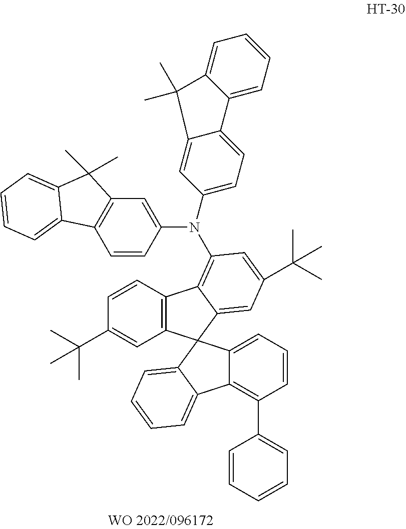 [SMILES: CC(C)(C)c1ccc2c(c1)C1(c3ccccc3-c3c(-c4ccccc4)cccc31)c1cc(C(C)(C)C)cc(N(c3ccc4c(c3)C(C)(C)c3ccccc3-4)c3ccc4c(c3)C(C)(C)c3ccccc3-4)c1-2]

The compounds HT-1 to HT-30 can be used generally in any hole transporting layers of OLEDs. The term hole transporting layer here means any layer of an OLED which is located between anode and emitting layer. The term OLED is not particular restricted, and applies to all OLED, in particular commonly used OLED setups at the filing date of the present application.

The compounds HT-1 to HT-30 can be prepared according to procedures which are disclosed in the application texts listed in the above table, below the respective compounds HT-1 to HT-30. The teaching regarding use of the compounds, and methods of preparation of the compounds, that is contained in the above-mentioned application texts is herewith explicitly included by reference into the present disclosure. The compounds HT-1 to HT-30 show excellent properties when used in OLEDs, in particular excellent lifetime and efficiency. This is especially the case when they are used in a hole transporting layer of the OLED.

Preferred cathodes of electronic devices are metals having a low work function, metal alloys or multilayer structures composed of various metals, for example alkaline earth metals, alkali metals, main group metals or lanthanoids (e.g. Ca, Ba, Mg, Al, In, Mg, Yb, Sm, etc.). Additionally suitable are alloys composed of an alkali metal or alkaline earth metal and silver, for example an alloy composed of magnesium and silver. In the case of multilayer structures, in addition to the metals mentioned, it is also possible to use further metals having a relatively high work function, for example Ag or Al, in which case combinations of the metals such as Ca/Ag, Mg/Ag or Ba/Ag, for example, are generally used. It may also be preferable to introduce a thin interlayer of a material having a high dielectric constant between a metallic cathode and the organic semiconductor. Examples of useful materials for this purpose are alkali metal or alkaline earth metal fluorides, but also the corresponding oxides or carbonates (e.g. LiF, Li₂O, BaF₂, MgO, NaF, CsF, Cs₂CO₃, etc.). It is also possible to use lithium quinolinate (LiQ) for this purpose. The layer thickness of this layer is preferably between 0.5 and 5 nm.

Preferred anodes are materials having a high work function. Preferably, the anode has a work function of greater than 4.5 eV versus vacuum. Firstly, metals having a high redox potential are suitable for this purpose, for example Ag, Pt or Au. Secondly, metal/metal oxide electrodes (e.g. Al/Ni/NiOₓ, Al/PtOₓ) may also be preferred. For some applications, at least one of the electrodes has to be transparent or partly transparent in order to enable either the irradiation of the organic material (organic solar cell) or the emission of light (OLED, O-LASER). Preferred anode materials here are conductive mixed metal oxides.

Particular preference is given to indium tin oxide (ITO) or indium zinc oxide (IZO). Preference is further given to conductive doped organic materials, especially conductive doped polymers. In addition, the anode may also consist of two or more layers, for example of an inner layer of ITO and an outer layer of a metal oxide, preferably tungsten oxide, molybdenum oxide or vanadium oxide.

The organic electronic device, in the course of production, is appropriately (according to the application) structured, contact-connected and finally sealed, since the lifetime of the devices of the invention is shortened in the presence of water and/or air.

In a further preferred embodiment, the organic electronic device comprising the composition of the invention is characterized in that one or more organic layers comprising the composition of the invention are coated by a sublimation method. In this case, the materials are applied by vapour deposition in vacuum sublimation systems at an initial pressure of less than 10⁻⁵ mbar, preferably less than 10⁻⁶ mbar. In this case, however, it is also possible that the initial pressure is even lower, for example less than 10⁻⁷ mbar.

Preference is likewise given to an organic electroluminescent device, characterized in that one or more layers are coated by the OVPD (organic vapour phase deposition) method or with the aid of a carrier gas sublimation. In this case, the materials are applied at a pressure between 10-5 mbar and 1 bar. A special case of this method is the OVJP (organic vapour jet printing) method, in which the materials are applied directly by a nozzle and thus structured (for example, M. S. Arnold et al., Appl. Phys. Lett. 2008, 92, 053301).

Preference is additionally given to an organic electroluminescent device, characterized in that one or more organic layers comprising the composition of the invention are produced from solution, for example by spin-coating, or by any printing method, for example screen printing, flexographic printing, nozzle printing or offset printing, but more preferably LITI (light-induced thermal imaging, thermal transfer printing) or inkjet printing. For this purpose, soluble compounds of the components of the composition of the invention are needed. High solubility can be achieved by suitable substitution of the corresponding compounds. Processing from solution has the advantage that the layer comprising the composition of the invention can be applied in a very simple and inexpensive manner. This technique is especially suitable for the mass production of organic electronic devices.

In addition, hybrid methods are possible, in which, for example, one or more layers are applied from solution and one or more further layers are applied by vapour deposition.

These methods are known in general terms to those skilled in the art and can be applied to organic electroluminescent devices.

The invention therefore further provides a process for producing an organic electronic device comprising a composition of the invention as described above or described as preferred, characterized in that at least one organic layer comprising a composition of the invention is applied by gas phase deposition, especially by a sublimation method and/or by an OVPD (organic vapour phase deposition) method and/or with the aid of carrier gas sublimation, or from solution, especially by spin-coating or by a printing method.

In the production of an organic electronic device by means of gas phase deposition, there are two methods in principle by which an organic layer which is to comprise the composition of the invention and which may comprise multiple different constituents can be applied, or applied by vapour deposition, to any substrate. Firstly, the materials used can each be initially charged in a material source and ultimately evaporated from the different material sources (“co-evaporation”). Secondly, the various materials can be premixed (premix systems) and the mixture can be initially charged in a single material source from which it is ultimately evaporated (“premix evaporation”). In this way, it is possible in a simple and rapid manner to achieve the vapour deposition of a layer with homogeneous distribution of the components without a need for precise actuation of a multitude of material sources.

The invention accordingly further provides a process characterized in that the compositions comprising the compounds of formula (1), (2), (3) as described above or described as preferred are deposited from the gas phase successively or simultaneously from at least two material sources, optionally with other materials as described above or described as preferred, and form the organic layer.

The invention accordingly further provides a process characterized in that the composition of the invention as described above or described as preferred is utilized as material source for the gas phase deposition of the host system and, optionally together with further materials, forms the organic layer.

The invention further provides a process for producing an organic electronic device comprising a composition of the invention as described above or described as preferred, characterized in that the formulation of the invention as described above is used to apply the organic layer.

It should be pointed out that variations of the embodiments described in the present invention are covered by the scope of this invention. Any feature disclosed in the present invention may, unless this is explicitly ruled out, be exchanged for alternative features which serve the same purpose or an equivalent or similar purpose. Any feature disclosed in the present invention, unless stated otherwise, should therefore be considered as an example from a generic series or as an equivalent or similar feature.

All features of the present invention may be combined with one another in any manner, unless particular features and/or steps are mutually exclusive. This is especially true of preferred features of the present invention. Equally, features of non-essential combinations may be used separately (and not in combination).

The technical teaching disclosed with the present invention may be abstracted and combined with other examples. The invention is illustrated in more detail by the examples which follow, without any intention of restricting it thereby.

### SYNTHESIS EXAMPLES

### Synthesis of 9H,9′H-4,4′-bicarbazole

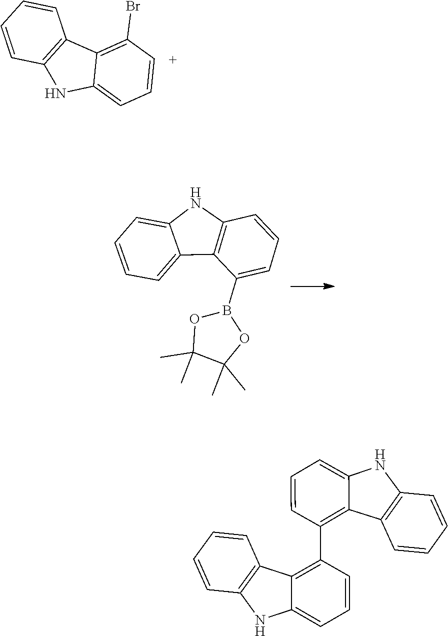 [SMILES: Brc1cccc2[nH]c3ccccc3c12 ; CC1(C)OB(c2cccc3[nH]c4ccccc4c23)OC1(C)C ; c1ccc2c(c1)[nH]c1cccc(-c3cccc4[nH]c5ccccc5c34)c12]

15 g (60.95 mmol) of 4-bromo-9H-carbazole, 21.44 g (73.14 mmol) of 4-(4,4,5,5-tetramethyl-1,3,2-dioxaborolan-2-yl)-9H-carbazole and 30.88 g (134.09 mmol) of potassium phosphate are dissolved in dry and degassed THF under an Argon atmosphere. 1.58 g (1.83 mmol) of XPhos Palladacycle Gen3 Catalyst are added in order to initiate the reaction. The reaction solution is stirred under reflux or until completion. The organic phase is washed with 100 ml of water and extracted with heptane. The combined organic phases are evaporated. The crude product is precipitated from the residual oil by the addition of 200 ml of ethanol and purified by column chromatography yielding 88% final product.

The following derivatives can be synthesized in an analogous way with the given yield:

| Starting Material 1 | Starting Material 2 | Product | Yield |
|---|---|---|---|
| 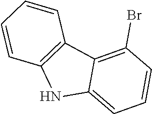 [SMILES: Brc1cccc2[nH]c3ccccc3c12] | 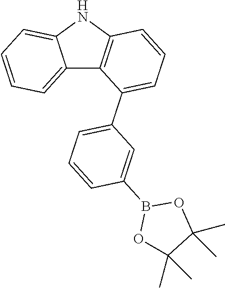 [SMILES: CC1(C)OB(c2cccc(-c3cccc4[nH]c5ccccc5c34)c2)OC1(C)C] | 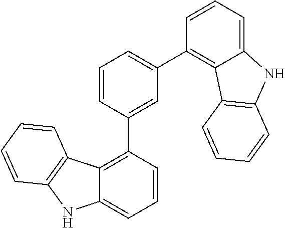 [SMILES: c1cc(-c2cccc3[nH]c4ccccc4c23)cc(-c2cccc3[nH]c4ccccc4c23)c1] | 82% |
| 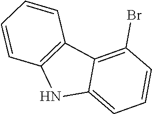 [SMILES: Brc1cccc2[nH]c3ccccc3c12] | 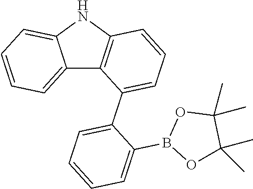 [SMILES: CC1(C)OB(c2ccccc2-c2cccc3[nH]c4ccccc4c23)OC1(C)C] | 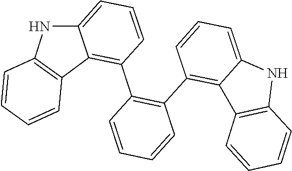 [SMILES: c1ccc(-c2cccc3[nH]c4ccccc4c23)c(-c2cccc3[nH]c4ccccc4c23)c1] | 79% |
| 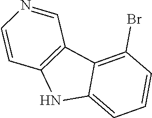 [SMILES: Brc1cccc2[nH]c3ccncc3c12] 1015460-62-4 | 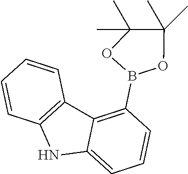 [SMILES: CC1(C)OB(c2cccc3[nH]c4ccccc4c23)OC1(C)C] 1255309-13-7 | 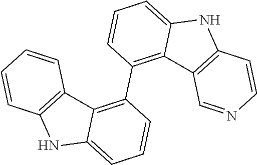 [SMILES: c1ccc2c(c1)[nH]c1cccc(-c3cccc4[nH]c5ccncc5c34)c12] | 73% |
| 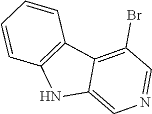 [SMILES: Brc1cncc2[nH]c3ccccc3c12] 1428635-31-7 | 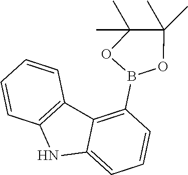 [SMILES: CC1(C)OB(c2cccc3[nH]c4ccccc4c23)OC1(C)C] 1255309-13-7 | 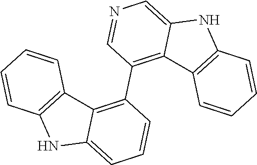 [SMILES: c1ccc2c(c1)[nH]c1cccc(-c3cncc4[nH]c5ccccc5c34)c12] | 70% |
| 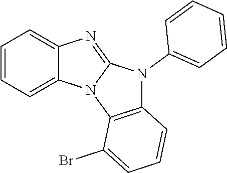 [SMILES: Brc1cccc2c1n1c3ccccc3nc1n2-c1ccccc1] 2259862-26-3 | 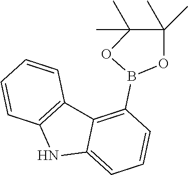 [SMILES: CC1(C)OB(c2cccc3[nH]c4ccccc4c23)OC1(C)C] 1255309-13-7 | 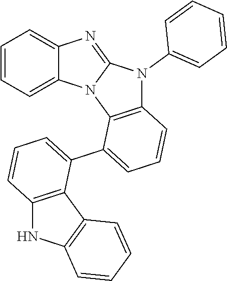 [SMILES: c1ccc(-n2c3cccc(-c4cccc5[nH]c6ccccc6c45)c3n3c4ccccc4nc23)cc1] | 79% |

### Synthesis of 9,9′-bis(4,6-diphenyl-1,3,5-triazin-2-yl)-9H,9′H-4,4′-bicarbazole

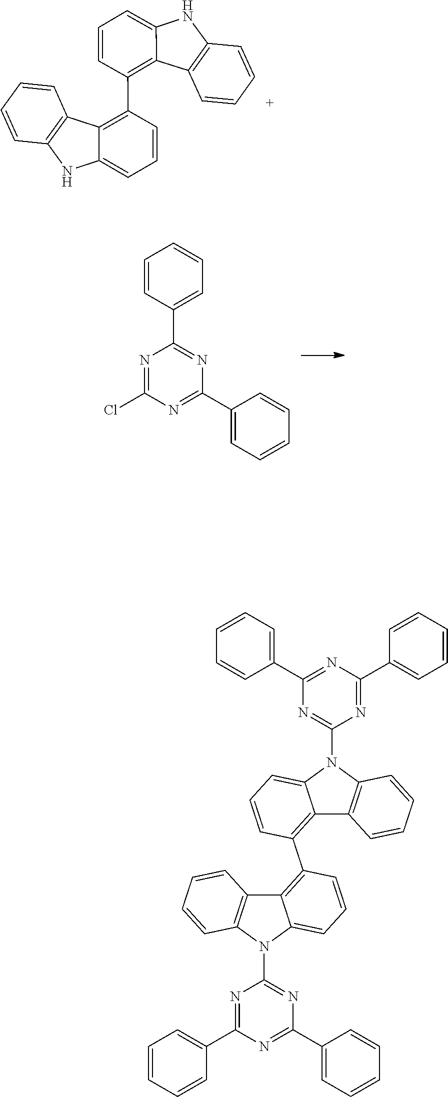 [SMILES: c1ccc2c(c1)[nH]c1cccc(-c3cccc4[nH]c5ccccc5c34)c12 ; Clc1nc(-c2ccccc2)nc(-c2ccccc2)n1 ; c1ccc(-c2nc(-c3ccccc3)nc(-n3c4ccccc4c4c(-c5cccc6c5c5ccccc5n6-c5nc(-c6ccccc6)nc(-c6ccccc6)n5)cccc43)n2)cc1]

17.9 g (53.85 mmol) of 9H,9′H-4,4′-bicarbazole and of 28.87 g (107.7 mmol) of 2-chloro-4,6-diphenyl-1,3,5-triazine are dissolved in 500 ml of DMF under inert conditions. After this 37.71 g (269.26 mmol) of potassium carbonate is added to the solution. The reaction is stirred under reflux until completion at room temperature. 300 ml of water is added to precipitate the crude product. The reaction product is filtered and dried and can be purified by extraction with suitable solvents and column chromatography with a total reaction yield of 51%.

The following derivatives can be synthesized in an analogous way with the given yield:

| Starting Material 1 | Starting Material 2 | Product | Yield |
|---|---|---|---|
| 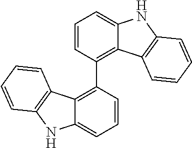 [SMILES: c1ccc2c(c1)[nH]c1cccc(-c3cccc4[nH]c5ccccc5c34)c12] | 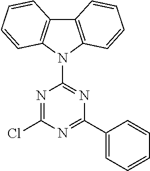 [SMILES: Clc1nc(-c2ccccc2)nc(-n2c3ccccc3c3ccccc32)n1] | 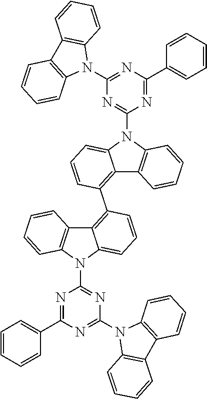 [SMILES: c1ccc(-c2nc(-n3c4ccccc4c4ccccc43)nc(-n3c4ccccc4c4c(-c5cccc6c5c5ccccc5n6-c5nc(-c6ccccc6)nc(-n6c7ccccc7c7ccccc76)n5)cccc43)n2)cc1] | 61% |
| 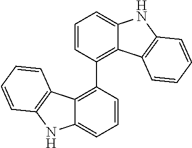 [SMILES: c1ccc2c(c1)[nH]c1cccc(-c3cccc4[nH]c5ccccc5c34)c12] | 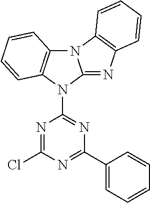 [SMILES: Clc1nc(-c2ccccc2)nc(-n2c3ccccc3n3c4ccccc4nc23)n1] | 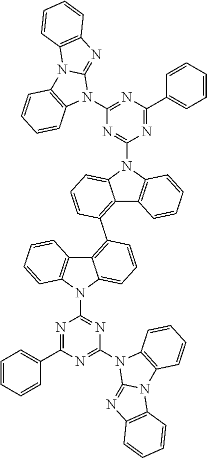 [SMILES: c1ccc(-c2nc(-n3c4ccccc4c4c(-c5cccc6c5c5ccccc5n6-c5nc(-c6ccccc6)nc(-n6c7ccccc7n7c8ccccc8nc67)n5)cccc43)nc(-n3c4ccccc4n4c5ccccc5nc34)n2)cc1] | 70% |
| 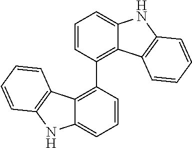 [SMILES: c1ccc2c(c1)[nH]c1cccc(-c3cccc4[nH]c5ccccc5c34)c12] | 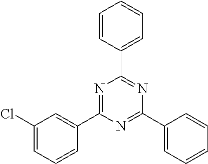 [SMILES: Clc1cccc(-c2nc(-c3ccccc3)nc(-c3ccccc3)n2)c1] | 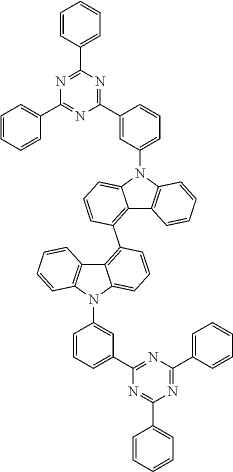 [SMILES: c1ccc(-c2nc(-c3ccccc3)nc(-c3cccc(-n4c5ccccc5c5c(-c6cccc7c6c6ccccc6n7-c6cccc(-c7nc(-c8ccccc8)nc(-c8ccccc8)n7)c6)cccc54)c3)n2)cc1] | 46% |
| 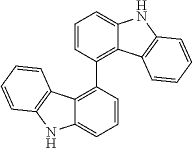 [SMILES: c1ccc2c(c1)[nH]c1cccc(-c3cccc4[nH]c5ccccc5c34)c12] | 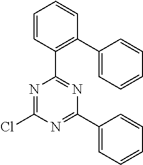 [SMILES: Clc1nc(-c2ccccc2)nc(-c2ccccc2-c2ccccc2)n1] | 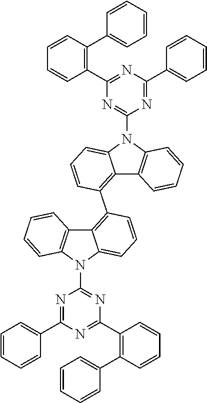 [SMILES: c1ccc(-c2nc(-c3ccccc3-c3ccccc3)nc(-n3c4ccccc4c4c(-c5cccc6c5c5ccccc5n6-c5nc(-c6ccccc6)nc(-c6ccccc6-c6ccccc6)n5)cccc43)n2)cc1] | 51% |
| 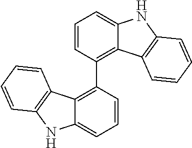 [SMILES: c1ccc2c(c1)[nH]c1cccc(-c3cccc4[nH]c5ccccc5c34)c12] | 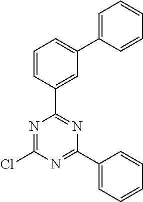 [SMILES: Clc1nc(-c2ccccc2)nc(-c2cccc(-c3ccccc3)c2)n1] | 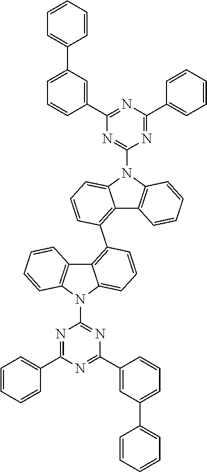 [SMILES: c1ccc(-c2cccc(-c3nc(-c4ccccc4)nc(-n4c5ccccc5c5c(-c6cccc7c6c6ccccc6n7-c6nc(-c7ccccc7)nc(-c7cccc(-c8ccccc8)c7)n6)cccc54)n3)c2)cc1] | 65% |
| 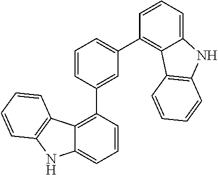 [SMILES: c1cc(-c2cccc3[nH]c4ccccc4c23)cc(-c2cccc3[nH]c4ccccc4c23)c1] | 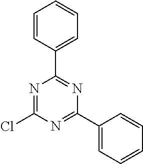 [SMILES: Clc1nc(-c2ccccc2)nc(-c2ccccc2)n1] | 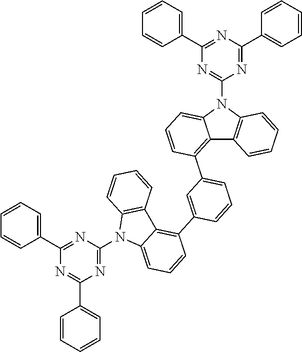 [SMILES: c1ccc(-c2nc(-c3ccccc3)nc(-n3c4ccccc4c4c(-c5cccc(-c6cccc7c6c6ccccc6n7-c6nc(-c7ccccc7)nc(-c7ccccc7)n6)c5)cccc43)n2)cc1] | 47% |
| 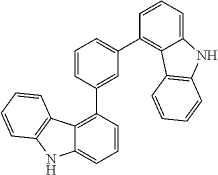 [SMILES: c1cc(-c2cccc3[nH]c4ccccc4c23)cc(-c2cccc3[nH]c4ccccc4c23)c1] | 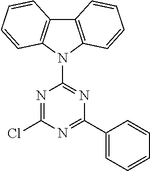 [SMILES: Clc1nc(-c2ccccc2)nc(-n2c3ccccc3c3ccccc32)n1] | 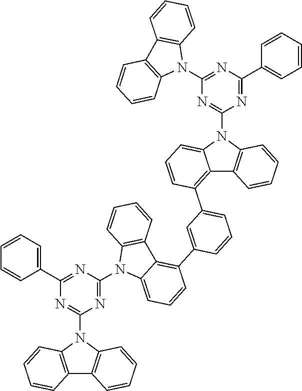 [SMILES: c1ccc(-c2nc(-n3c4ccccc4c4ccccc43)nc(-n3c4ccccc4c4c(-c5cccc(-c6cccc7c6c6ccccc6n7-c6nc(-c7ccccc7)nc(-n7c8ccccc8c8ccccc87)n6)c5)cccc43)n2)cc1] | 42% |
| 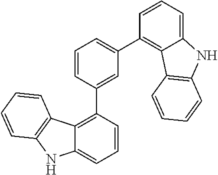 [SMILES: c1cc(-c2cccc3[nH]c4ccccc4c23)cc(-c2cccc3[nH]c4ccccc4c23)c1] | 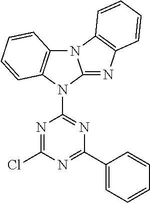 [SMILES: Clc1nc(-c2ccccc2)nc(-n2c3ccccc3n3c4ccccc4nc23)n1] | 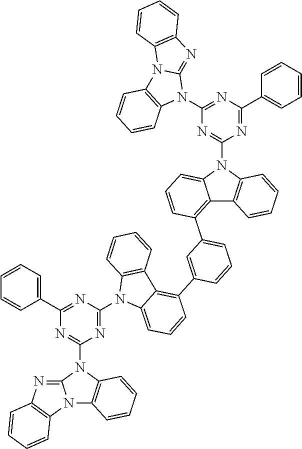 [SMILES: c1ccc(-c2nc(-n3c4ccccc4c4c(-c5cccc(-c6cccc7c6c6ccccc6n7-c6nc(-c7ccccc7)nc(-n7c8ccccc8n8c9ccccc9nc78)n6)c5)cccc43)nc(-n3c4ccccc4n4c5ccccc5nc34)n2)cc1] | 68% |
| 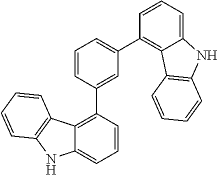 [SMILES: c1cc(-c2cccc3[nH]c4ccccc4c23)cc(-c2cccc3[nH]c4ccccc4c23)c1] | 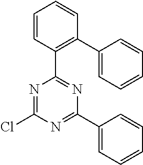 [SMILES: Clc1nc(-c2ccccc2)nc(-c2ccccc2-c2ccccc2)n1] | 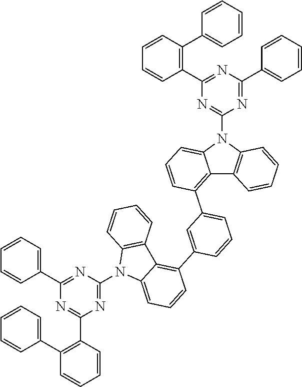 [SMILES: c1ccc(-c2nc(-c3ccccc3-c3ccccc3)nc(-n3c4ccccc4c4c(-c5cccc(-c6cccc7c6c6ccccc6n7-c6nc(-c7ccccc7)nc(-c7ccccc7-c7ccccc7)n6)c5)cccc43)n2)cc1] | 46% |
| 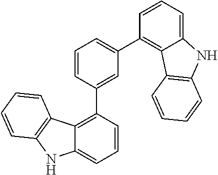 [SMILES: c1cc(-c2cccc3[nH]c4ccccc4c23)cc(-c2cccc3[nH]c4ccccc4c23)c1] | 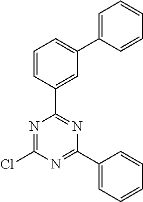 [SMILES: Clc1nc(-c2ccccc2)nc(-c2cccc(-c3ccccc3)c2)n1] | 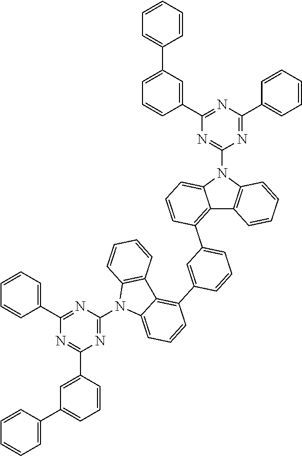 [SMILES: c1ccc(-c2cccc(-c3nc(-c4ccccc4)nc(-n4c5ccccc5c5c(-c6cccc(-c7cccc8c7c7ccccc7n8-c7nc(-c8ccccc8)nc(-c8cccc(-c9ccccc9)c8)n7)c6)cccc54)n3)c2)cc1] | 67% |
| 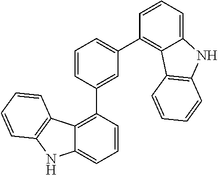 [SMILES: c1cc(-c2cccc3[nH]c4ccccc4c23)cc(-c2cccc3[nH]c4ccccc4c23)c1] | 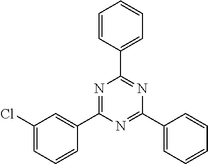 [SMILES: Clc1cccc(-c2nc(-c3ccccc3)nc(-c3ccccc3)n2)c1] | 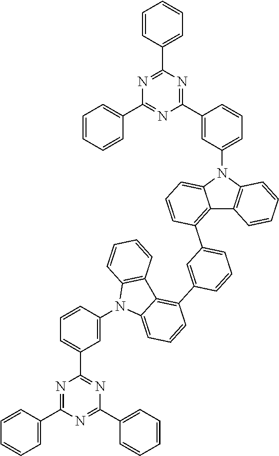 [SMILES: c1ccc(-c2nc(-c3ccccc3)nc(-c3cccc(-n4c5ccccc5c5c(-c6cccc(-c7cccc8c7c7ccccc7n8-c7cccc(-c8nc(-c9ccccc9)nc(-c9ccccc9)n8)c7)c6)cccc54)c3)n2)cc1] | 66% |
| 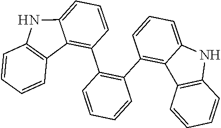 [SMILES: c1ccc(-c2cccc3[nH]c4ccccc4c23)c(-c2cccc3[nH]c4ccccc4c23)c1] | 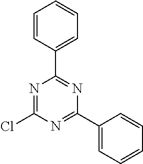 [SMILES: Clc1nc(-c2ccccc2)nc(-c2ccccc2)n1] | 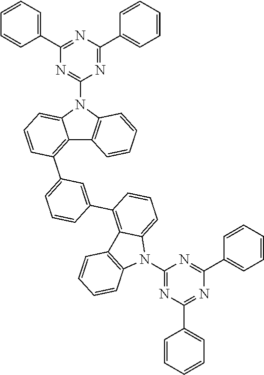 [SMILES: c1ccc(-c2nc(-c3ccccc3)nc(-n3c4ccccc4c4c(-c5cccc(-c6cccc7c6c6ccccc6n7-c6nc(-c7ccccc7)nc(-c7ccccc7)n6)c5)cccc43)n2)cc1] | 55% |
| 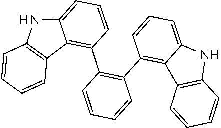 [SMILES: c1ccc(-c2cccc3[nH]c4ccccc4c23)c(-c2cccc3[nH]c4ccccc4c23)c1] | 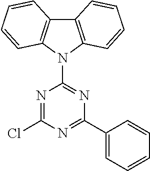 [SMILES: Clc1nc(-c2ccccc2)nc(-n2c3ccccc3c3ccccc32)n1] | 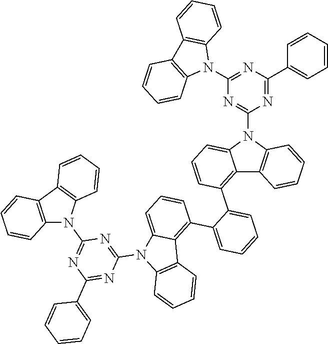 [SMILES: c1ccc(-c2nc(-n3c4ccccc4c4ccccc43)nc(-n3c4ccccc4c4c(-c5ccccc5-c5cccc6c5c5ccccc5n6-c5nc(-c6ccccc6)nc(-n6c7ccccc7c7ccccc76)n5)cccc43)n2)cc1] | 64% |
| 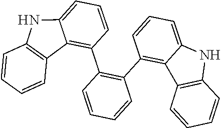 [SMILES: c1ccc(-c2cccc3[nH]c4ccccc4c23)c(-c2cccc3[nH]c4ccccc4c23)c1] | 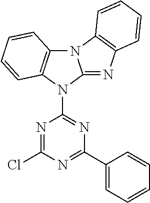 [SMILES: Clc1nc(-c2ccccc2)nc(-n2c3ccccc3n3c4ccccc4nc23)n1] | 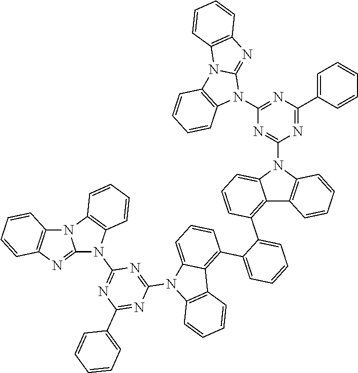 [SMILES: c1ccc(-c2nc(-n3c4ccccc4c4c(-c5ccccc5-c5cccc6c5c5ccccc5n6-c5nc(-c6ccccc6)nc(-n6c7ccccc7n7c8ccccc8nc67)n5)cccc43)nc(-n3c4ccccc4n4c5ccccc5nc34)n2)cc1] | 51 |
| 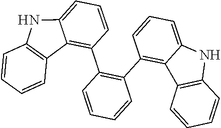 [SMILES: c1ccc(-c2cccc3[nH]c4ccccc4c23)c(-c2cccc3[nH]c4ccccc4c23)c1] | 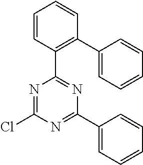 [SMILES: Clc1nc(-c2ccccc2)nc(-c2ccccc2-c2ccccc2)n1] | 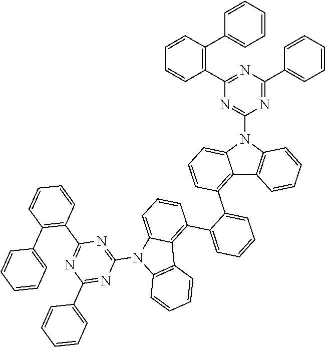 [SMILES: c1ccc(-c2nc(-c3ccccc3-c3ccccc3)nc(-n3c4ccccc4c4c(-c5ccccc5-c5cccc6c5c5ccccc5n6-c5nc(-c6ccccc6)nc(-c6ccccc6-c6ccccc6)n5)cccc43)n2)cc1] | 42% |
| 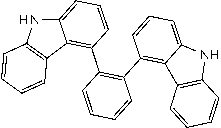 [SMILES: c1ccc(-c2cccc3[nH]c4ccccc4c23)c(-c2cccc3[nH]c4ccccc4c23)c1] | 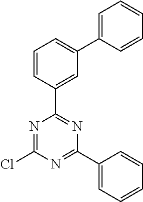 [SMILES: Clc1nc(-c2ccccc2)nc(-c2cccc(-c3ccccc3)c2)n1] | 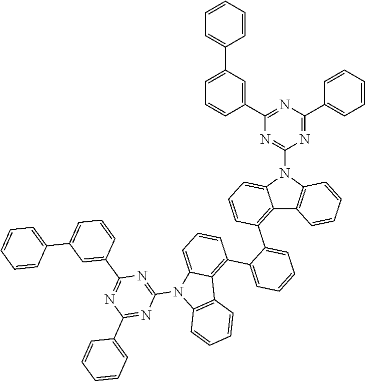 [SMILES: c1ccc(-c2cccc(-c3nc(-c4ccccc4)nc(-n4c5ccccc5c5c(-c6ccccc6-c6cccc7c6c6ccccc6n7-c6nc(-c7ccccc7)nc(-c7cccc(-c8ccccc8)c7)n6)cccc54)n3)c2)cc1] | 62% |
| 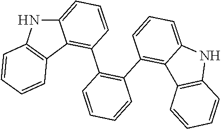 [SMILES: c1ccc(-c2cccc3[nH]c4ccccc4c23)c(-c2cccc3[nH]c4ccccc4c23)c1] | 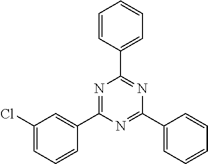 [SMILES: Clc1cccc(-c2nc(-c3ccccc3)nc(-c3ccccc3)n2)c1] | 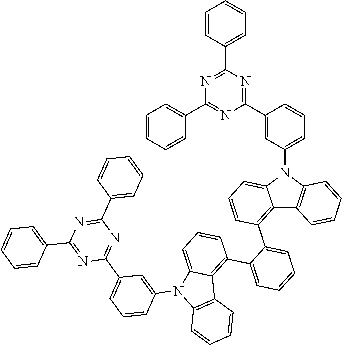 [SMILES: c1ccc(-c2nc(-c3ccccc3)nc(-c3cccc(-n4c5ccccc5c5c(-c6ccccc6-c6cccc7c6c6ccccc6n7-c6cccc(-c7nc(-c8ccccc8)nc(-c8ccccc8)n7)c6)cccc54)c3)n2)cc1] | 72% |
| 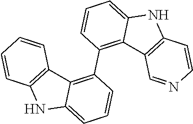 [SMILES: c1ccc2c(c1)[nH]c1cccc(-c3cccc4[nH]c5ccncc5c34)c12] | 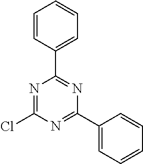 [SMILES: Clc1nc(-c2ccccc2)nc(-c2ccccc2)n1] | 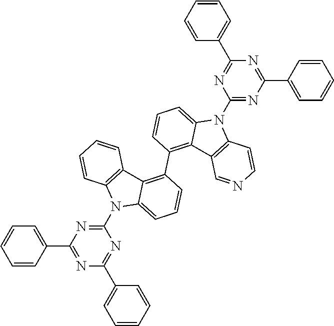 [SMILES: c1ccc(-c2nc(-c3ccccc3)nc(-n3c4ccccc4c4c(-c5cccc6c5c5cnccc5n6-c5nc(-c6ccccc6)nc(-c6ccccc6)n5)cccc43)n2)cc1] | 73% |
| 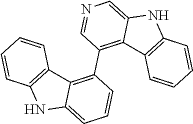 [SMILES: c1ccc2c(c1)[nH]c1cccc(-c3cncc4[nH]c5ccccc5c34)c12] | 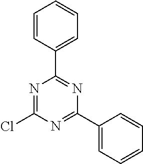 [SMILES: Clc1nc(-c2ccccc2)nc(-c2ccccc2)n1] | 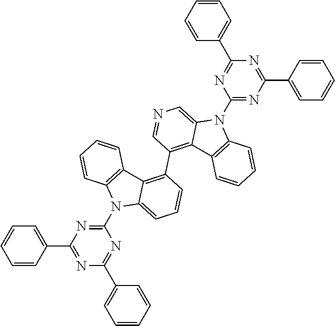 [SMILES: c1ccc(-c2nc(-c3ccccc3)nc(-n3c4ccccc4c4c(-c5cncc6c5c5ccccc5n6-c5nc(-c6ccccc6)nc(-c6ccccc6)n5)cccc43)n2)cc1] | 67% |
| 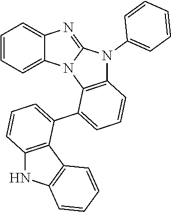 [SMILES: c1ccc(-n2c3cccc(-c4cccc5[nH]c6ccccc6c45)c3n3c4ccccc4nc23)cc1] | 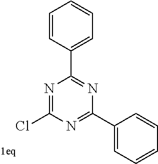 [SMILES: Clc1nc(-c2ccccc2)nc(-c2ccccc2)n1] | 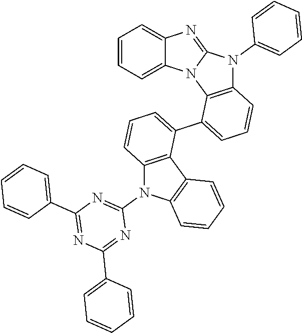 [SMILES: c1ccc(-c2nc(-c3ccccc3)nc(-n3c4ccccc4c4c(-c5cccc6c5n5c7ccccc7nc5n6-c5ccccc5)cccc43)n2)cc1] | 69% |

### Fabrication of OLEDs

### Fabrication of Vapor Processed OLED Devices

The manufacturing of the OLED devices is performed accordingly to WO 04/05891 with adapted film thicknesses and layer sequences. The following examples E1-E6 show data of OLED devices.

Glass plates with structured ITO (50 nm, indium tin oxide) are pre-treated with an oxygen plasma, followed by an argon plasma. The pre-treated glass plates form the substrates on which the OLED devices are fabricated.

The OLED devices have in principle the following layer structure:
Substrate,
ITO (50 nm),
Hole injection layer (HIL)
Hole transporting layer (HTL),
Electron blocking layer (EBL),
Emissive layer (EML),
Hole blocking layer (HBL),
Electron transporting layer (ETL),
Electron injection layer (optional, EIL)
Cathode.

The cathode is formed by an aluminium layer with a thickness of 100 nm. The detailed stack sequence is shown in table A. The materials used for the OLED fabrication are presented in table C.

All materials are applied by thermal vapour deposition in a vacuum chamber. The emission layer here always consists of at least one matrix material, one phosphorescent material and one fluorescent emitting dopant. The phosphorescent material and fluorescent dopant are mixed with the matrix material or matrix materials in a certain proportion by volume by co-evaporation. An expression such as H1:S1:D1 (82%:15%:3%) here means that material H1 is present in the layer in a proportion by volume of 82%, material H2 is present in the layer in a proportion by volume of 15% and material S1 is present in the layer in a proportion by volume of 3%. An expression such as H1:H2:S1:D1 (30%:52%:15%:3%) here means that material H1 is present in the layer in a proportion by volume of 30%, material H2 is present in the layer in a proportion by volume of 52%, material S1 is present in the layer in a proportion by volume of 15% and material D1 is present in the layer in a proportion by volume of 3%. Analogously, the electron-transport layer and hole-injection layer may also consist of a mixture of two or more materials.

The OLED devices are characterised by standard methods. For this purpose, the electroluminescence spectra and the external quantum efficiency (EQE, measured in %) are determined from current/voltage/luminance characteristic lines (IUL characteristic lines) assuming a Lambertian emission profile. The electroluminescence (EL) spectra are recorded at a luminous density of 1000 cd/m² and the CIE 1931 x and y coordinates are then calculated from the EL spectrum. The parameter U is defined as the voltage, which is required for a current density of

10 mA/cm². The parameter EQE represents the external quantum efficiency at a current density of 10 mA/cm².

The device data of various OLED devices are summarized in table B. The examples E1, E2 and E3 show data of inventive examples of hyperphosphorescent OLED devices with three components in the EML The examples E4, E5 and E6 show data of inventive hyperphosphorescent OLED devices with four components in the EML.

TABLE A
device stack of vapor processed OLEDs

| | HIL | HTL | EBL | EML | HBL | ETL |
|---|---|---|---|---|---|---|
| Ex. | [nm] | [nm] | [nm] | [nm] | [nm] | [nm] |
| E1 | HTM:F4TCNQ | HTM | HH | EH1:S1:D1 | EH1 | ETM:LiQ |
| | (95%:5%) | 150 nm | 20 nm | (82%:15%:3%) | 10 nm | (50%:50%) |
| | 20 nm | | | 30 nm | | 20 nm |
| E2 | HTM:F4TCNQ | HTM | HH | EH2:S1:D1 | EH2 | ETM:LiQ |
| | (95%:5%) | 150 nm | 20 nm | (82%:15%:3%) | 10 nm | (50%:50%) |
| | 20 nm | | | 30 nm | | 20 nm |
| E3 | HTM:F4TCNQ | HTM | HH | EH3:S1:D1 | EH3 | ETM:LiQ |
| | (95%:5%) | 150 nm | 20 nm | (82%:15%:3%) | 10 nm | (50%:50%) |
| | 20 nm | | | 30 nm | | 20 nm |
| E4 | HTM:F4TCNQ | HTM | HH | HH:EH1:S1:D1 | EH1 | ETM:LiQ |
| | (95%:5%) | 150 nm | 20 nm | (30%:52%:15%:3%) | 10 nm | (50%:50%) |
| | 20 nm | | | 30 nm | | 20 nm |
| E5 | HTM:F4TCNQ | HTM | HH | HH:EH2:S1:D1 | EH2 | ETM:LiQ |
| | (95%:5%) | 150 nm | 20 nm | (30%:52%:15%:3%) | 10 nm | (50%:50%) |
| | 20 nm | | | 30 nm | | 20 nm |
| E6 | HTM:F4TCNQ | HTM | HH | HH:EH3:S1:D1 | EH3 | ETM:LiQ |
| | (95%:5%) | 150 nm | 20 nm | (30%:52%:15%:3%) | 10 nm | (50%:50%) |
| | 20 nm | | | 30 nm | | 20 nm |

| Ex. | U (V) | EQE (%) | CIE x/y |
|---|---|---|---|
| E1 | 3.89 | 13.2 | 0.169/0.346 |
| E2 | 3.91 | 13.3 | 0.169/0.344 |
| E3 | 3.92 | 13.4 | 0.167/0.347 |
| E4 | 4.07 | 17.0 | 0.133/0.274 |
| E5 | 4.09 | 16.9 | 0.133/0.275 |
| E6 | 4.05 | 17.1 | 0.134/0.272 |

TABLE C
Structural formulae of vapor processed OLED materials

| | |
|---|---|
| 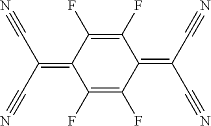 [SMILES: N#CC(C#N)=c1c(F)c(F)c(=C(C#N)C#N)c(F)c1F] F4TCNQ | 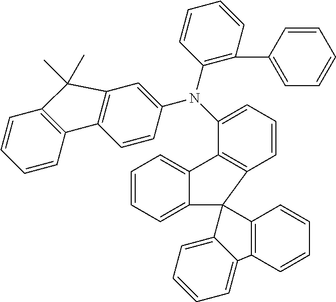 HTM |
| 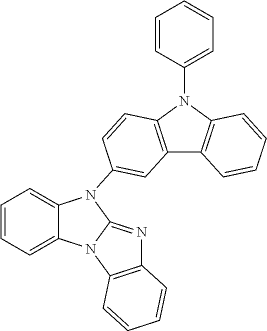 [SMILES: c1ccc(-n2c3ccccc3c3cc(-n4c5ccccc5n5c6ccccc6nc45)ccc32)cc1] HH | 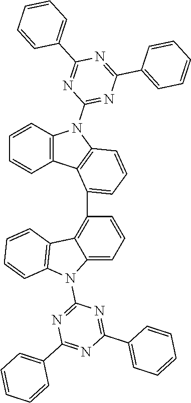 EH1 |
| 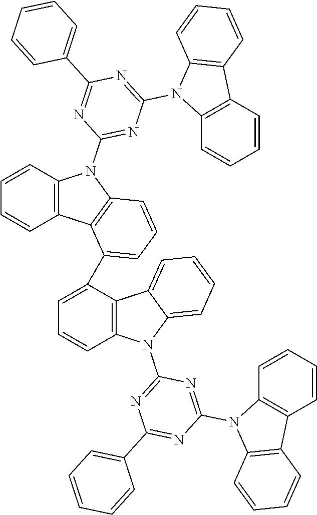 [SMILES: c1ccc(-c2nc(-n3c4ccccc4c4ccccc43)nc(-n3c4ccccc4c4c(-c5cccc6c5c5ccccc5n6-c5nc(-c6ccccc6)nc(-n6c7ccccc7c7ccccc76)n5)cccc43)n2)cc1] EH2 | 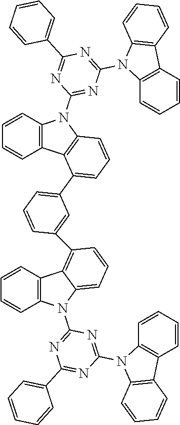 EH3 |
| 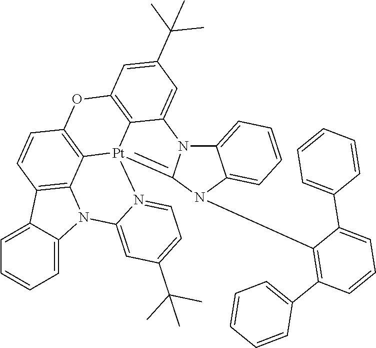 S1 HOMO: −5.00 eV LUMO: −1.91 eV S1: 2.84 eV T1: 2.63 eV | 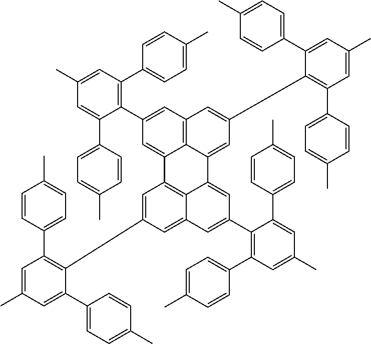 D1 HOMO: −5.04 eV LUMO: −2.39 eV S1: 2.71 eV T1: 1.53 eV |
| 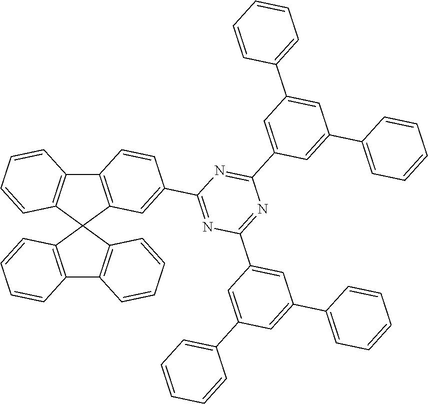 [SMILES: c1ccc(-c2cc(-c3ccccc3)cc(-c3nc(-c4cc(-c5ccccc5)cc(-c5ccccc5)c4)nc(-c4ccc5c(c4)C4(c6ccccc6-c6ccccc64)c4ccccc4-5)n3)c2)cc1] ETM | 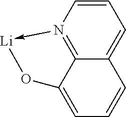 LiQ |

### Determination of Peak Emission Wavelength λₘₐₓ of the Fluorescent Emitter and of the Full Width at Half Maximum (FWHM)

To determine the peak emission wavelength of the fluorescent emitter, the fluorescent emitter is dissolved in toluene and a photoluminescent spectrum is obtained using a fluorescence spectrometer. More specifically, a concentration of 1 mg/100 mL is used. The solution is excited in a fluorescence spectrometer Hitachi F-4500 with a to the material matching wavelength. The measurement is carried out at room temperature. The peak emission wavelength λₘₐₓ is the wavelength of the first maximum of the emission spectrum. Typically, the first maximum is also the global maximum of the spectrum.

To determine the spectral broadness of the fluorescent emitter the values for the wavelengths, which are at half the maximum of the peak emission wavelength are subtracted.

According to the described methods the following properties for the fluorescent emitter D1 are obtained: λₘₐₓ=470 nm, FWHM: 21 nm

1.-21. (canceled)

22. A composition comprising:
an electron-transporting host material;
a blue phosphorescent metal complex;
a fluorescent emitter;
wherein the electron-transporting host material is selected from the compounds of formulae (1), (2) or (3); 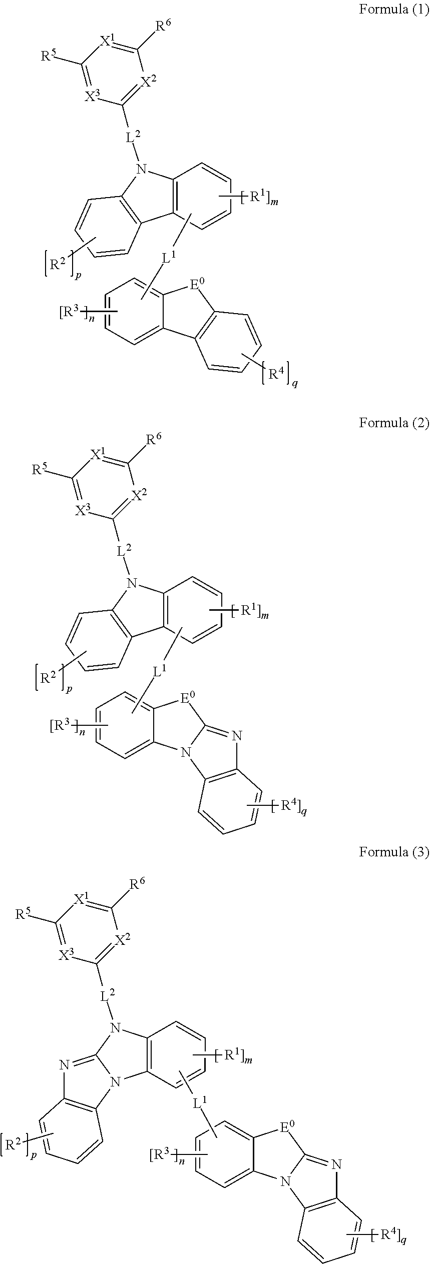
where the symbols and indices used are as follows:
X¹, X², X³ stand, on each occurrence identically or differently, for a group CR^{X} or N; with the proviso that at least one group selected from X¹, X² and X³ stands for N;
E⁰ stands for on each occurrence, identically or differently, for C(R^{C})₂, NR^{N}, O or S;
L¹, L² stand on each occurrence, identically or differently, for a single bond, —C(R)₂—, —Si(R)₂— or for an aromatic or heteroaromatic ring system having 5 to 30 aromatic ring atoms, which may be substituted by one or more radicals R;
R^{X}, R¹, R², R³, R⁴, R⁵, R⁶ stand on each occurrence, identically or differently, for a radical selected from H, D, F, Cl, Br, I, CHO, CN, C(═O)Ar, P(═O)(Ar)₂, S(═O)Ar, S(═O)₂Ar, N(R)₂, N(Ar)₂, NO₂, Si(R)₃, B(OR)₂, OSO₂R, a straight-chain alkyl, alkoxy or thioalkyl group having 1 to 40 C atoms or branched or a cyclic alkyl, alkoxy or thioalkyl group having 3 to 40 C atoms, each of which may be substituted by one or more radicals R, where in each case one or more non-adjacent CH₂ groups may be replaced by RC═CR, C≡C, Si(R)₂, Ge(R)₂, Sn(R)₂, C═O, C═S, C═Se, P(═O)(R), SO, SO₂, O, S or CONR and where one or more H atoms may be replaced by D, F, Cl, Br, I, CN or NO₂, an aromatic or heteroaromatic ring system having 5 to 60 aromatic ring atoms, which may in each case be substituted by one or more radicals R, and an aryloxy group having 5 to 60 aromatic ring atoms, which may be substituted by one or more radicals R; where two radicals R¹, two radicals R², two radicals R³, two radicals R⁴ may form an aliphatic, aromatic or heteroaromatic ring system together, which may be substituted by one or more radicals R;
R^{C} stand on each occurrence, identically or differently, for a radical selected from H, D, a straight-chain alkyl group having 1 to 40 C atoms, which may be substituted by one or more radicals R, an aryl or heteroaryl group having 6 to 18 aromatic ring atoms, which may in each case be substituted by one or more radicals R; where two radicals R′ may form an aliphatic, aromatic or heteroaromatic ring system together, which may be substituted by one or more radicals R;
R^{N} stand on each occurrence, identically or differently, for a radical selected from H, D, F, a straight-chain alkyl group having 1 to 40 C atoms or branched or a cyclic alkyl group having 3 to 40 C atoms, each of which may be substituted by one or more radicals R, and where one or more H atoms may be replaced by D, F or CN, an aromatic or heteroaromatic ring system having 5 to 60 aromatic ring atoms, which may in each case be substituted by one or more radicals R;
R stands on each occurrence, identically or differently, for H, D, F, Cl, Br, I, CHO, CN, C(═O)Ar, P(═O)(Ar)₂, S(═O)Ar, S(═O)₂Ar, N(R′)₂, N(Ar)₂, NO₂, Si(R′)₃, B(OR′)₂, OSO₂R′, a straight-chain alkyl, alkoxy or thioalkyl group having 1 to 40 C atoms or branched or a cyclic alkyl, alkoxy or thioalkyl group having 3 to 40 C atoms, each of which may be substituted by one or more radicals R′, where in each case one or more non-adjacent CH₂ groups may be replaced by R′C═CR′, C≡C, Si(R′)₂, Ge(R′)₂, Sn(R′)₂, C═O, C═S, C═Se, P(═O)(R′), SO, SO₂, O, S or CONR and where one or more H atoms may be replaced by D, F, Cl, Br, I, CN or NO₂, an aromatic or heteroaromatic ring system having 5 to 60 aromatic ring atoms, which may in each case be substituted by one or more radicals R′, or an aryloxy group having 5 to 60 aromatic ring atoms, which may be substituted by one or more radicals R′; where two radicals R may form an aliphatic or aromatic ring system together, which may be substituted by one or more radicals R′;
Ar is, on each occurrence, identically or differently, an aromatic or heteroaromatic ring system having 5 to 60 aromatic ring atoms, which may in each case also be substituted by one or more radicals R′;
R′ stands on each occurrence, identically or differently, for H, D, F, Cl, Br, I, CN, a straight-chain alkyl, alkoxy or thioalkyl group having 1 to 20 C atoms or branched or cyclic alkyl, alkoxy or thioalkyl group having 3 to 20 C atoms, where in each case one or more non-adjacent CH₂ groups may be replaced by SO, SO₂, O, S and where one or more H atoms may be replaced by D, F, Cl, Br or I, or an aromatic or heteroaromatic ring system having 5 to 24 aromatic ring atoms;
m, n are the same or different at each instance and are selected from 0, 1, 2 or 3;
p, q are the same or different at each instance and are 0, 1, 2, 3 or 4.

23. The composition according to claim 22, where the electron-transporting host material is selected from the compounds of formulae (1A), (2A) or (3A); 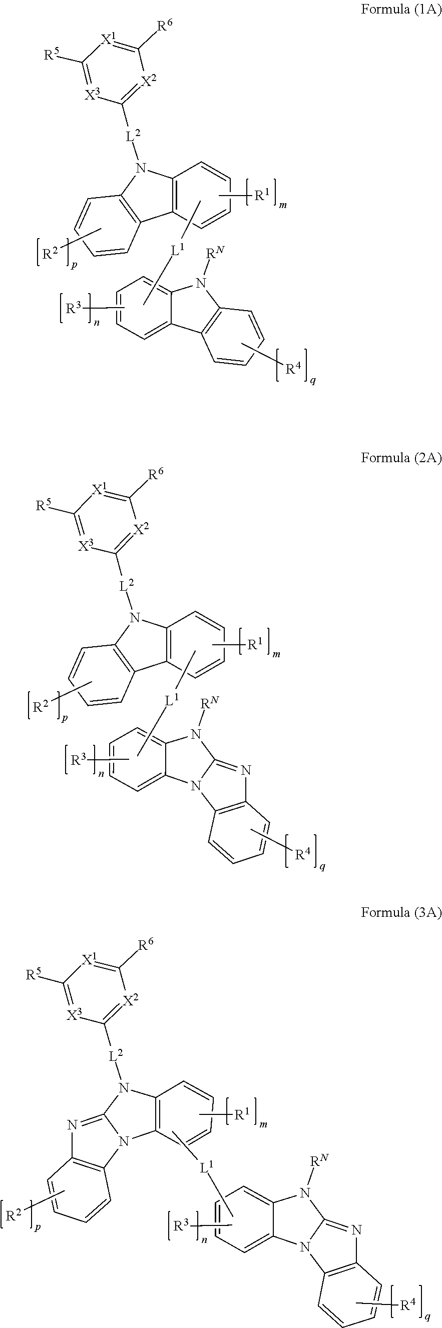
where the symbols and indices have the same meaning as in claim 22.

24. The composition according to claim 22, where the electron-transporting host material is selected from the compounds of formulae (1B), (2B) or (3B); 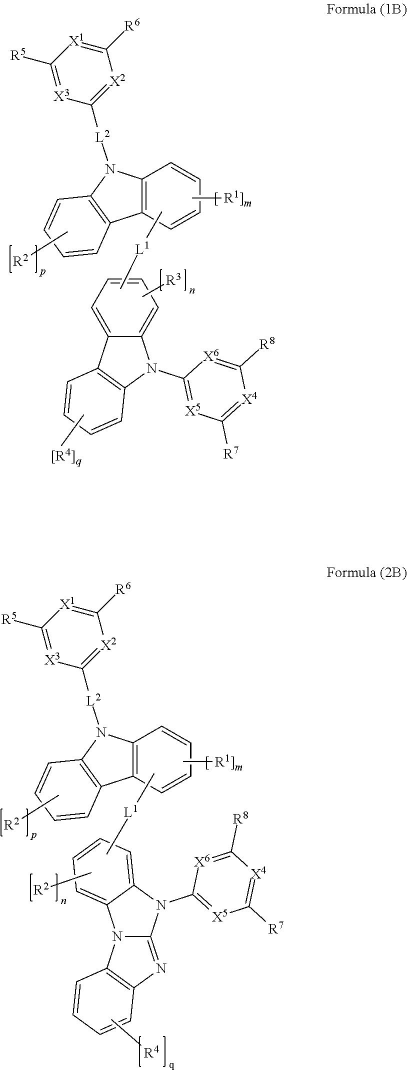 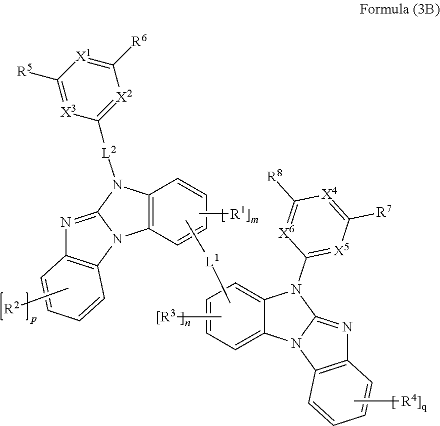
where
X⁴, X⁵, X⁶ stand, on each occurrence identically or differently, for a group CR^{X} or N; where R^{X} has the same meaning as in claim 22, and with the proviso that at least one group selected from X⁴, X⁵ and X⁶ stands for N;
R⁷, R⁸ stand on each occurrence, identically or differently, for a radical selected from H, D, F, Cl, Br, I, CHO, CN, C(═O)Ar, P(═O)(Ar)₂, S(═O)Ar, S(═O)₂Ar, N(R)₂, N(Ar)₂, NO₂, Si(R)₃, B(OR)₂, OSO₂R, a straight-chain alkyl, alkoxy or thioalkyl group having 1 to 40 C atoms or branched or a cyclic alkyl, alkoxy or thioalkyl group having 3 to 40 C atoms, each of which may be substituted by one or more radicals R, where in each case one or more non-adjacent CH₂ groups may be replaced by RC═CR, C≡C, Si(R)₂, Ge(R)₂, Sn(R)₂, C═O, C═S, C═Se, P(═O)(R), SO, SO₂, O, S or CONR and where one or more H atoms may be replaced by D, F, Cl, Br, I, CN or NO₂, an aromatic or heteroaromatic ring system having 5 to 60 aromatic ring atoms, which may in each case be substituted by one or more radicals R, and an aryloxy group having 5 to 60 aromatic ring atoms, which may be substituted by one or more radicals R;
and where the other symbols and indices have the same meaning as in claim 22.

25. The composition according to claim 22, wherein the electron-transporting host material is selected from the compounds of formulae (1C), (2C) or (3C); 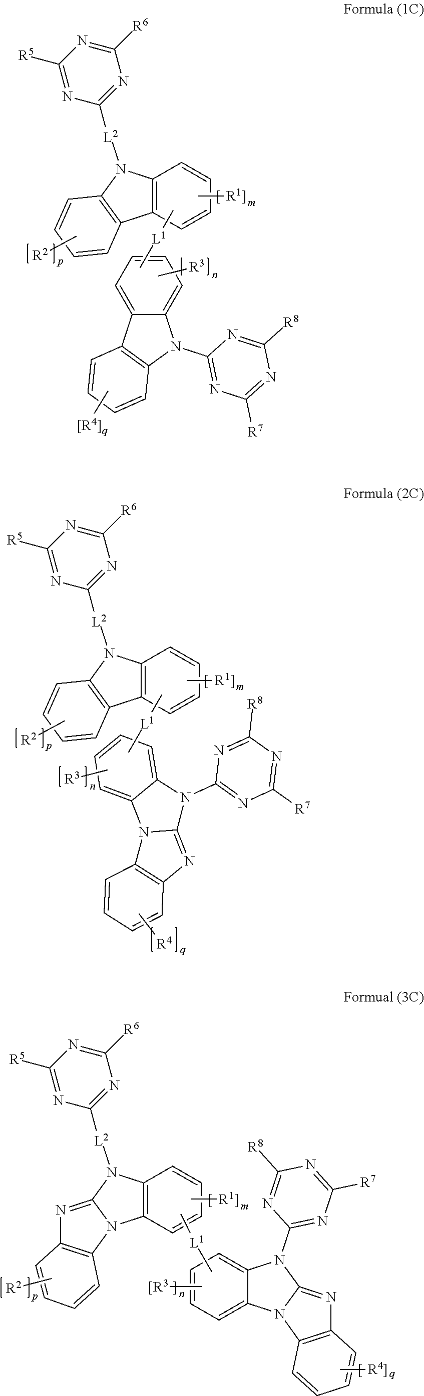
where the symbols and indices have the same meaning as in claim 22.

26. The composition according to claim 22, wherein the electron-transporting host material is selected from the compounds of formulae (1D), (2D) or (3D); 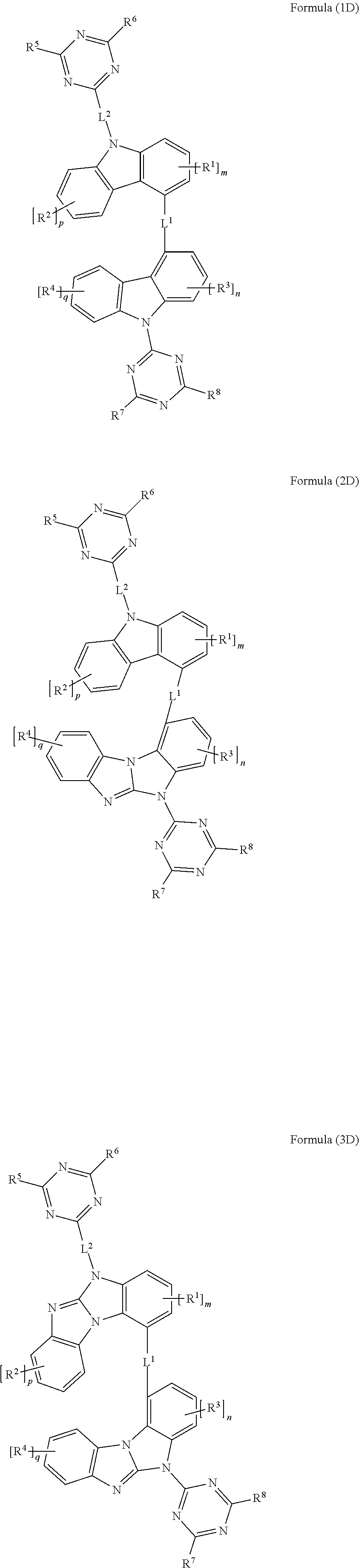
where the symbols and indices have the same meaning as in claim 22.

27. The composition according to claim 22, wherein the composition further comprises a hole-transporting host material.

28. The composition according to claim 27, wherein the hole-transporting host material is selected from the group of the carbazole and triarylamine derivatives, more particularly the biscarbazoles, the bridged carbazoles, the triarylamines, the dibenzofuran-carbazole derivatives or dibenzofuran-amine derivatives, and the carbazoleamines.

29. The composition according to claim 27, wherein the hole-transporting host material is selected from compounds of formula (h-1) or (h-2), 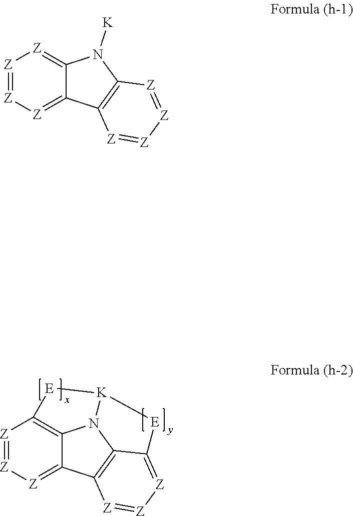
where:
K is Ar⁴ or -L⁵-N(Ar)₂;
Z is C—R^{Z} or C—R^{A}; or two adjacent groups Z form a condensed ring together;
R^{A} is -L³-Ar⁵ or -L⁴-N(Ar)₂;
R^{Z} is the same or different at each instance and is selected from H, D, F, Cl, Br, I, N(Ar)₂, N(R)₂, OAr, SAr, CN, NO₂, OR, SR, COOR, C(═O)N(R)₂, Si(R)₃, B(OR)₂, C(═O)R, P(═O)(R)₂, S(═O)R, S(═O)₂R, OSO₂R, a straight-chain alkyl group having 1 to 20 carbon atoms or an alkenyl or alkynyl group having 2 to 20 carbon atoms or a branched or cyclic alkyl group having 3 to 20 carbon atoms, where the alkyl, alkenyl or alkynyl group may in each case be substituted by one or more R radicals, where one or more nonadjacent CH₂ groups may be replaced by Si(R)₂, C═O, NR, O, S or CONR, or an aromatic or heteroaromatic ring system which has 5 to 60 aromatic ring atoms, preferably 5 to 40 aromatic ring atoms, and may be substituted in each case by one or more R radicals;
L⁴, L⁵ are the same or different at each instance and are a single bond or an aromatic or heteroaromatic ring system which has 5 to 30 aromatic ring atoms and may be substituted by one or more R radicals;
L³ is a single bond or an aromatic or heteroaromatic ring system which has 5 to 30 aromatic ring atoms and may be substituted by one or more R radicals, where one radical R on L³ may form a ring with a radical R^{Z} on the carbazole;
Ar⁴ is an aromatic ring system having 6 to 40 aromatic ring atoms or a heteroaromatic ring system having 5 to 40 aromatic ring atoms, which may be substituted by one or more R radicals;
Ar⁵ is the same or different at each instance and is an unsubstituted or substituted heteroaromatic ring system having 5 to 40 aromatic ring atoms, which may be substituted by one or more R;
R^{Z} is the same or different at each instance and is H, D, F, Cl, Br, I, N(Ar)₂, N(R)₂, OAr, SAr, CN, NO₂, OR, SR, COOR, C(═O)N(R)₂, Si(R)₃, B(OR)₂, C(═O)R, P(═O)(R)₂, S(═O)R, S(═O)₂R, OSO₂R, a straight-chain alkyl group having 1 to 20 carbon atoms or an alkenyl or alkynyl group having 2 to 20 carbon atoms or a branched or cyclic alkyl group having 3 to 20 carbon atoms, where the alkyl, alkenyl or alkynyl group may in each case be substituted by one or more R radicals, where one or more nonadjacent CH₂ groups may be replaced by Si(R)₂, C═O, NR, O, S or CONR, or an aromatic or heteroaromatic ring system which has 5 to 60 aromatic ring atoms, preferably 5 to 40 aromatic ring atoms, and may be substituted in each case by one or more R radicals; at the same time, two R^{Z} radicals together may also form a ring system;
E is on each occurrence, independently, a single bond or a group C(R⁰)₂;
R⁰ is selected on each occurrence, independently, from a straight-chain alkyl group having 1 to 10 carbon atoms or a branched or cyclic alkyl group having 3 to 10 carbon atoms, which may in each case be substituted by one or more R′ radicals;
x, y are selected, independently, from 0 or 1, wherein when x or y is 0, then the corresponding group E is absent; and x+y=1 or 2;
with the proviso that the compounds of formulae (h-1) and (h-2) comprise at least one group Z, which stands for R^{A}.

30. The composition according to claim 29, wherein Ar⁵ is a an unsubstituted or substituted heteroaromatic ring system selected from the groups of formulae (Ar5-1) to (Ar5-6), 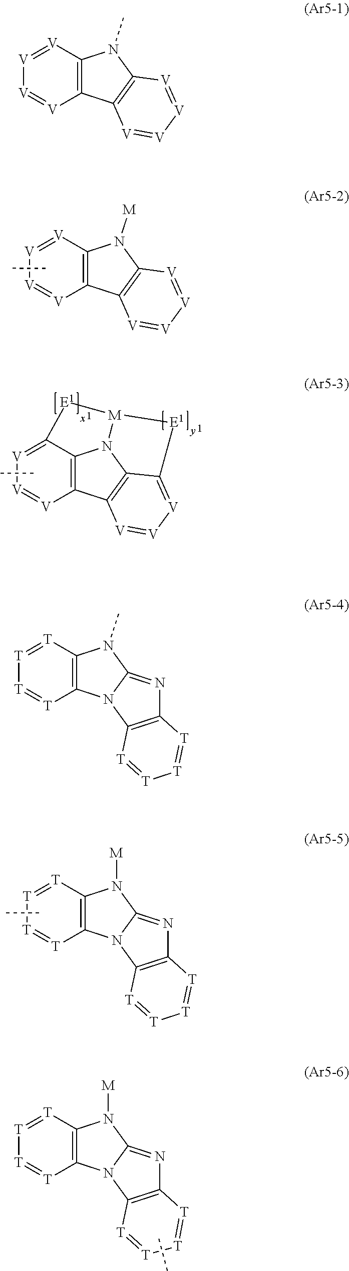
where the dashed bond indicates the bonding to L³ or Z;
V is C—R^{V}, with the proviso that V stands for C when it is bonded to the group of formula (h-1) or (h-2); or two adjacent groups V form a condensed ring together;
T is C—R^{T}, with the proviso that T stands for C when it is bonded to the group of formula (h-1) or (h-2), or two adjacent groups T form a condensed ring together;
M is an aromatic ring system having 6 to 40 aromatic ring atoms or a heteroaromatic ring system having 5 to 40 aromatic ring atoms, which may be substituted by one or more R radicals;
E¹ is on each occurrence, independently, a single bond or a group C(R⁰)₂;
R^{T}, R^{V} is the same or different at each instance and is selected from H, D, F, Cl, Br, I, N(Ar)₂, N(R)₂, OAr, SAr, CN, NO₂, OR, SR, COOR, C(═O)N(R)₂, Si(R)₃, B(OR)₂, C(═O)R, P(═O)(R)₂, S(═O)R, S(═O)₂R, OSO₂R, a straight-chain alkyl group having 1 to 20 carbon atoms or an alkenyl or alkynyl group having 2 to 20 carbon atoms or a branched or cyclic alkyl group having 3 to 20 carbon atoms, where the alkyl, alkenyl or alkynyl group may in each case be substituted by one or more R radicals, where one or more nonadjacent CH₂ groups may be replaced by Si(R)₂, C═O, NR, O, S or CONR, or an aromatic or heteroaromatic ring system which has 5 to 60 aromatic ring atoms, preferably 5 to 40 aromatic ring atoms, and may be substituted in each case by one or more R radicals; at the same time, two R^{T} radicals together may form a ring system and two R^{V} radicals together may form a ring system;
x¹, y¹ are selected, independently, from 0 or 1, wherein when x¹ or y¹ is 0, then the corresponding group E¹ is absent; with the proviso that x¹+y¹=1 or 2.

31. The composition according to claim 29, wherein the hole-transporting host material is selected from compounds of formula (h-1-1) to (h-2-2), 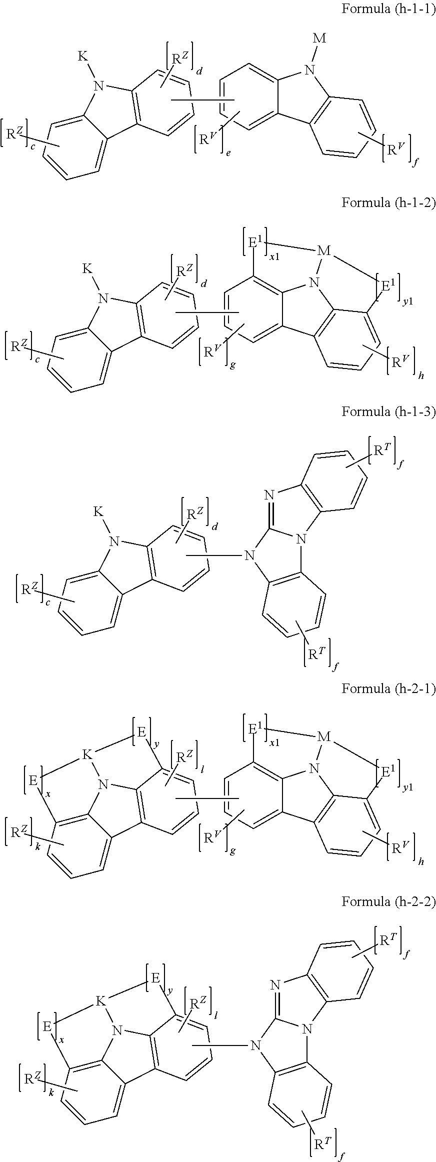
where the indices have the following meaning:
x, y are selected, independently, from 0 or 1, wherein when x or y is 0, then the corresponding group E is absent; and x+y=1 or 2;
x¹, y¹ are selected, independently, from 0 or 1, wherein when x¹ or y¹ is 0, then the corresponding group E¹ is absent; with the proviso that x¹+y¹=1 or 2;
c, f stands, independently, for 0, 1, 2, 3 or 4;
d, e stands, independently, for 0, 1, 2 or 3;
g stands for 0, 1, 2 or 3 if x¹=0; or for 0, 1 or 2 if x¹=1;
h stands for 0, 1, 2, 3 or 4 if y¹=0; or for 0, 1, 2 or 3 if y¹=1;
k stands for 0, 1, 2, 3 or 4 if x=0; or for 0, 1, 2 or 3 if x=1; and
l stands for 0, 1, 2 or 3 if y=0; or for 0, 1 or 2 if y=1.

32. The composition according to claim 22, wherein the blue phosphorescent metal complex is selected from platinum complexes.

33. The composition according to claim 22, wherein the blue phosphorescent metal complex has a LUMO of from −1.8 eV to −2.2 eV, as defined by quantum-chemical calculations.

34. The composition according to claim 22, wherein the blue phosphorescent metal complex has a HOMO of from −5.0 eV to −5.6 eV, as defined by quantum-chemical calculations.

35. The composition according to claim 22, wherein the energy of the lowest triplet state T₁ of the blue phosphorescent metal complex is higher then 2.55 eV, as defined by quantum-chemical calculations.

36. The composition according to claim 22, wherein the fluorescent emitter has an emission peak wavelength between 420-550 nm and has a full width at half maximum FWHM≤50 nm.

37. The composition according to claim 22, wherein the fluorescent emitter has a LUMO of from −2.1 eV to −2.5 eV, as defined by quantum-chemical calculations.

38. The composition according to claim 22, wherein the fluorescent emitter has a HOMO of from −4.8 eV to −5.2 eV, as defined by quantum-chemical calculations.

39. The composition according to claim 22, wherein the energy of the lowest singlet state S₁ of the fluorescent emitter is of from 2.65 eV to 2.9 eV as defined by quantum-chemical calculations.

40. Formulation comprising a composition according to claim 22 and a solvent.

41. An electronic device comprising at least one composition according to claim 22.

42. The electronic device according to claim 41 which is an organic electroluminescent device comprising:
anode;
cathode; and
at least one emitting layer, where the emitting layer comprises at least one composition.
